(19) United States
(12) Patent Application Publication
(10) Pub. No.: US 2026/0173263 A1
(43) Pub. Date: Jun. 18, 2026

(54) CONDUCTOR-EMBEDDED CIRCUIT BOARD

(71) Applicant: Murata Manufacturing Co., Ltd., Nagaokakyo-shi (JP)

(72) Inventors: Nobuyoshi Adachi, Nagaokakyo-shi (JP); Kenji Nishiyama, Nagaokakyo-shi (JP); Yoshimitsu Ushimi, Nagaokakyo-shi (JP); Hidehiko Sasaki, Nagaokakyo-shi (JP); Koshi Himeda, Nagaokakyo-shi (JP)

(21) Appl. No.: 19/530,793

(22) Filed: Feb. 5, 2026

Related U.S. Application Data
(63) Continuation of application No. PCT/JP2024/028785, filed on Aug. 9, 2024.

(30) Foreign Application Priority Data
Aug. 10, 2023 (JP) 2023-130819

(51) Int. Cl. H05K 1/02; H05K 1/11; H05K 1/182

(52) U.S. Cl. CPC H05K 1/0298; H05K 1/115; H05K 1/182; H05K 2201/1003

(57) ABSTRACT

A conductor-embedded circuit board includes a base member, first and second wiring layers, and first and second conductors. The conductor-embedded circuit board also includes a separation insulating layer. The base member has first and second surfaces and a through-hole. The second surface is located on a side of the base member opposite the first surface in a thickness direction. The through-hole extends in the thickness direction. The first wiring layer is disposed on the first surface of the base member. The second wiring layer is disposed on the second surface of the base member. The first and second conductors are disposed in the through-hole and each extend in the thickness direction. In a plan view that is viewed in the thickness direction, the separation insulating layer is located between the first conductor and the second conductor within the through-hole so as to separate the first conductor and the second conductor.

### CROSS REFERENCE TO RELATED APPLICATIONS

This application is a continuation of International Application No. PCT/JP2024/028785, filed Aug. 9, 2024, which claims priority to Japanese Patent Application No. 2023-130819, filed Aug. 10, 2023, the entire contents of each of which are hereby incorporated by reference in their entirety.

### TECHNICAL FIELD

The present disclosure relates to a conductor-embedded circuit board.

### BACKGROUND

A voltage regulator module is used for, for example, supplying power to a processor, such as a CPU or a GPU. As the voltage regulator module, a buck switching regulator module including a combination of functional components, such as a switching device, an inductor, and a capacitor, is known.

Usually, such a voltage regulator module is disposed together with a processor on one main surface of a system board (motherboard). In contrast, placing a voltage regulator module on a main surface of a system board opposite the main surface including a processor is also proposed.

U.S. Patent Application Publication No. 2020/0111597 discloses a three-layer voltage regulator module in which a magnetic core assembly is disposed between two circuit board assemblies. A conductor forming an inductor is embedded in the magnetic core assembly.

### SUMMARY OF INVENTION

In the voltage regulator module disclosed in U.S. Patent Application Publication No. 2020/0111597, there remains room for improvement in terms of further reducing the size of a structure having a conductor embedded therein.

The present disclosure has been made to address the above-described issue. It is an object of the disclosure to provide a conductor-embedded circuit board that can be further reduced in size.

According to an exemplary aspect, a conductor-embedded circuit board of the present disclosure includes a base member, first and second wiring layers, and first and second conductors. The conductor-embedded circuit board also includes a separation insulating layer. The base member has first and second surfaces and a through-hole. The second surface is located on a side of the base member opposite the first surface in a thickness direction. The through-hole extends in the thickness direction. The first wiring layer is disposed on the first surface of the base member. The second wiring layer is disposed on the second surface of the base member. The first and second conductors are disposed in the through-hole and each extend in the thickness direction. In a plan view that is viewed in the thickness direction, the separation insulating layer is located between the first conductor and the second conductor within the through-hole so as to separate the first conductor and the second conductor from each other.

According to the present disclosure, it is possible to provide a conductor-embedded circuit board that can be further reduced in size.

### BRIEF DESCRIPTION OF DRAWINGS

FIG. 1 is a schematic perspective view of an inductor-embedded circuit board according to a first exemplary embodiment.

FIG. 2 is a schematic exploded perspective view of the inductor-embedded circuit board shown in FIG. 1.

FIG. 3A is a schematic top view illustrating a component-embedded base body and some wiring layers in the inductor-embedded circuit board shown in FIG. 1.

FIG. 3B is a schematic bottom view illustrating the component-embedded base body and the wiring layers shown in FIG. 3A.

FIG. 3C is a schematic sectional view taken along line IIIC-IIIC in FIGS. 3A and 3B.

FIG. 4 is a schematic perspective view of an inductor unit cell.

FIG. 5A is a schematic top view of the inductor unit cell shown in FIG. 4.

FIG. 5B is a schematic sectional view taken along line VB-VB in FIG. 5A.

FIG. 6 is a diagram illustrating the basic circuit configuration of a voltage regulator module (buck converter).

FIG. 7A is a schematic top view for explaining a method for manufacturing inductor unit cells.

FIG. 7B is a schematic sectional view taken along line VIIB-VIIB in FIG. 7A.

FIG. 8A is a schematic top view for explaining the method for manufacturing the inductor unit cells.

FIG. 8B is a schematic sectional view taken along line VIIIB-VIIIB in FIG. 8A.

FIG. 9A is a schematic top view for explaining the method for manufacturing the inductor unit cells.

FIG. 9B is a schematic sectional view taken along line IXB-IXB in FIG. 9A.

FIG. 10A is a schematic top view for explaining the method for manufacturing the inductor unit cells.

FIG. 10B is a schematic sectional view taken along line XB-XB in FIG. 10A.

FIG. 11A is a schematic top view for explaining the method for manufacturing the inductor unit cells.

FIG. 11B is a schematic sectional view taken along line XIB-XIB in FIG. 11A.

FIG. 12A is a schematic top view for explaining the method for manufacturing the inductor unit cells.

FIG. 12B is a schematic sectional view taken along line XIIB-XIIB in FIG. 12A.

FIG. 13A is a schematic top view for explaining the method for manufacturing the inductor unit cells.

FIG. 13B is a schematic sectional view taken along line XIIIB-XIIIB in FIG. 13A.

FIG. 14A is a schematic top view for explaining the method for manufacturing the inductor unit cells.

FIG. 14B is a schematic sectional view taken along line XIVB-XIVB in FIG. 14A.

FIG. 15A is a schematic top view for explaining a method for manufacturing a circuit board.

FIG. 15B is a schematic sectional view taken along line XVB-XVB in FIG. 15A.

FIG. 16A is a schematic top view for explaining the method for manufacturing the circuit board.

FIG. 16B is a schematic sectional view taken along line XVIB-XVIB in FIG. 16A.

FIG. 17A is a schematic top view for explaining the method for manufacturing the circuit board.

FIG. 17B is a schematic sectional view taken along line XVIIB-XVIIB in FIG. 17A.

FIG. 18A is a schematic top view for explaining the method for manufacturing the circuit board.

FIG. 18B is a schematic bottom view corresponding to FIG. 18A.

FIG. 18C is a schematic sectional view taken along line XVIIIC-XVIIIC in FIG. 18A.

FIG. 19A is a schematic top view for explaining the method for manufacturing the circuit board.

FIG. 19B is a schematic bottom view corresponding to FIG. 19A.

FIG. 19C is a schematic sectional view taken along line XIXC-XIXC in FIG. 19A.

FIG. 20A is a schematic top view for explaining the method for manufacturing the circuit board.

FIG. 20B is a schematic bottom view corresponding to FIG. 20A.

FIG. 20C is a schematic sectional view taken along line XXC-XXC in FIG. 20A.

FIG. 21A is a schematic top view for explaining the method for manufacturing the circuit board.

FIG. 21B is a schematic bottom view corresponding to FIG. 21A.

FIG. 21C is a schematic sectional view taken along line XXIC-XXIC in FIG. 21A.

FIG. 22A is a schematic top view for explaining the method for manufacturing the circuit board.

FIG. 22B is a schematic bottom view corresponding to FIG. 22A.

FIG. 22C is a schematic sectional view taken along line XXIIC-XXIIC in FIG. 22A.

FIG. 23A is a schematic top view for explaining the method for manufacturing the circuit board.

FIG. 23B is a schematic bottom view corresponding to FIG. 23A.

FIG. 23C is a schematic sectional view taken along line XXIIIC-XXIIIC in FIG. 23A.

FIG. 24A is a schematic top view for explaining the method for manufacturing the circuit board.

FIG. 24B is a schematic bottom view corresponding to FIG. 24A.

FIG. 24C is a schematic sectional view taken along line XXIVC-XXIVC in FIG. 24A.

FIG. 25A is a schematic top view illustrating a component-embedded base body and some wiring layers of an inductor-embedded circuit board of a second exemplary embodiment.

FIG. 25B is a schematic bottom view illustrating the component-embedded base body and the wiring layers shown in FIG. 25A.

FIG. 25C is a schematic sectional view taken along line XXVC-XXVC in FIGS. 25A and 25B.

FIG. 26A is a schematic top view for explaining a method for manufacturing inductor unit cells.

FIG. 26B is a schematic sectional view taken along line XXVIB-XXVIB in FIG. 26A.

FIG. 27A is a schematic top view for explaining the method for manufacturing the inductor unit cells.

FIG. 27B is a schematic sectional view taken along line XXVIIB-XXVIIB in FIG. 27A.

FIG. 28A is a schematic top view for explaining a method for manufacturing a circuit board.

FIG. 28B is a schematic sectional view taken along line XXVIIIB-XXVIIIB in FIG. 28A.

FIG. 29A is a schematic top view for explaining the method for manufacturing the circuit board.

FIG. 29B is a schematic sectional view taken along line XXIXB-XXIXB in FIG. 29A.

FIG. 30 is a schematic perspective view of a conductor-containing section of a circuit board according to a third exemplary embodiment.

FIG. 31A is a schematic top view of the conductor-containing section shown in FIG. 30.

FIG. 31B is a schematic sectional view taken along line XXXIB-XXXIB in FIG. 31A.

FIG. 32A is a schematic top view of a first modified example of a conductor-containing section.

FIG. 32B is a schematic sectional view taken along line XXXIIB-XXXIIB in FIG. 32A.

FIG. 33A is a schematic top view of a second modified example of a conductor-containing section.

FIG. 33B is a schematic sectional view taken along line XXXIIIB-XXXIIIB in FIG. 33A.

FIG. 34A is a schematic top view of a third modified example of a conductor-containing section.

FIG. 34B is a schematic sectional view taken along line XXXIVB-XXXIVB in FIG. 34A.

FIG. 35A is a schematic top view of a fourth modified example of a conductor-containing section.

FIG. 35B is a schematic sectional view taken along line XXXVB-XXXVB in FIG. 35A.

FIG. 36A is a schematic top view of a fifth modified example of a conductor-containing section.

FIG. 36B is a schematic sectional view taken along line XXXVIB-XXXVIB in FIG. 36A.

FIG. 37A is a top perspective view schematically illustrating conductor-containing sections and second electrodes in a configuration example (2).

FIG. 37B is a bottom perspective view schematically illustrating the conductor-containing sections and first electrodes in the configuration example (2).

FIG. 37C is a schematic top view illustrating magnetic fields generated in a first structure.

FIG. 38A is a diagram illustrating an example of the circuit configuration of a voltage regulator module using the circuit board of the configuration example (2).

FIG. 38B is a diagram illustrating a simplified form of the circuit configuration shown in FIG. 38A.

FIG. 38C is a diagram illustrating phase 1 of the circuit shown in FIG. 38B.

FIG. 38D is a schematic graph illustrating waveforms of a ripple current occurring in the circuit shown in FIG. 38A.

FIG. 39A is a top perspective view schematically illustrating conductor-containing sections and second electrodes in a configuration example (3).

FIG. 39B is a bottom perspective view schematically illustrating the conductor-containing sections and first electrodes in the configuration example (3).

FIG. 40 is a diagram illustrating an example of the circuit configuration of a voltage regulator module using the circuit board of the configuration example (3).

FIG. 41A is a top perspective view schematically illustrating conductor-containing sections and second electrodes in a configuration example (5).

FIG. 41B is a bottom perspective view schematically illustrating the conductor-containing sections and first electrodes in the configuration example (5).

FIG. 42A is a schematic perspective view for explaining a manufacturing method for a first structure M.

FIG. 42B is a schematic perspective view for explaining the manufacturing method for the first structure M.

FIG. 42C is a schematic perspective view for explaining the manufacturing method for the first structure M.

FIG. 43A is a schematic perspective view for explaining a manufacturing method for a conductor-containing section.

FIG. 43B is a schematic perspective view for explaining a manufacturing method for the first structure M.

FIG. 44A is a schematic top view illustrating an example of a design method for the first structure M.

FIG. 44B is a schematic top view illustrating the example of the design method for the first structure M.

FIG. 45 is a schematic sectional view illustrating an example of a voltage regulator module according to a fourth exemplary embodiment.

FIG. 46 is a schematic sectional view of an inductor-embedded assembly of a reference example.

### DETAILED DESCRIPTION OF EMBODIMENTS

Embodiments of the present disclosure will be described below with reference to the drawings. The disclosure is not limited to these exemplary embodiments. In the drawings, substantially identical members are designated by like reference numeral. For the purpose of representation, the dimensions of individual elements in the drawings may be exaggerated for clarity and are not necessarily to scale.

Hereinafter, a board having a conductor embedded therein will be called a “conductor-embedded circuit board”. Among conductor-embedded circuit boards, a circuit board having an inductor formed by multiple series-connected conductors embedded therein may be called an “inductor-embedded circuit board”. A conductor-embedded circuit board or an inductor-embedded circuit board may be simply called a “circuit board”.

Hereinafter, for the sake of description, the terms indicating directions, such as “top”, “bottom”, “right”, “left”, and “side”, are used based on a state in which a circuit board is typically used, but are not intended to limit the usage state or other states of the circuit board of the present disclosure. In the specification, “being perpendicular” refers to an angle within the range of 90°+10°, while “being parallel” refers to an angle within the range of +5°, for example. Additionally, an explanation of the shapes and the directions (orientations) will be given, and such shapes and directions include not only the exact shapes and directions, but also shapes and directions similar to the indicated shapes and directions. For example, a “rectangular cuboid” includes not only an exact rectangular cuboid, but also a substantially rectangular cuboid.

In the drawings, which will be explained below, the X axis, Y axis, and Z axis perpendicular to each other are schematically illustrated for reference. The Z axis is an axis corresponding to the thickness direction of a circuit board. In the following description, the X direction, Y direction, and Z direction refer to the respective axial directions and also each include two opposite directions (−X direction and +X direction, for example).

### First Exemplary Embodiment

### (Underlying Knowledge Forming Basis of Disclosure)

Extensive studies of the configuration of an inductor-embedded circuit board that can make a voltage regulator module thinner have been committed and the following findings have been obtained.

The amount of current required for processors used in data centers or other locations has been increasing due to the rapid rise in data traffic in information communication. With the increasing amount of current, it becomes necessary to suppress a transient voltage response (voltage fluctuations) caused by variations in the current (load fluctuations) of a processor.

If a voltage regulator module is disposed on a main surface (hereinafter called an opposing surface) of a system board opposite the other main surface on which a processor is disposed, the output terminal of the voltage regulator module and the input terminal of the processor can be arranged close to each other. This configuration suppresses the transient voltage response more effectively.

It is desirable that the voltage regulator module disposed on the opposing surface be thinner, as well as having functional components, such as inductors, embedded therein.

As discussed above, however, it may be difficult to reduce the thickness of the voltage regulator module disclosed in U.S. Patent Application Publication No. 2020/0111597. In U.S. Patent Application Publication No. 2020/0111597, a conductor is disposed in a magnetic core assembly to pass through a magnetic core in the thickness direction so as to form an inductor (see FIG. 46). With this structure, the height of the conductor within the magnetic core constrains the thickness of the magnetic core assembly. Additionally, two circuit board assemblies are required to be placed above and under the magnetic core assembly. The thicknesses of the two circuit board assemblies and those of connecting portions required for soldering between the assemblies further increase the thickness of the module.

According to an exemplary aspect of the disclosure, the thickness of an inductor-embedded circuit board can be reduced by dividing an inductor into multiple portions and embedding them into a circuit board and that using such an inductor-embedded circuit board can make a voltage regulator module thinner. Based on the exemplary aspect, the following exemplary embodiments are conceived.

### [Overall Configuration of Inductor-Embedded Circuit Board]

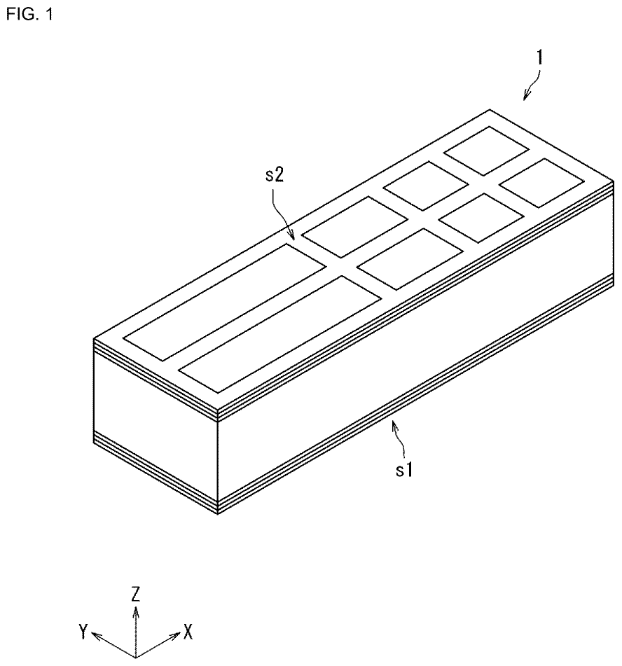

An overview of an inductor-embedded circuit board (hereinafter called the “circuit board”) according to a first exemplary embodiment of the disclosure will be described below with reference to FIGS. 1 through 5B.

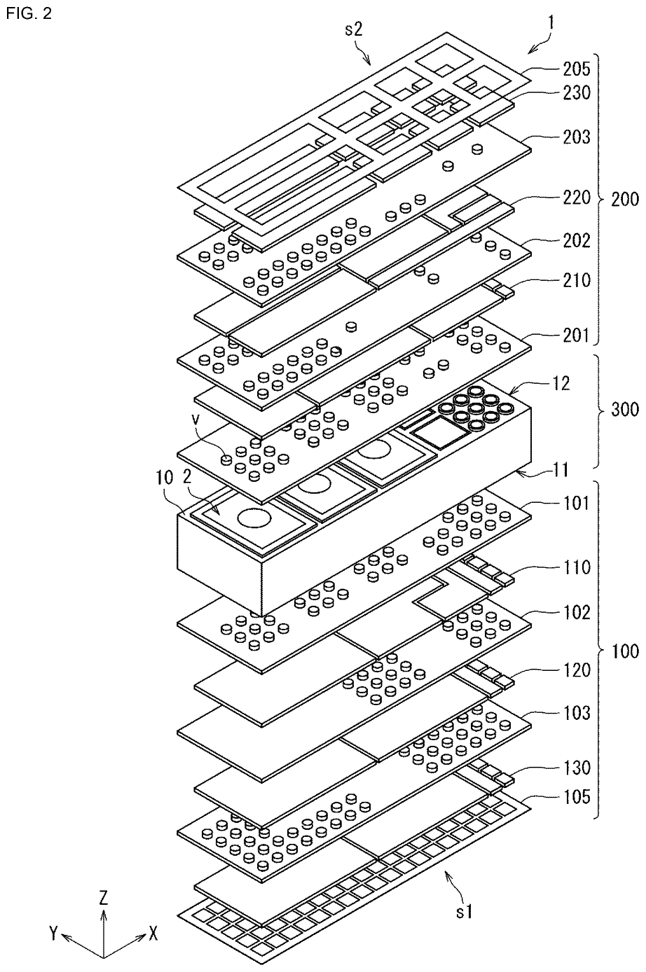

FIG. 1 is a schematic perspective view of a circuit board according to the first exemplary embodiment of the disclosure. FIG. 2 is a schematic exploded perspective view of the circuit board shown in FIG. 1.

A circuit board 1 is formed in a substantially rectangular cuboid, for example, as illustrated in FIG. 1. The circuit board 1 has a first main surface s1 and a second main surface s2, which is located on the side of the circuit board 1 opposite the first main surface s1 in the thickness direction (Z direction). In the individual drawings, for the sake of convenience, the thickness direction of the circuit board 1 is defined as the Z direction, the direction parallel with the long sides of the main surfaces s1 and s2 of the circuit board 1 is defined as the X direction, and the direction parallel with the short sides thereof is defined as the Y direction.

As illustrated in FIG. 2, the circuit board 1 includes a first wiring structure 100, a second wiring structure 200, and a component-embedded base body 300. In the thickness direction (Z direction) of the circuit board 1, the component-embedded base body 300 is positioned between the first wiring structure 100 and the second wiring structure 200. In this example, the first wiring structure 100 is located on the side of the component-embedded base body 300 facing the first main surface s1, while the second wiring structure 200 is located on the side of the component-embedded base body 300 facing the second main surface s2.

The component-embedded base body 300 includes a base member 10 (also called a “core base member”) and components, such as an inductor 2 and two-terminal capacitors, disposed inside the base member 10. In the specification, components disposed (embedded) inside the base member 10 may collectively be called “embedded components”.

The base member 10 is formed in a rectangular-cuboid shape, for example. The base member 10 has a first surface (bottom surface in this example) 11 and a second surface (top surface in this example) 12, which is positioned on the side of the base member 10 opposite the first surface 11 in the Z direction. The first surface 11 is located on the side of the base member 10 facing the first main surface s1 of the circuit board 1, while the second surface 12 is located on the side of the base member 10 facing the second main surface s2 of the circuit board 1.

Embedded components, such as the inductor 2 and the two-terminal capacitors, are disposed in through-holes formed in the base member 10.

The first wiring structure 100 is located on the first surface 11 of the base member 10. The first wiring structure 100 has a multilayer structure formed by multiple (three in this example) insulating layers 101 through 103 and multiple wiring layers 110 through 130 alternately stacked on each other in the thickness direction (−Z direction). In this example, from the side of the base member 10, the insulating layer 101, wiring layer 110, insulating layer 102, wiring layer 120, insulating layer 103, and wiring layer 130 are stacked in this order.

The second wiring structure 200 is located on the second surface 12 of the base member 10. The second wiring structure 200 has a multilayer structure formed by multiple (three in this example) insulating layers 201 through 203 and multiple wiring layers 210 through 230 alternately stacked on each other in the thickness direction (+Z direction). In this example, from the side of the base member 10, the insulating layer 201, wiring layer 210, insulating layer 202, wiring layer 220, insulating layer 203, and wiring layer 230 are stacked in this order.

The wiring layers 110 through 130 and 210 through 230 include electrodes, wiring patterns, terminals, and other elements. Within the insulating layers 101 through 103 and 201 through 203, multiple via-conductors v are disposed to electrically connect electrodes located above and under the via-conductors v.

The circuit board 1 may also include solder resist layers 105 and 205. The solder resist layer 105 is located on the side of the first wiring structure 100 facing the first main surface s1. The solder resist layer 205 is located on the side of the second wiring structure 200 facing the second main surface s2. The solder resist layers 105 and 205 are provided to reduce solder flowing that may occur when components and a BGA (Ball Grid Array) are mounted on the circuit board 1 by soldering.

### [Component-Embedded Base Body]

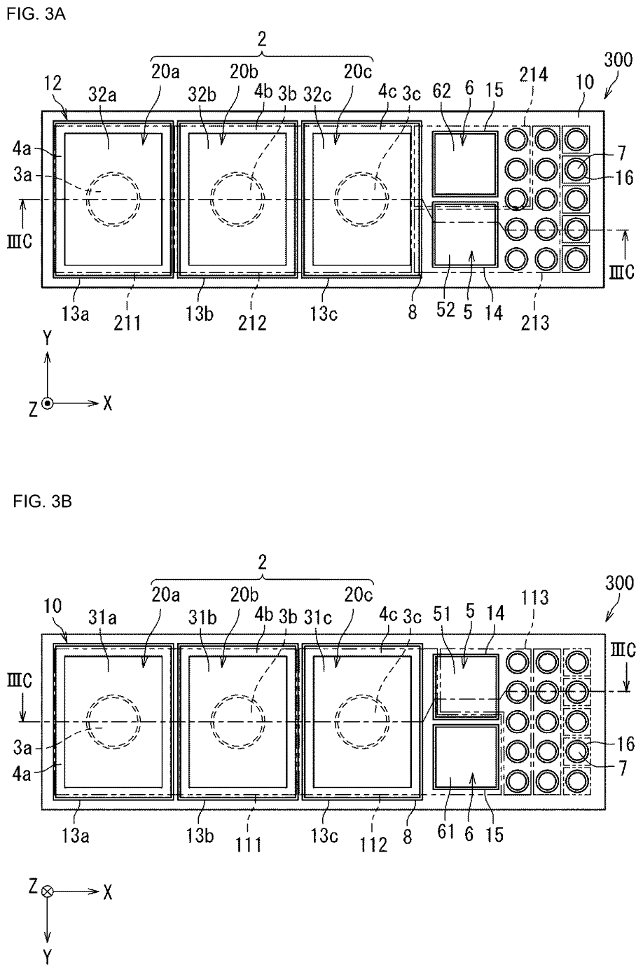

The greater detailed structure of the component-embedded base body 300 will be discussed below with reference to FIGS. 3A through 3C. FIGS. 3A and 3B are a schematic top view and a schematic bottom view, respectively, illustrating the component-embedded base body and some of the wiring layers. FIG. 3C is a schematic sectional view taken along line IIIC-IIIC in FIGS. 3A and 3B. In FIG. 3C, in addition to the component-embedded base body 300, the wiring layer 110 that is positioned closer to the base member 10 than the other wiring layers of the first wiring structure 100, and the wiring layer 210 that is positioned closer to the base member 10 than the other wiring layers of the second wiring structure 200, are shown. In FIGS. 3A and 3B, for easy understanding, the electrodes within the wiring layers 210 and 110 are indicated by the long dashed double-dotted lines.

As shown in FIGS. 3A through 3C, the component-embedded base body 300 includes the base member 10, the inductor 2, an input capacitor 5, an output capacitor 6, and multiple core through-conductors 7. The inductor 2 includes three inductor unit cells 20a through 20c.

The inductor unit cells 20a through 20c, input capacitor 5, output capacitor 6, and core through-conductors 7 are located (embedded) inside the base member 10.

As shown in FIG. 3C, the inductor 2 includes multiple (three in this example) conductors 3a through 3c and multiple (three in this example) magnetic members 4a through 4c. The conductors 3a through 3c extend to pass through the associated magnetic members 4a through 4c in the Z direction.

In the first exemplary embodiment, the conductor 3a and the magnetic member 4a form the inductor unit cell 20a. Likewise, the conductor 3b and the magnetic member 4b form the inductor unit cell 20b, and the conductor 3c and the magnetic member 4c form the inductor unit cell 20c. The inductor unit cells 20a through 20c are connected in series with each other to form one inductor. In the specification, when multiple inductors are connected in series with each other and function as one inductor, each of the series-connected inductors is called an “inductor unit cell”. That is, three components, which have been discussed as the inductor unit cells 20a through 20c, can individually function as one inductor when they are used separately.

The conductors 3a through 3c are arranged in the base member 10 with a distance therebetween in a plan view as seen in the Z direction (hereinafter may simply be called “in a plan view”). The conductors 3a through 3c each extend in the Z direction. In the example in FIGS. 3A through 3C, the conductors 3a through 3c are arranged in the X direction in this order in a plan view.

The magnetic member 4a is located around the conductor 3a to surround the peripheral surface of the conductor 3a. Likewise, the magnetic member 4b is located around the conductor 3b to surround the peripheral surface of the conductor 3b, and the magnetic member 4c is located around the conductor 3c to surround the peripheral surface of the conductor 3c. Among the magnetic members 4a through 4c, two adjacent magnetic members are separated from each other by a partition wall of the base member 10.

In the example in FIGS. 3A through 3C, the end portions (first end portions) of the conductors 3a and 3b facing the first surface 11 are electrically connected to each other by a first connection electrode 111 disposed within the wiring layer 110. The end portions (second end portions) of the conductors 3b and 3c facing the second surface 12 are electrically connected to each other by a second connection electrode 212 disposed within the wiring layer 210. With this configuration, the conductors 3a through 3c are connected in series with each other.

In the first exemplary embodiment, the inductor unit cells 20a through 20c are connected in series with each other by the first and second connection electrodes 111 and 212 so as to form the inductor 2. As a result of dividing the inductor into three or more (three in this example) inductor unit cells 20a through 20c and disposing them inside the base member 10, the thickness of the base member 10 required for accommodating the inductor 2 therein can be reduced while securing a desired inductance.

The base member 10 and the embedded components of the component-embedded base body 300 will be explained below in greater detail.

### (Base Member 10)

As illustrated in FIG. 3C, the base member 10 includes an inductor placement region r1 in which the inductor 2 is disposed, a capacitor placement region r2 in which the capacitors 5 and 6 are disposed, and a core through-conductor placement region r3 in which the core through-conductors 7 are disposed. In this example, the inductor placement region r1, capacitor placement region r2, and core through-conductor placement region r3 are arranged in the X direction in this order.

In the inductor placement region r1, through-holes 13a through 13c are formed to pass through the base member 10 from the first surface 11 to the second surface 12. Each of the through-holes 13a through 13c is a rectangular-prism-shaped opening, for example. In the example in FIGS. 3A and 3B, the through-holes 13a through 13c are arranged in the X direction and two adjacent through-holes are separated from each other by a partition wall of the base member 10. In the through-holes 13a through 13c, the inductor unit cells 20a through 20c, respectively, are disposed.

In the capacitor placement region r2, two through-holes 14 and 15 are formed to pass through the base member 10 from the first surface 11 to the second surface 12. Each of the through-holes 14 and 15 is a rectangular-prism-shaped opening, for example. In the example in FIGS. 3A and 3B, the through-holes 14 and 15 are arranged in the Y direction and are separated from each other by a partition wall of the base member 10. The input capacitor 5 is disposed in the through-hole 14, while the output capacitor 6 is disposed in the through-hole 15.

In the core through-conductor placement region r3, multiple through-holes 16 are formed in the base member 10. In the example in FIGS. 3A and 3B, fifteen columnar through-holes 16 are arranged in the X direction and the Y direction in a matrix form. The core through-conductors 7 are disposed in the respective through-holes 16. The core through-conductors 7 each serve as a connection conductor for electrically connecting a circuit within the first wiring structure 100 and a circuit within the second wiring structure 200.

### (Inductor Unit Cells 20a Through 20c)

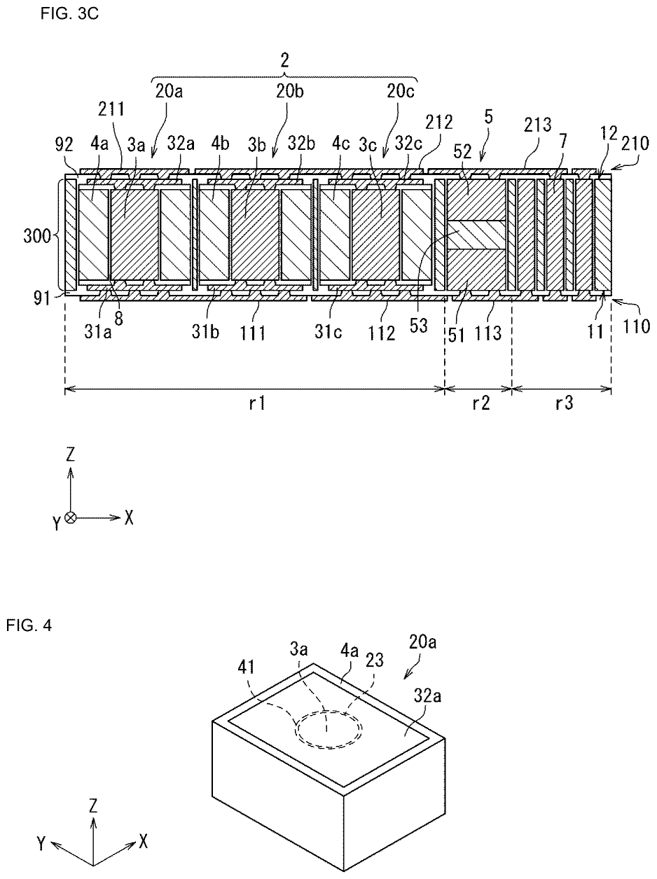

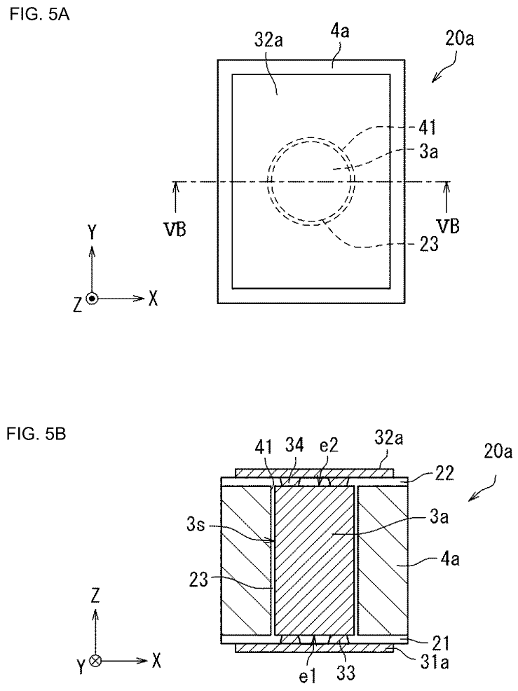

The detailed structure of the inductor unit cells will be explained below with reference to FIGS. 4 through 5B. FIG. 4 is a schematic perspective view of the inductor unit cell. FIG. 5A is a schematic top view of the inductor unit cell shown in FIG. 4. FIG. 5B is a schematic sectional view taken along line VB-VB in FIG. 5A. The inductor unit cells will be explained by taking the inductor unit cell 20a as an example.

The inductor unit cell 20a includes the magnetic member 4a, the conductor 3a that passes through the magnetic member 4a, a first electrode 31a electrically connected to the first end portion of the conductor 3a, and a second electrode 32a electrically connected to the second end portion of the conductor 3a.

The shape of the magnetic member 4a corresponds to that of the through-hole formed in the base member 10 and is a rectangular-prism shape (rectangular cuboid in this example), for instance. The magnetic member 4a has a magnetic through-hole 41 passing through the thickness direction (Z direction). The magnetic through-hole 41 has a cylindrical shape, for example. In a plan view, the magnetic through-hole 41 is positioned substantially at the center of the magnetic member 4a.

The conductor 3a is disposed inside the magnetic through-hole 41 and extends in the Z direction. The shape of the conductor 3a corresponds to that of the magnetic through-hole 41. In this example, the conductor 3a has a cylindrical shape and has a first end surface e1, a second end surface e2, and a peripheral surface 3s positioned between the end surfaces e1 and e2. The peripheral surface 3s of the conductor 3a is surrounded by the magnetic member 4a. The first and second end surfaces e1 and e2 each at least partially protrude from the magnetic member 4a. The first end surface e1 is a surface facing downward (facing in the −Z direction). The first end surface e1 may be substantially flush with the bottom surface of the magnetic member 4a. The second end surface e2 is a surface facing upward (facing in the +Z direction). The second end surface e2 may be substantially flush with the top surface of the magnetic member 4a.

The inductor unit cell 20a may also include a resin member that seals the conductor 3a inside the magnetic through-hole 41 of the magnetic member 4a. The resin member may include an insulating portion 23 located to fill a gap between the inner wall of the magnetic through-hole 41 and the conductor 3a. The resin member may cover the top surface and the bottom surface of the magnetic member 4a.

The first electrode 31a is disposed on the first end surface e1 of the conductor 3a with a first cell insulating portion 21 interposed therebetween. The first electrode 31a is electrically connected to the first end portion of the conductor 3a by at least one via-conductor 33 (multiple via-conductors 33 in this example) disposed in the first cell insulating portion 21. In the example in FIGS. 4 through 5B, one end portion of the via-conductor 33 is connected to the first electrode 31a, and the other end portion thereof is connected to the first end surface e1 of the conductor 3a.

The second electrode 32a is disposed on the second end surface e2 of the conductor 3a with a second cell insulating portion 22 interposed therebetween. The second electrode 32a is electrically connected to the second end portion of the conductor 3a by at least one via-conductor 34 (multiple via-conductors 34 in this example) disposed in the second cell insulating portion 22. In the example in FIGS. 4 through 5B, one end portion of the via-conductor 34 is connected to the second electrode 32a, and the other end portion thereof is connected to the second end surface e2 of the conductor 3a.

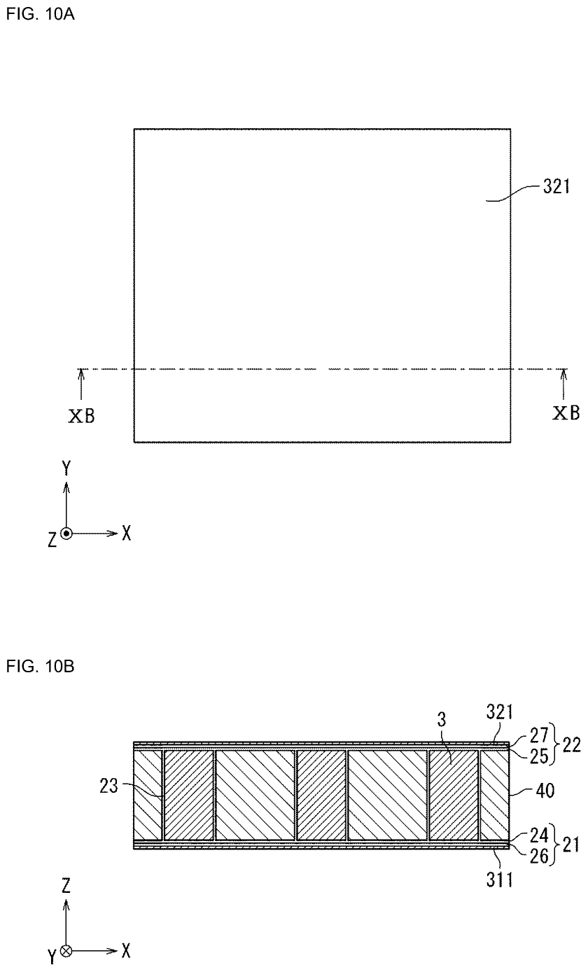

The first cell insulating portion 21 may include a portion of the resin member that covers the bottom surface of the magnetic member 4a (sealing insulating layer 24 shown in FIG. 10B). Likewise, the second cell insulating portion 22 may include a portion of the resin member that covers the top surface of the magnetic member 4a (sealing insulating layer 25 shown in FIG. 10B).

In a plan view, the first electrode 31a and the second electrode 32a may have a larger area than the conductor 3a. In the example in FIGS. 4 through 5B, in a plan view, the first electrode 31a covers the entirety of the first end surface e1 of the conductor 3a and at least part of the magnetic member 4a, while the second electrode 32a covers the entirety of the second end surface e2 of the conductor 3a and at least part of the magnetic member 4a.

The magnetic member 4a formed in a rectangular-cuboid shape has a size of 2.3 mm (X direction)×3 mm (Y direction)×1.8 mm (Z direction), for example. The diameter of the cylindrical magnetic through-hole 41 is 1.1 mm, for example. The cylindrical conductor 3a has a diameter of 1.0 mm and a thickness of 1.8 mm. The thickness of each of the first cell insulating portion 21 and the second cell insulating portion 22 is 30 μm, for example.

In the example in FIGS. 4 through 5B, the conductors 3a through 3c and the magnetic through-hole 41 have a cylindrical shape, but may have a rectangular-prism shape. It is not essential that the conductors 3a through 3c and the magnetic through-holes 41 are arranged in parallel with the Z direction if they extend from the top surfaces to the bottom surfaces of the magnetic members 4a through 4c.

As shown in FIGS. 3A through 3C, as in the inductor unit cell 20a, the inductor unit cell 20b includes the magnetic member 4b, the conductor 3b, a first electrode 31b, and a second electrode 32b, while the inductor unit cell 20c includes the magnetic member 4c, the conductor 3c, a first electrode 31c, and a second electrode 32c. The inductor unit cells 20b and 20c also have a structure similar to that of the inductor unit cell 20a discussed with reference to FIGS. 4 through 5B. In the first exemplary embodiment, the inductor unit cells 20a through 20c have the same size, but they may have different sizes.

### (Capacitors 5 and 6)

As illustrated in FIG. 3C, the input capacitor 5 is a two-terminal capacitor including a lower electrode 51, an upper electrode 52, and a dielectric member 53. The dielectric member 53 is located between the lower electrode 51 and the upper electrode 52 in the Z direction. The lower electrode 51 is positioned on the side of the dielectric member 53 facing the first surface 11, while the upper electrode 52 is positioned on the side of the dielectric member 53 facing the second surface 12. The input capacitor 5 is able to function as a bypass capacitor on an input power line of a voltage regulator module.

Likewise, the output capacitor 6 is a two-terminal capacitor including a lower electrode 61 (FIG. 3B), an upper electrode 62 (FIG. 3A), and a dielectric member located between the lower electrode 61 and the upper electrode 62 in the Z direction. The lower electrode 61 is positioned on the side of the dielectric member facing the first surface 11, while the upper electrode 62 is positioned on the side of the dielectric member facing the second surface 12. The output capacitor 6 is able to function as a bypass capacitor on an output power line of a voltage regulator module.

### (Sealing Member 8)

The component-embedded base body 300 also includes a sealing member 8 that seals the base member 10 having the inductor unit cells 20a through 20c, input capacitor 5, output capacitor 6, and core through-conductors 7 embedded therein. In the example in FIG. 3C, the sealing member 8 is provided in gaps between the inner walls of the through-holes 13a through 13c and 14 through 16 and the components disposed in the through-holes. The sealing member 8 may be provided on the first surface 11 and the second surface 12 of the base member 10.

### [Wiring Layers 110 and 210]

The structure of the wiring layers 110 and 210 respectively disposed on the first surface 11 and the second surface 12 of the base member 10 will be explained below with reference to FIGS. 3A through 3C.

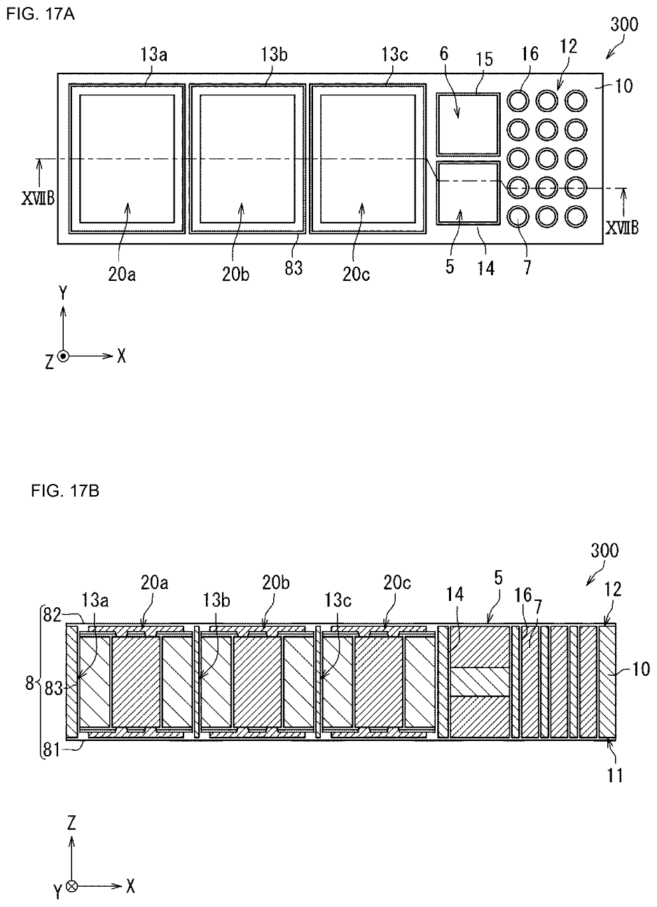

The wiring layer 110 (may also be called a “first wiring layer”) is disposed on the first surface 11 of the base member 10 with a first insulator 91 interposed therebetween. The “first insulator” is an insulating portion located between the wiring layer 110 and the first surface 11 of the base member 10. In the first exemplary embodiment, the first insulator 91 includes part of the sealing member 8 (lower insulating layer 81 shown in FIG. 17B) of the component-embedded base body 300 and the insulating layer 101 (FIG. 2) that is positioned closer to the base member 10 than the other insulating layers of the first wiring structure 100.

The wiring layer 210 (may also be called a “second wiring layer”) is disposed on the second surface 12 of the base member 10 with a second insulator 92 interposed therebetween. The “second insulator” is an insulating portion located between the wiring layer 210 and the second surface 12 of the base member 10. In the first exemplary embodiment, the second insulator 92 includes part of the sealing member 8 (upper insulating layer 82 shown in FIG. 17B) of the component-embedded base body 300 and the insulating layer 201 (FIG. 2) that is positioned closer to the base member 10 than the other insulating layers of the second wiring structure 200.

Within the first insulator 91, multiple via-conductors are formed to electrically connect the components within the base member 10 and the electrodes in the wiring layer 110. Likewise, within the second insulator 92, multiple via-conductors are formed to electrically connect the components within the base member 10 and the electrodes in the wiring layer 210. Regarding the number of via-conductors to be associated with one electrode of an embedded component, one or more via-conductors are associated with one electrode of an embedded component. Preferably, multiple via-conductors are associated with one electrode to increase the connection area.

### (Wiring Layer 110)

As illustrated in FIGS. 3B and 3C, the wiring layer 110 includes the first connection electrode 111, a first inductor connection electrode 112 connected to the output terminal of the inductor, and a first input capacitor connection electrode 113. These electrodes 111 through 113 are arranged with a distance therebetween.

The first connection electrode 111 electrically connects the end portions (first end portions) of the conductors 3a and 3b facing the first surface 11. In the example in FIGS. 3B and 3C, the first connection electrode 111 is electrically connected to the first electrode 31a of the inductor unit cell 20a and the first electrode 31b of the inductor unit cell 20b by via-conductors within the first insulator 91.

The planar shape of the first connection electrode 111 is rectangular, for example. In a plan view, the first connection electrode 111 may cover the entirety of the conductors 3a and 3b, and more preferably, the entirety of the first electrodes 31a and 31b.

The first inductor connection electrode 112 electrically connects the first end portion of the conductor 3c, which is the output terminal of the inductor 2, to the lower electrode 61 of the output capacitor 6. In the example in FIGS. 3B and 3C, the first inductor connection electrode 112 is electrically connected to the first electrode 31c of the inductor unit cell 20c and the lower electrode 61 of the output capacitor 6 by via-conductors within the first insulator 91.

The first input capacitor connection electrode 113 is electrically connected to the lower electrode 51 of the input capacitor 5 and some of the core through-conductors 7 by via-conductors within the first insulator 91.

### (Wiring Layer 210)

As illustrated in FIGS. 3A and 3C, the wiring layer 210 includes a second inductor connection electrode 211 connected to the input terminal of the inductor, the second connection electrode 212, a second input capacitor connection electrode 213, and an output capacitor connection electrode 214. These electrodes 211 through 214 are arranged with a distance therebetween.

The second inductor connection electrode 211 is electrically connected to the second end portion of the conductor 3a, which is the input terminal of the inductor 2. In the example in FIGS. 3A and 3C, the second inductor connection electrode 211 is electrically connected to the second electrode 32a of the inductor unit cell 20a by via-conductors within the second insulator 92.

The second connection electrode 212 electrically connects the end portions (second end portions) of the conductors 3b and 3c facing the second surface 12. In the example in FIGS. 3A and 3C, the second connection electrode 212 is electrically connected to the second electrode 32b of the inductor unit cell 20b and the second electrode 32c of the inductor unit cell 20c by via-conductors within the second insulator 92.

The planar shape of the second connection electrode 212 is rectangular, for example. In a plan view, the second connection electrode 212 may cover the entirety of the conductors 3b and 3c, and more preferably, the entirety of the second electrodes 32b and 32c.

The second input capacitor connection electrode 213 is electrically connected to the upper electrode 52 of the input capacitor 5 and some of the core through-conductors 7 by via-conductors within the second insulator 92. This configuration electrically connects the upper electrode 52 of the input capacitor 5 to an input terminal Vin, which is located opposite the upper electrode 52 with the base member 10 interposed therebetween, by the core through-conductors 7 electrically connected to the second input capacitor connection electrode 213.

The output capacitor connection electrode 214 is electrically connected to the upper electrode 62 of the output capacitor 6 and some of the core through-conductors 7 by via-conductors within the second insulator 92. This configuration electrically connects the upper electrode 62 of the output capacitor 6 to a ground terminal GND, which is located opposite the upper electrode 62 with the base member 10 interposed therebetween, by the core through-conductors 7 electrically connected to the output capacitor connection electrode 214.

### [Circuit Configuration of Voltage Regulator Module]

The circuit configuration of the circuit board 1 according to the first exemplary embodiment will be described below. An explanation will be given through illustration of an example in which the circuit board 1 is applied to a buck switching regulator (buck converter).

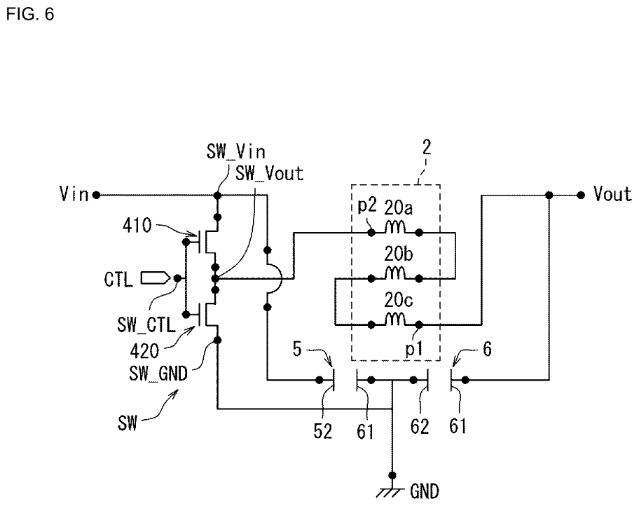

FIG. 6 is a diagram illustrating the basic circuit configuration of a voltage regulator module (buck converter). The voltage regulator module includes the circuit board 1 of the first exemplary embodiment and a switching device SW.

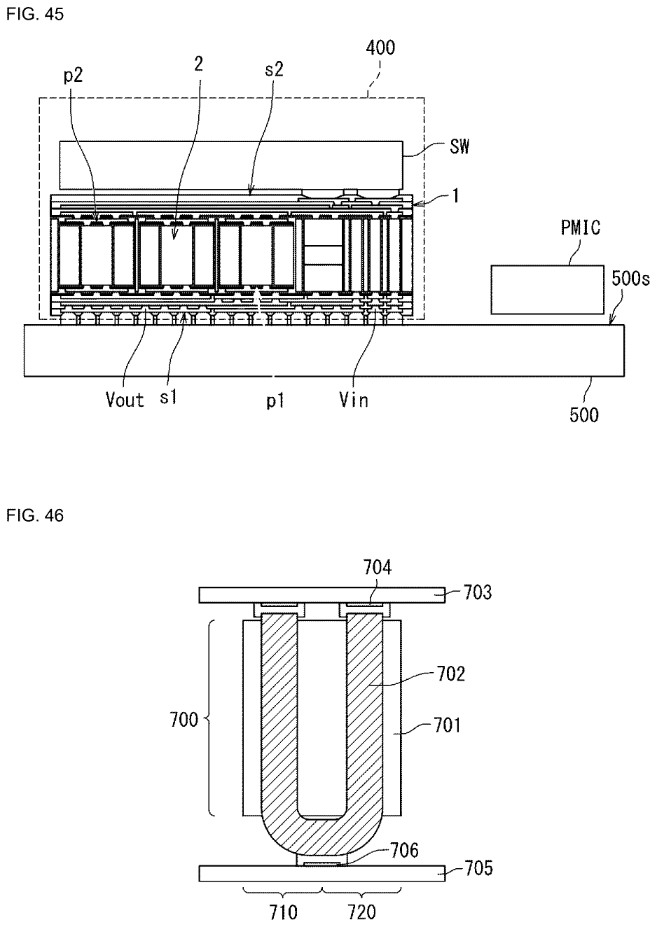

The switching device SW includes MOSFETS 410 and 420, a switch input terminal SW_Vin, a switch output terminal SW_Vout, a switch GND terminal SW_GND, and a switch control terminal SW_CTL. Instead of MOSFETS, another type of switching element may be used. The switching device SW is disposed on the first main surface of the circuit board 1, for example (see FIG. 45).

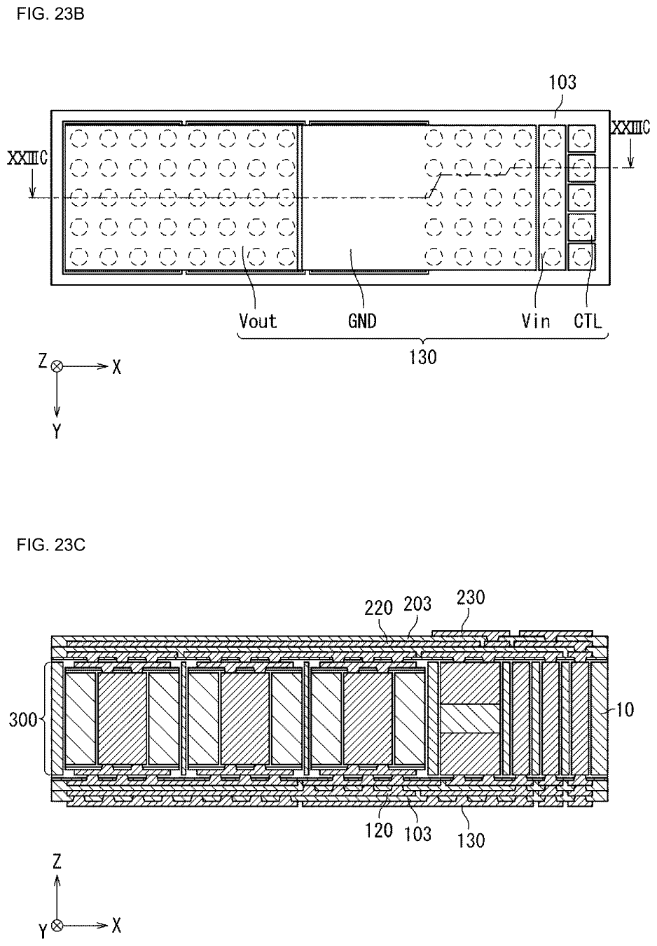

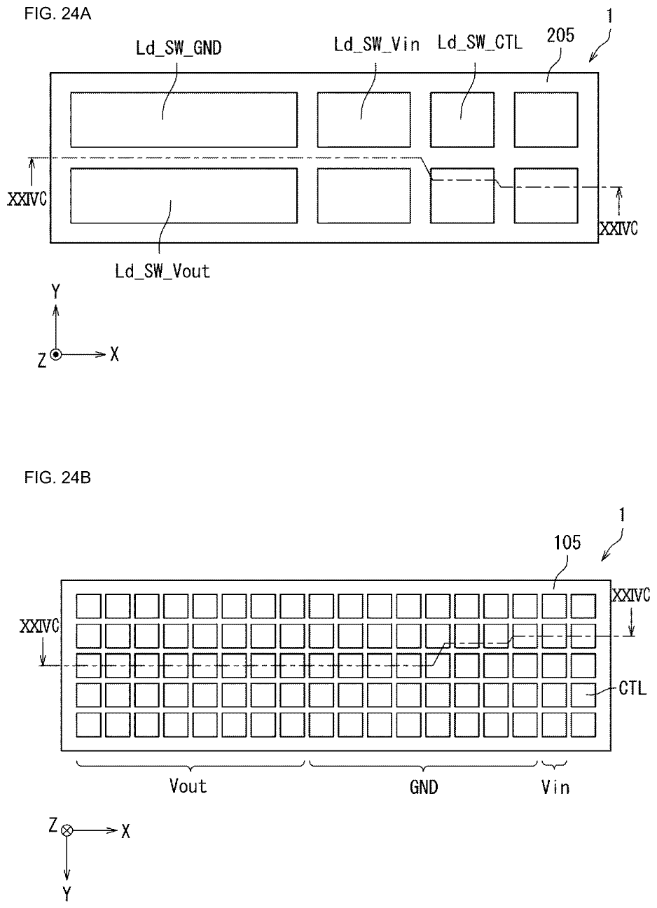

The inductor 2, input capacitor 5, and output capacitor 6 forming the circuit shown in FIG. 6 are embedded in the circuit board 1. A control terminal CTL, an input terminal Vin, an output terminal Vout, and a ground terminal GND are formed on the wiring layer 230, which is positioned on the topmost layer of the circuit board 1, for example (see FIG. 23A). Terminal lands for the terminals of the switching device SW are formed on the wiring layer 130, which is positioned on the bottommost layer of the circuit board 1 (see FIG. 23B).

In the circuit shown in FIG. 6, the MOSFET 410 on the high side is connected to the input terminal Vin, while the MOSFET 420 on the low side is connected to the terminal of the MOSFET 410 closer to the GND terminal. An input voltage is applied from the input terminal Vin to the switch input terminal SW_Vin.

The inductor 2 is formed by connecting the inductor unit cells 20a through 20c in series with each other in this order. An input terminal p2 of the inductor 2 is connected to the switch output terminal SW_Vout.

The input capacitor 5 is shunt-connected to the switch input terminal SW_Vin. The upper electrode 52 of the input capacitor 5 is connected to the switch input terminal SW_Vin, while the lower electrode 51 is connected to the ground terminal GND.

The output capacitor 6 is shunt-connected to the output terminal Vout. The lower electrode 61 of the output capacitor 6 is connected to the output terminal Vout, while the upper electrode 62 is connected to the ground terminal GND.

With this circuit configuration, in the switching device SW, a pulse waveform, which is generated by alternately switching the MOSFETs 410 and 420 between ON and OFF, is smoothed by the inductor 2 and the output capacitor 6. As a result, a desired output voltage is generated and is output from the output terminal Vout.

### [Materials of Elements]

As a magnetic material to form the magnetic members (magnetic elements) 4a through 4c of the inductor unit cells 20a through 20c, any material having magnetic permeability, such as a metal magnetic material or sintered ferrite, may be used. Desirably, the magnetic material is a composite material of metal magnetic powder and an organic material. The reasons for this are as follows, for example. Magnetostriction of a metal magnetic material is smaller than that of sintered ferrite. Characteristic degradation of a metal magnetic material caused by external stress when the magnetic members 4a through 4c are buried in the base member 10 is thus small. Additionally, a composite state of metal magnetic powder and an organic material can improve DC bias superposition characteristics and also implement easy processing to form through-holes. Using an organic material can elastically absorb external stress when the magnetic members 4a through 4c are embedded in the base member 10, for example, thereby reducing internal stress applied to the metal magnetic powder. Because of the above-described reasons, a decrease in the inductance caused by magnetostriction can be suppressed. Examples of the metal magnetic material are Fe, Co, Ni, and alloys containing these elements (FeSi alloys, such as FeSiCr, FeSiAl, FeCo alloys, and NiFe alloys, such as NiFe), and amorphous alloys thereof, which are all soft magnetic materials. An example of the organic material is an organic insulating material composed of epoxy resin, polyimide, liquid crystal polymer, or bismaleimide.

The conductors 3a through 3c that pass through the magnetic members 4a through 4c and the core through-conductors 7 are made of a metal material having a low volume resistivity. As such a metal material, a material mainly composed of Cu is desirably used in terms of easy processing and the material compatibility with the conductors used for the wiring layers (circuit layers).

The base member 10, first and second cell insulating portions 21 and 22, sealing member 8, and the insulating layers 101 through 103 and 201 through 203 forming the printed circuit board are composed of a thermosetting resin and an inorganic filler or a woven fiber of an inorganic material. Examples of the thermosetting resin are epoxy resin, acrylic resin, and polyimide. The inorganic filler or the woven fiber of an inorganic material may be made of SiO₂, for example.

The wiring layers 110 through 130 and 210 through 230 forming the circuit board 1 are metal layers composed of Cu as a main material, for example. Likewise, the via-conductors disposed in the insulating layers 101 through 103 and 201 through 203 are metal conductors composed of Cu as a main material. For wiring layers exposed through the openings of the solder resist layers 105 and 205, a surface coating of AuNi may be formed or rust-prevention treatment may be performed on the wiring layers to improve corrosion resistance, rust prevention, or solder wettability.

### [Manufacturing Method for Circuit Board]

The manufacturing method for the circuit board 1 has the following steps:
(1) a step of preparing components, such as inductor unit cells and two-terminal capacitors;
(2) a step of embedding components, such as the inductor unit cells, in a base member; and
(3) a step of forming wiring structures on the front side and the back side of the base member.

The step (1) of preparing components includes a step of manufacturing the inductor unit cells. The individual steps will be explained sequentially.

### (Step of Manufacturing Inductor Unit Cells)

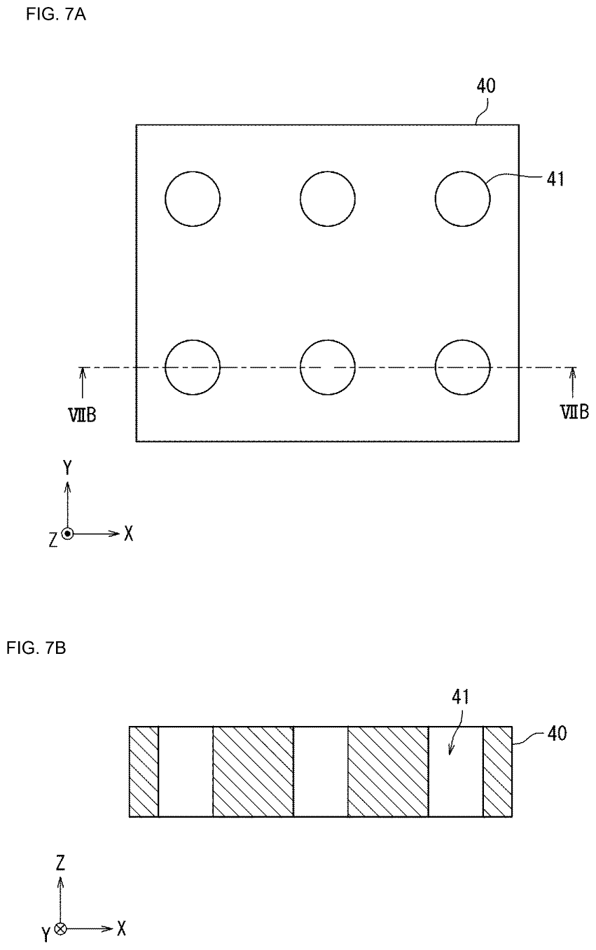

FIGS. 7A through 14A are schematic top views for explaining a method for manufacturing inductor unit cells. FIGS. 7B through 14B are schematic sectional views taken along lines VIIB-VIIB through XIVB-XIBV in FIGS. 7A through 14A, respectively.

As illustrated in FIGS. 7A and 7B, a magnetic block 40, which is to form magnetic members (magnetic elements) of inductor unit cells, is formed by pressure molding, for example. Then, multiple (six in this example) magnetic through-holes 41 are formed by drilling, for example, in the magnetic block 40. In a plan view, the magnetic through-holes 41 are arranged with a distance therebetween.

In this example, for instance, a planar magnetic block 40 having a thickness of 1.8 mm is molded by hot pressing. Then, cylindrical magnetic through-holes 41 having a diameter of 1.1 mm are formed in the magnetic block 40 by using a drill (having a diameter of 1.1 mmφ). After the magnetic block 40 is molded, it may be processed to a desired thickness by grinding or another method.

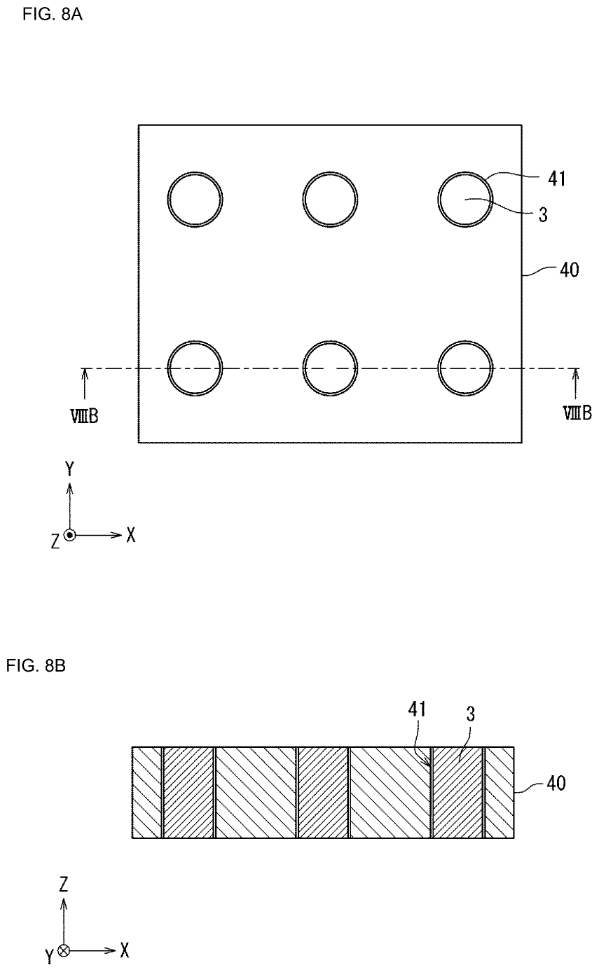

Then, as shown in FIGS. 8A and 8B, conductors 3 are placed within the respective magnetic through-holes 41 of the magnetic block 40.

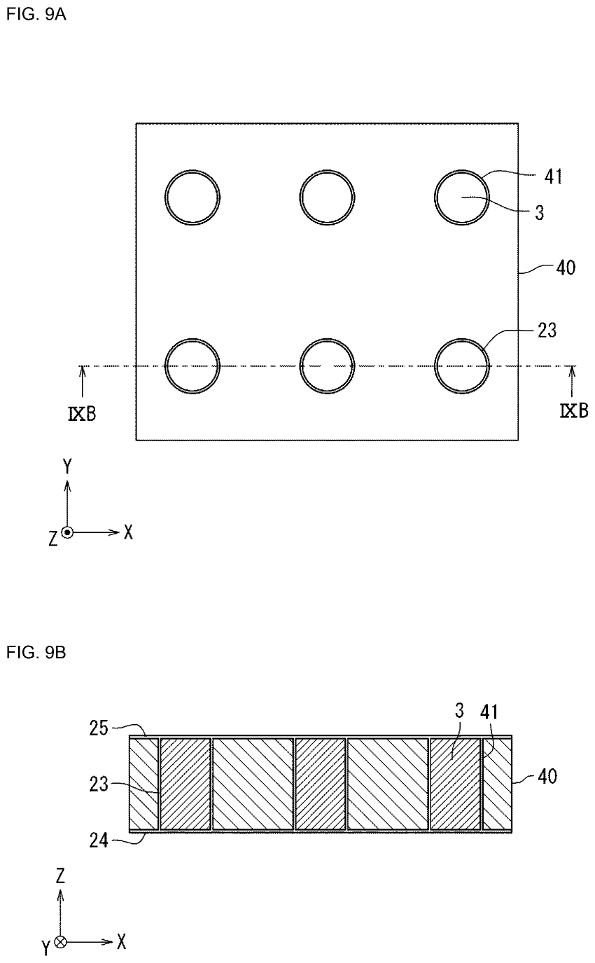

Then, as shown in FIGS. 9A and 9B, with the use of a resin material, a resin member is formed starting from the top surface and the bottom surface of the magnetic block 40 to seal gaps between the inner walls of the magnetic through-holes 41 and the peripheral surfaces of the conductors 3. In this example, as the resin material, a thermosetting resin composed mainly of epoxy is used. The resin member includes an insulating portion 23 located between the inner walls of the magnetic through-holes 41 and the conductors 3, a sealing insulating layer 24 that covers the bottom surfaces of the magnetic block 40 and the conductors 3, and a sealing insulating layer 25 that covers the top surfaces of the magnetic block 40 and the conductors 3. After the magnetic block 40 and the conductors 3 are sealed with the resin member, the thickness of the sealing insulating layers 24 and 25 may be adjusted by grinding or another method.

Then, as illustrated in FIGS. 10A and 10B, an insulating layer 26 is formed on the bottom surface of the magnetic block 40, and then, an underlying conductor layer 311 is formed on the insulating layer 26. Likewise, an insulating layer 27 is formed on the top surface of the magnetic block 40, and then, an underlying conductor layer 321 is formed on the insulating layer 27. As the insulating layers 26 and 27, layers made of a thermosetting resin and an inorganic filler or a woven fiber of an inorganic material are formed. In the specification, the insulating portion 21 including the insulating layer 26 and the sealing insulating layer 24 will be called a “first cell insulating portion”, while the insulating portion 22 including the insulating layer 27 and the sealing insulating layer 25 will be called a “second cell insulating portion”.

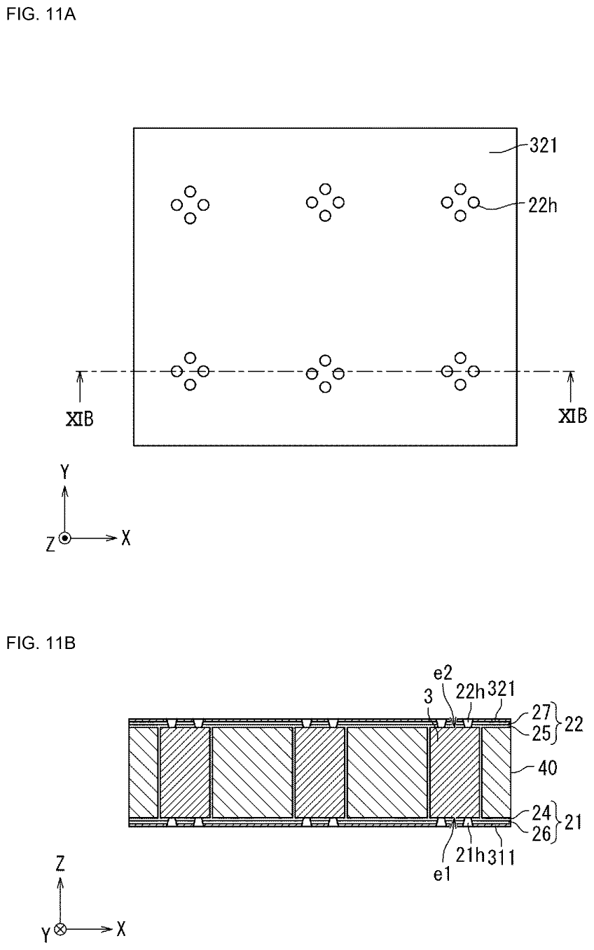

Then, as illustrated in FIGS. 11A and 11B, pattern etching is partially performed on the underlying conductor layers 311 and 321 to form multiple openings. In a plan view, the openings are formed to overlap the end surfaces e1 and e2 of the conductors 3. Then, the first and second cell insulating portions 21 and 22 which are exposed by the provision of the openings are removed by a laser drill or another machine. As a result, on the bottom surface of the magnetic block 40, via-holes 21h which expose the first end surfaces e1 of the conductors 3 are formed in the first cell insulating portion 21 and the underlying conductor layer 311. Likewise, on the top surface of the magnetic block 40, via-holes 22h which expose the second end surfaces e2 of the conductors 3 are formed in the second cell insulating portion 22 and the underlying conductor layer 321.

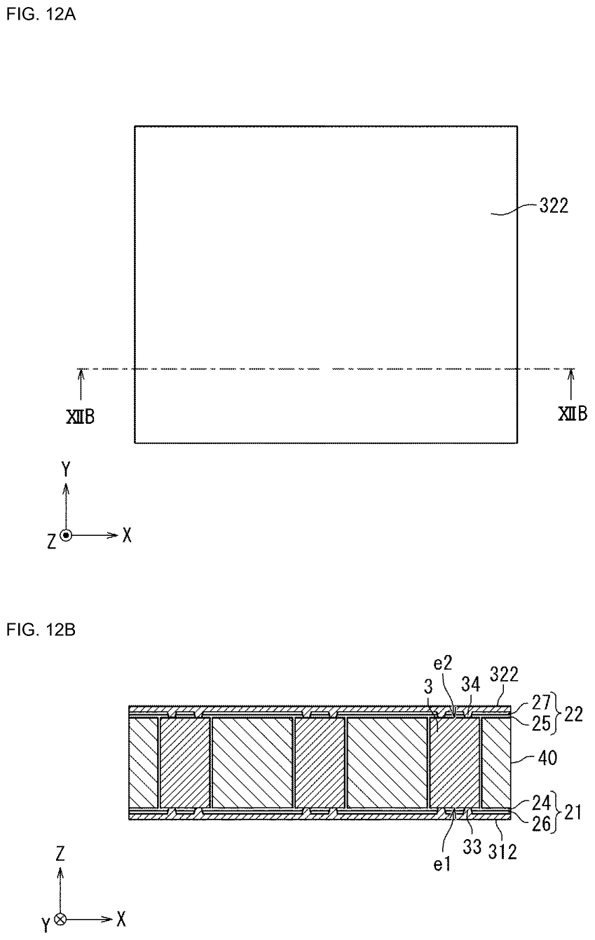

Then, electroless plating and electrolytic plating are applied to the surfaces of the underlying conductor layers 311 and 321 and the surfaces of the conductors 3 exposed by the provision of the via-holes 21h and 22h. As a result, via-conductors 33 are formed inside the via-holes 21h, and a conductor layer 312 is formed on the first cell insulating portion 21, as shown in FIGS. 12A and 12B. The conductor layer 312 is electrically connected to the first end surfaces e1 of the conductors 3 by the via-conductors 33. The conductor layer 312 includes the underlying conductor layer 311 and a plated layer. Likewise, via-conductors 34 are formed inside the via-holes 22h, and a conductor layer 322 is formed on the second cell insulating portion 22. The conductor layer 322 is electrically connected to the second end surfaces e2 of the conductors 3 by the via-conductors 34.

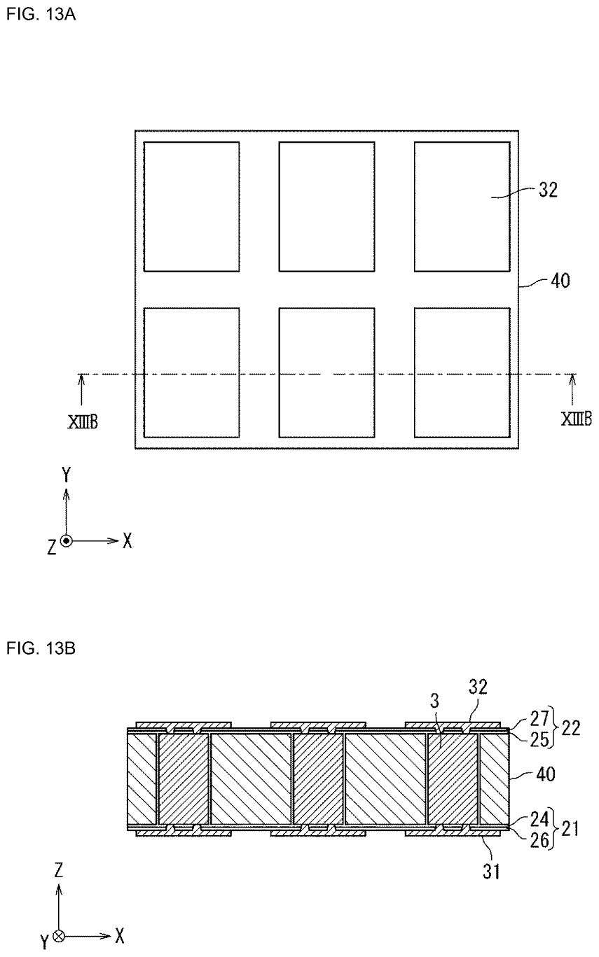

Then, each of the conductor layers 312 and 322 is patterned into a desired shape. As a result, multiple first electrodes 31 arranged with a distance therebetween are formed from the conductor layer 312, as shown in FIGS. 13A and 13B. Likewise, multiple second electrodes 32 arranged with a distance therebetween are formed from the conductor layer 322. Each of the first electrodes 31 and a corresponding second electrode 32 oppose each other with a corresponding one of the conductors 3 interposed therebetween in the Z direction.

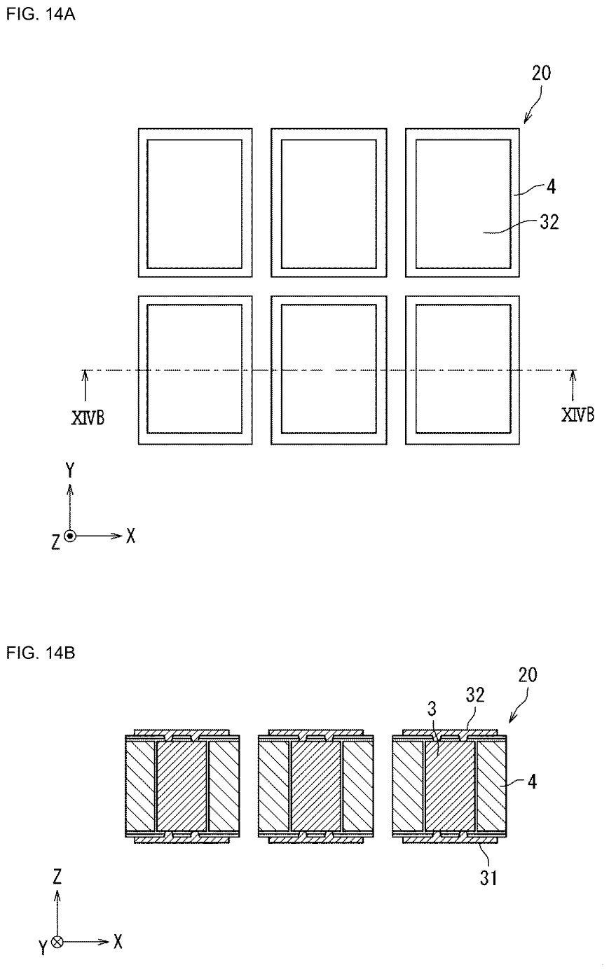

Then, as illustrated in FIGS. 14A and 14B, the magnetic block 40 is divided by a dicer or another machine so as to obtain multiple (six in this example) inductor unit cells 20. Each inductor unit cell 20 includes one inductor 3, a magnetic member 4 located around the inductor 3, and first and second electrodes 31 and 32 electrically connected to the inductor 3. Three of the six inductor unit cells 20 manufactured by the above-described method are used as the inductor unit cells 20a through 20c to be embedded in a circuit board.

### (Embedding Step)

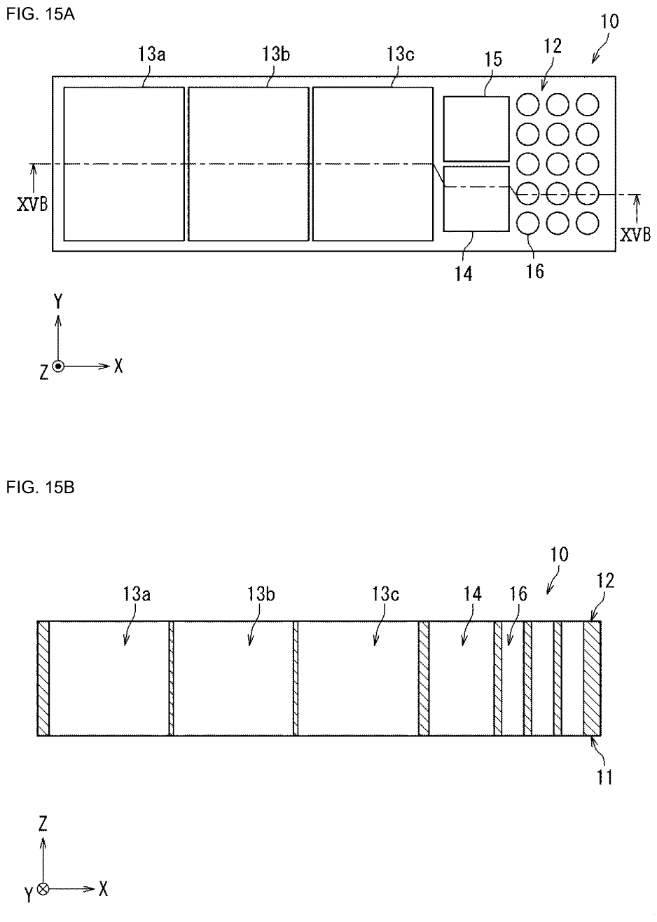

FIGS. 15A through 17A are schematic top views for explaining a method for manufacturing a circuit board (embedding step). FIGS. 15B through 17B are schematic sectional views taken along lines XVB-XVB, XVIB-XVIB, and XVIIB-XVIIB in FIGS. 15A through 17A, respectively.

As illustrated in FIGS. 15A and 15B, a planar base member 10 having a first surface 11 and a second surface 12 is prepared. The base member 10 is composed of a thermosetting resin and an inorganic filler or a woven fiber of an inorganic material, for example. In the base member 10, through-holes (core through-holes) 13a through 13c, 14, and 15, and multiple through-holes 16 are formed at predetermined positions by drilling or routing.

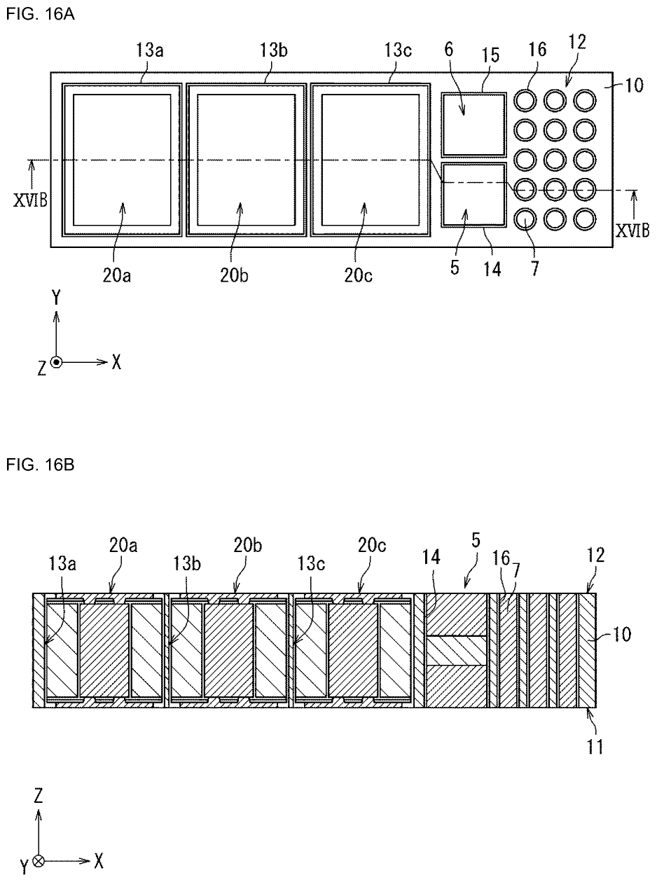

Then, as illustrated in FIGS. 16A and 16B, the inductor unit cells 20a through 20c are placed in the through-holes 13a through 13c, respectively. Likewise, a two-terminal capacitor, which is to form the input capacitor 5, is placed in the through-hole 14, while a two-terminal capacitor, which is to form the output capacitor 6, is placed in the through-hole 15. The core through-conductors 7 are placed in the respective through-holes 16.

Then, as illustrated in FIGS. 17A and 17B, components, such as the inductor unit cells 20a through 20c, are embedded in the base member 10 with a sealing member 8. As the sealing member 8, an insulating layer made of a thermosetting resin and an inorganic filler or a woven fiber of an inorganic material is formed. The sealing member 8 includes a lower insulating layer 81 positioned on the first surface 11 of the base member 10 and an upper insulating layer 82 positioned on the second surface 12 of the base member 10. The sealing member 8 also includes an insulating portion 83 located to fill gaps between the inner walls of the through-holes 13a through 16 and the peripheral surfaces of the individual embedded components. After the sealing member 8 is formed, the thickness of the sealing member 8 (lower insulating layer 81 and upper insulating layer 82) may be adjusted by grinding or another method. In this manner, the component-embedded base body 300 having the inductor unit cells 20a through 20c, the capacitors 5 and 6, and the core through-conductors 7 embedded therein is formed.

### (Wiring Structure Forming Step)

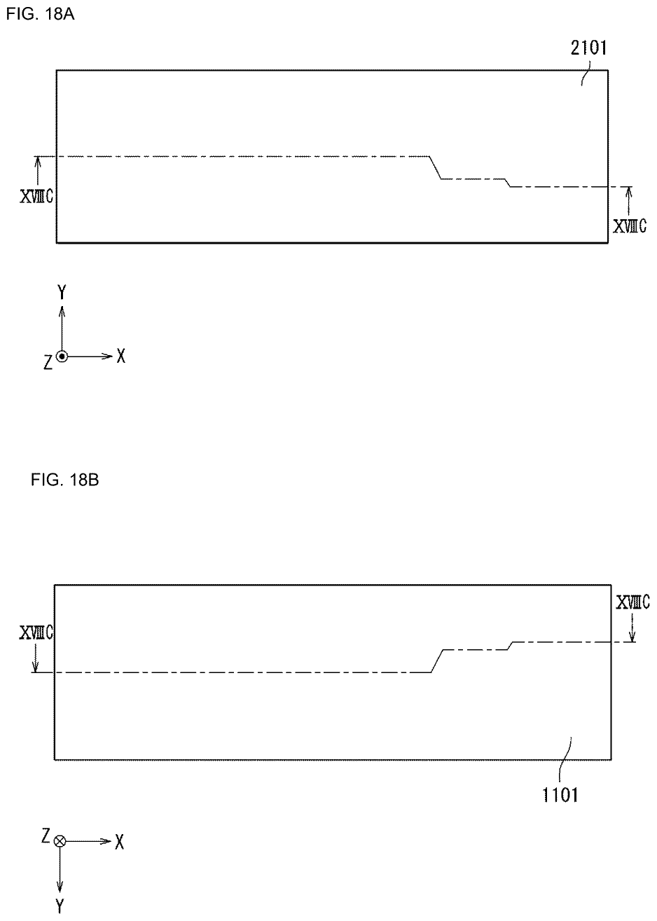

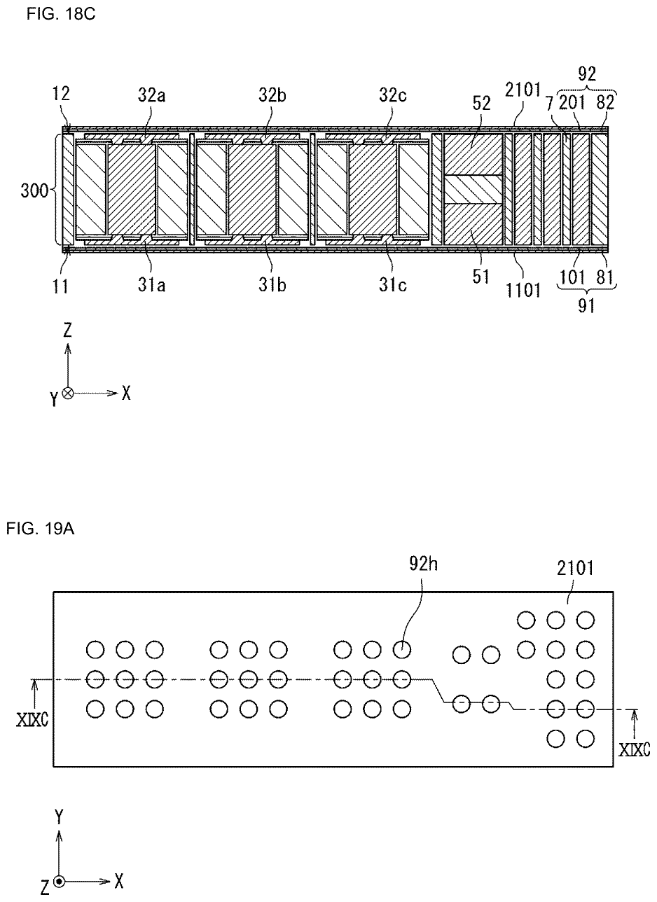

FIGS. 18A through 24A are schematic top views for explaining a method for manufacturing a circuit board (wiring structure forming step). FIGS. 18B through 24B are bottom views corresponding to FIGS. 18A through 24A, respectively. FIGS. 18C through 24C are schematic sectional views taken along lines XVIIIC-XVIIIC through XXIVC-XXIVC in FIGS. 18A through 24A, respectively.

The step of forming wiring layers that form wiring structures includes the following steps, for example:
(i) a step of forming insulating layers and underlying conductor layers;
(ii) a step of forming openings in the underlying conductor layers;
(iii) a step of forming via-holes by removing portions of the insulating layers positioned in the openings;
(iv) a step of forming via-conductors and obtaining conductor layers, which are electrically connected to electrodes by the via-conductors, by forming overlying conductor layers (plated layers, for example) in the via-holes and on the underlying conductor layers; and
(v) a step of obtaining wiring layers including multiple electrodes, wiring patterns, terminals, and other elements by patterning the conductor layers.
   <Step (i)>

As illustrated in FIGS. 18A through 18C, an insulating layer 101 is formed on the first surface 11 of the component-embedded base body 300, and then, an underlying conductor layer 1101 made of a Cu foil is formed. Likewise, an insulating layer 201 is formed on the second surface 12 of the base member 10, and then, an underlying conductor layer 2101 made of a Cu foil is formed. The insulating layers 101 and 201 are made of a thermosetting resin and an inorganic filler or a woven fiber of an inorganic material, for example.

In the first exemplary embodiment, an insulating portion (hereinafter called a “first insulator”) 91 located between the underlying conductor layer 1101 and the electrodes (first electrodes 31a through 31c, for example) of embedded components includes the insulating layer 101 and a lower insulating layer 81. An insulating portion (hereinafter called a “second insulator”) 92 positioned between the underlying conductor layer 2101 and the electrodes (second electrodes 32a through 32c, for example) of embedded components includes the insulating layer 201 and an upper insulating layer 82.

<Steps (ii) and (iii)>

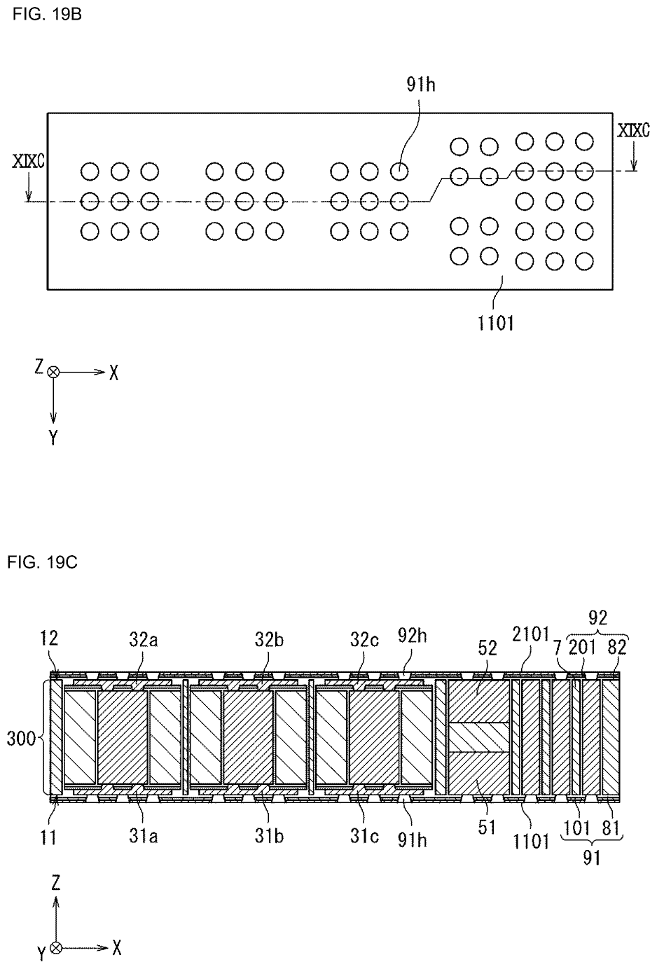

Then, as illustrated in FIGS. 19A through 19C, pattern etching is performed on each of the underlying conductor layers 1101 and 2101 so as to form multiple openings (step (ii)). Then, the first and second insulators 91 and 92 which are exposed by the openings are removed by a laser drill or another machine (step (iii)). As a result, on the first surface 11 of the base member 10, multiple via-holes 91h are formed in the first insulator 91 and the underlying conductor layer 1101. Each via-hole 91h exposes part of the electrode of a corresponding embedded component facing the first surface 11. Likewise, on the second surface 12 of the base member 10, multiple via-holes 92h are formed in the second insulator 92 and the underlying conductor layer 2101. Each via-hole 92h exposes part of the electrode of a corresponding embedded component facing the second surface 12.

<Step (iv)>

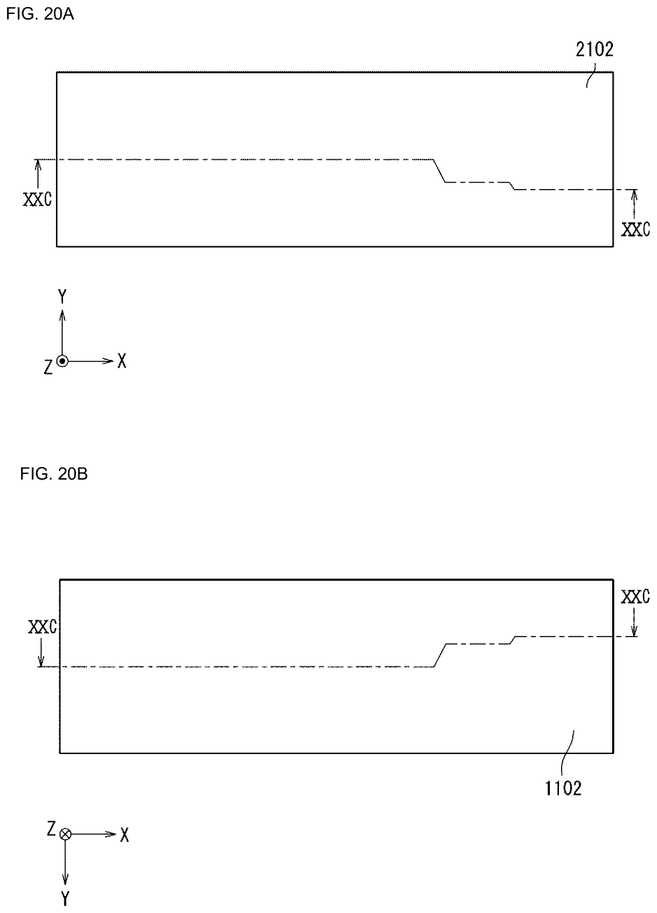

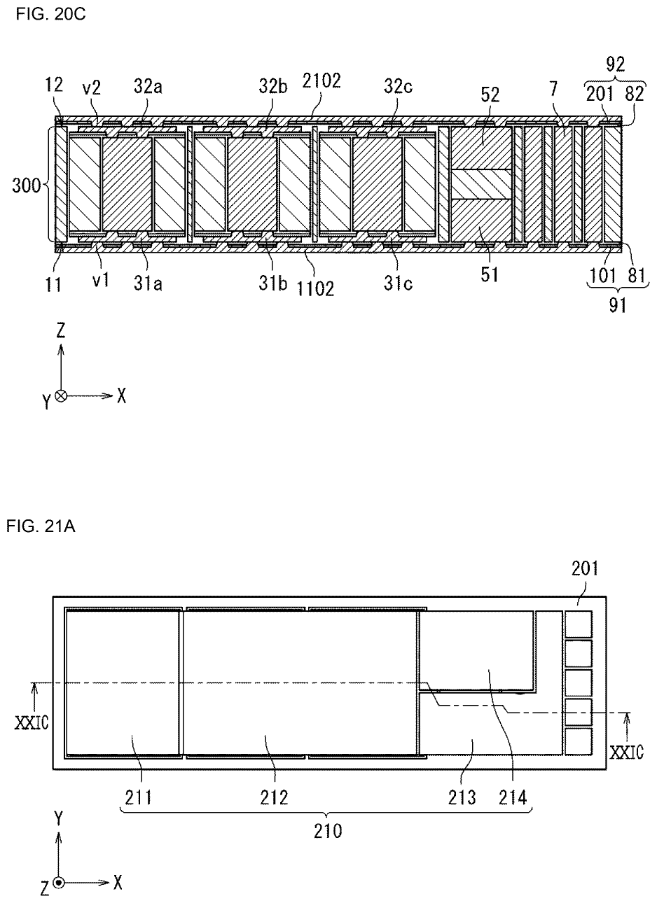

Then, electroless plating and electrolytic plating are applied to the surfaces of the underlying conductor layers 1101 and 2101 and the surfaces of the electrodes of embedded components which are exposed by the provision of the via-holes 91h and 92h. As a result, as shown in FIGS. 20A through 20C, multiple via-conductors v1 are formed inside the via-holes 91h, and a conductor layer 1102 is formed on the first insulator 91. The conductor layer 1102 is electrically connected to the embedded components by the via-conductors v1. Likewise, multiple via-conductors v2 are formed inside the via-holes 92h, and a conductor layer 2102 is formed on the second insulator 92. The conductor layer 2102 is electrically connected to the embedded components by the via-conductors v2.

<Step (v)>

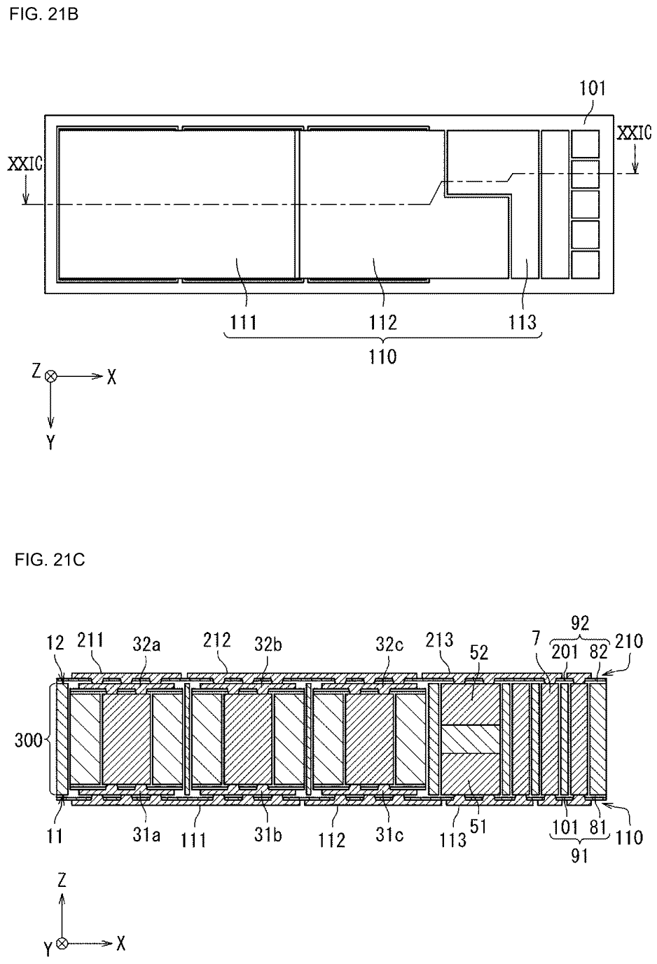

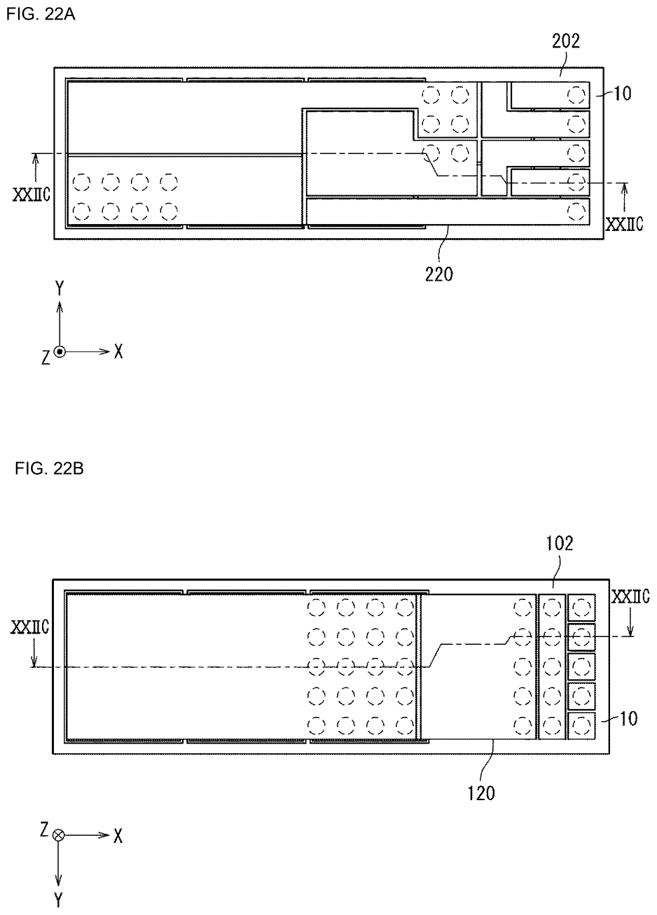

Then, each of the conductor layers 1102 and 2102 is patterned into a desired shape (step (v)). As illustrated in FIGS. 21A through 21C, as a result of patterning the conductor layer 1102, a wiring layer 110 including multiple electrodes, such as a first connection electrode 111, a first inductor connection electrode 112, and a first input capacitor connection electrode 113, is obtained. Likewise, as a result of patterning the conductor layer 2102, a wiring layer 210 including multiple electrodes, such as a second inductor connection electrode 211, a second connection electrode 212, a second input capacitor connection electrode 213, and an output capacitor connection electrode 214, is obtained.

### <Forming of Wiring Layers 120, 130, 220, and 230>

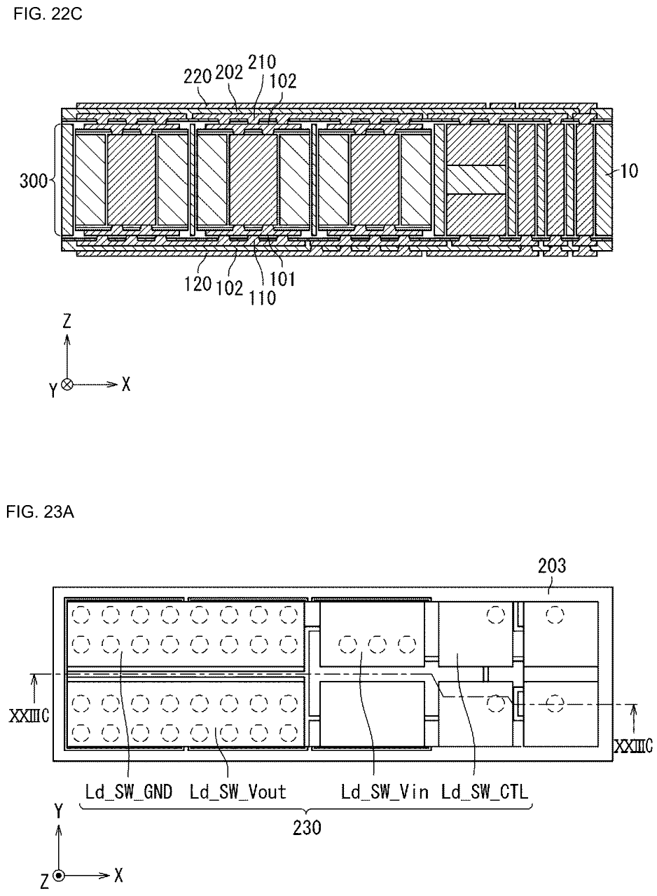

Then, as illustrated in FIGS. 22A and 22B, by performing steps similar to the above-described steps (i) through (v), the wiring layer 120 is formed on the wiring layer 110 with the insulating layer 102 interposed therebetween, and the wiring layer 220 is formed on the wiring layer 210 with the insulating layer 202 interposed therebetween. The wiring layers 120 and 220 each include multiple electrodes having a desired pattern.

Then, as illustrated in FIGS. 23A and 23B, by performing steps similar to the above-described steps (i) through (v), the wiring layer 130 is formed on the wiring layer 120 with the insulating layer 103 interposed therebetween, and the wiring layer 230 is formed on the wiring layer 220 with the insulating layer 203 interposed therebetween.

In the first exemplary embodiment, as shown in FIG. 23B, the wiring layer 130 includes terminals, such as a control terminal CTL, an input terminal Vin, an output terminal Vout, and a ground terminal GND. As shown in FIG. 23A, the wiring layer 230 includes terminal lands Ld_SW_Vin, Ld_SW_Vout, Ld_SW_GND, and Ld_SW_CTL for the respective terminals (SW_Vin, SW_Vout, SW_GND, and SW_CTL) (see FIG. 6) of the switching device SW.

### <Forming of Solder Resist Layers>

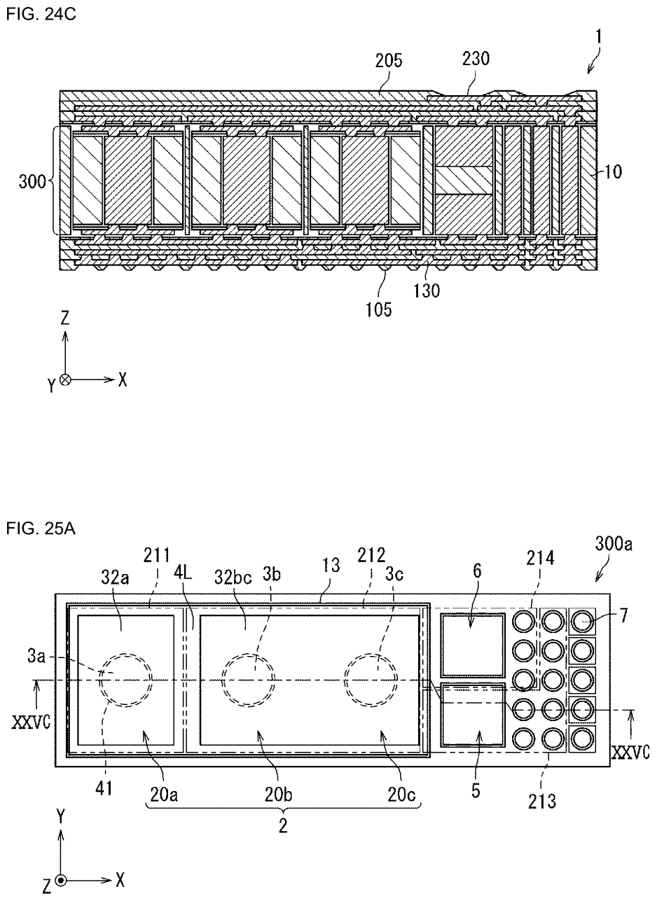

Subsequently, as illustrated in FIGS. 24A and 24B, the solder resist layer 105 is formed on the wiring layer 130, while the solder resist layer 205 is formed on the wiring layer 230. The solder resist layers 105 and 205 have openings for exposing the terminals on the wiring layer 130 and the lands on the wiring layer 230, respectively. Corrosion resistance and rust prevention treatment using NiAu, and other surface treatment, may be applied to the surfaces (conductor surfaces) of the wiring layers 120 and 230 which are exposed by the openings of the solder resist layers 105 and 205. The circuit board 1 is manufactured in the above-described manner.

### [Advantages]

For comparison, a magnetic core assembly, which is a reference example, having an inductor in which a current flows in the thickness direction (vertical direction inductor) embedded therein will be explained. FIG. 46 is a schematic sectional view of a magnetic core assembly 700, which is a reference example according to a description of U.S. Patent Application Publication No. 2020/0111597. In the magnetic core assembly 700 of the reference example, a U-shaped conductor 702 is disposed to pass through a magnetic core 701 in the thickness direction, thereby forming two inductors 710 and 720. The inductors 710 and 720 are connected in parallel with each other. With this structure, the height of the conductor 702 becomes high to obtain a desired inductance, which may make the magnetic core assembly 700 thick.

In the reference example shown in FIG. 46, the following problem may also arise. The magnetic core assembly 700 is electrically and mechanically connected to upper and lower printed circuit boards 703 and 705 by soldering or other techniques as would be appreciated to one skilled in the art. More specifically, the top end of the conductor 702 is connected to bonding pads 704 of the printed circuit board 703 by soldering. The bottom end (folded portion) of the conductor 702 is connected to a bonding pad 706 of the printed circuit board 705 by soldering. With this structure, the presence of the folded portion makes it difficult to reduce the size of the magnetic core assembly 700. Additionally, the connection between the assemblies may become partial and discontinuous. In other words, the connecting portions between the assemblies are discretely positioned, resulting in the presence of air gaps between the assemblies. As a result, mechanical stress may be concentrated on the connecting portions between the assemblies, which may lead to lower connection reliability.

In contrast, in the first exemplary embodiment, the inductor 2 is embedded in the circuit board 1. It is thus possible to form a smaller, thinner voltage regulator module compared with the structure in which printed circuit boards are disposed on both sides of an inductor, such as the structure shown in FIG. 46.

In the circuit board 1 of the first exemplary embodiment, a vertical direction inductor in which a current flows in the thickness direction (direction perpendicular to the circuit surface) can be divided into three or more portions and be disposed within the base member 10. This eliminates the need to form a folded portion, such as that in the reference example. This makes it possible to make the component-embedded base body 300 thinner while securing a desired inductance. Using this circuit board 1 can thus make a voltage regulator module even thinner.

Additionally, in the circuit board 1 of the first exemplary embodiment, the inductor 2 (inductor unit cells 20a through 20c) is surface-mounted on the wiring layers 110 and 210 with the insulating portions 91 and 92 interposed therebetween. Hence, the mechanical connection stability of the inductor 2 can be significantly improved compared with the structure of the reference example in FIG. 46.

In the circuit board 1 of the first exemplary embodiment, the number of inductor unit cells (the number of conductors 3a through 3c) forming the inductor 2 is three. This makes it easy to connect one of the input terminal and the output terminal of the inductor 2 to the electrode of the base member 10 facing the first surface 11 and to connect the other one of the input terminal and the output terminal to the electrode facing the second surface 12. When the circuit board 1 is applied to a voltage regulator module (see FIG. 45), it is possible to shorten the path from the switch output terminal SW_Vout to the input terminal of the inductor 2 and the path from the output terminal of the inductor 2 to the output terminal Vout of the module. This configuration reduces the electrical resistance of the voltage regulator module and can thus enhance the efficiency of the voltage regulator module.

The circuit board 1 illustrated in the drawings includes three inductor unit cells. However, any number of inductor unit cells may be provided if the circuit board 1 includes at least one inductor unit cell. An odd number of inductor unit cells may preferably be provided. This configuration facilitates connecting the input terminal and the output terminal of the inductor 2 to the wiring layers disposed on the opposite sides across the base member 10. In a voltage regulator module incorporating the circuit board 1, the current path of elements excluding the inductor 2 can be shortened.

In the circuit board 1 of the first exemplary embodiment, in a plan view, each of the first electrodes 31a through 31c and the second electrodes 32a through 32c (collectively called “inductor electrodes”) of the inductor unit cells 20a through 20c is disposed to cover the entirety of the corresponding conductor and at least part of the corresponding magnetic member. With this configuration, multiple via-conductors, which are used to connect an inductor electrode to a corresponding electrode within the wiring layers 110 and 210, can be disposed on this inductor electrode, thereby making it possible to increase the connection area. Hence, the connection resistance can be decreased and the connection reliability can be enhanced.

In the first exemplary embodiment, as a result of setting the inductor electrodes to be larger than the conductors in a plan view, multiple via-conductors, which are used to connect the first electrodes 31a and 31b to the first connection electrodes 111, can be disposed in an area larger than the end surfaces of the conductors 3a and 3b in a plan view. In a plan view, at least one of the via-conductors may be disposed outside the corresponding one of the conductors 3a and 3b. Likewise, multiple via-conductors, which are used to connect the second electrodes 32b and 32c to the second connection electrodes 212, can be disposed in an area larger than the end surfaces of the conductors 3a and 3b in a plan view. With the above-described configuration, the connection resistance between the inductor unit cells can be lowered, thereby making it possible to reduce the DC resistance of the inductor 2 formed by the inductor unit cells 20a through 20c.

The circuit board 1 of the first exemplary embodiment includes at least one two-terminal capacitor, which may be the two-terminal capacitors 5 and 6, inside the base member 10. At least one two-terminal capacitor, which may be the two-terminal capacitors 5 and 6, and the inductor 2 are disposed side by side in a direction intersecting with the Z direction. Using this circuit board 1 can make the voltage regulator module even thinner than the structure in which a capacitor and an inductor are disposed in the thickness direction (U.S. Patent Application Publication No. 2020/0111597, for example).

A two-terminal capacitor (input capacitor 5, for example) in the first exemplary embodiment includes a dielectric member 53, a lower electrode 51 located on the side of the dielectric member 53 facing the first surface 11, an upper electrode 52 located on the side of the dielectric member 53 facing the second surface 12. The lower electrode 51 is electrically connected to wiring within the first wiring layer 110 by via-conductors provided in the first insulator 91. The upper electrode 52 is electrically connected to wiring within the second wiring layer 210 by via-conductors provided in the second insulator 92. With this configuration, the connection resistance between the electrodes of the two-terminal capacitor and the corresponding wiring layers can be reduced, thereby improving the connection reliability.

The circuit board of the present disclosure is not limited to that of the exemplary embodiment illustrated in FIGS. 1 through 24C and may be implemented in various other modes. For example, one or both of the input capacitor and the output capacitor may be disposed outside the base member 10. Two or more inductors 2 may be embedded in the base member 10. The layout of the components embedded in the base member 10, the circuit configuration of the circuit board 1, the number of wiring layers of the circuit board 1, and the electrode patterns within the wiring layers are not limited to those in the examples shown in FIGS. 1 through 24C and may suitably be determined.

In the first exemplary embodiment, in each of the inductor unit cells 20a through 20c, a single conductor is disposed to pass through the magnetic member. However, in the same inductor unit cell, two or more conductors may be disposed to pass through the magnetic member. These conductors are arranged with a distance therebetween and may be connected in parallel with each other by an inductor electrode. That is, one inductor unit cell may be formed by two or more parallel-connected inductors.

As discussed above, each inductor unit cell is able to function solely as an inductor. Accordingly, by connecting the three conductors 3a through 3c in parallel with each other, three inductors may be formed from the conductors 3a through 3c and the magnetic members 4a through 4c. In this case, all of the first electrodes 31a through 31c may be electrically connected to the first connection electrode 111, and all of the second electrodes 32a through 32c may be electrically connected to the second connection electrode 212.

### Second Exemplary Embodiment

A circuit board according to a second exemplary embodiment is different from that of the first exemplary embodiment in that three inductor unit cells are integrally formed. The second exemplary embodiment will be described below by mainly referring to the points different from the circuit board of the first exemplary embodiment while omitting an explanation of the same points as the first exemplary embodiment.

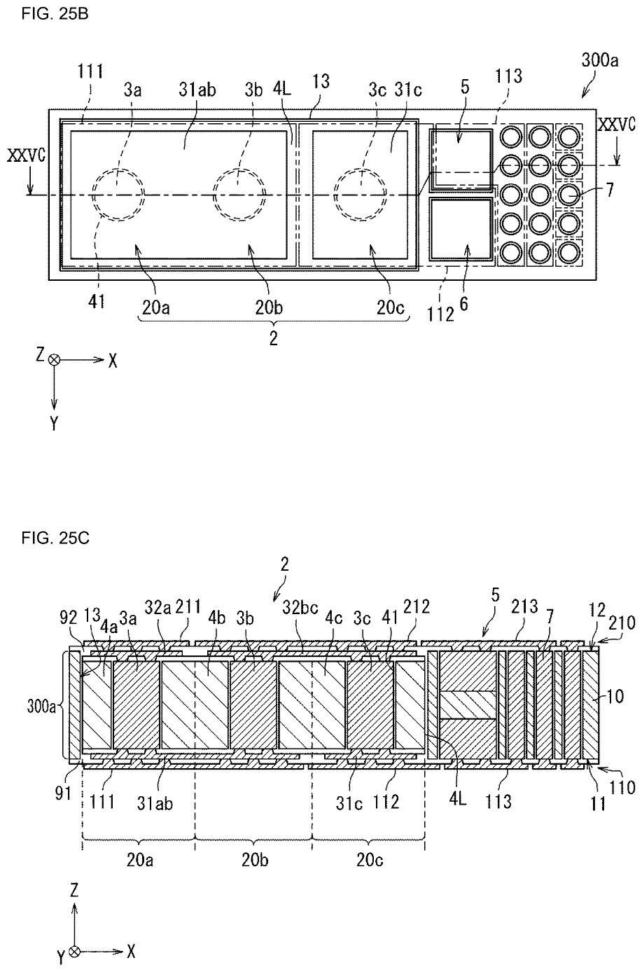

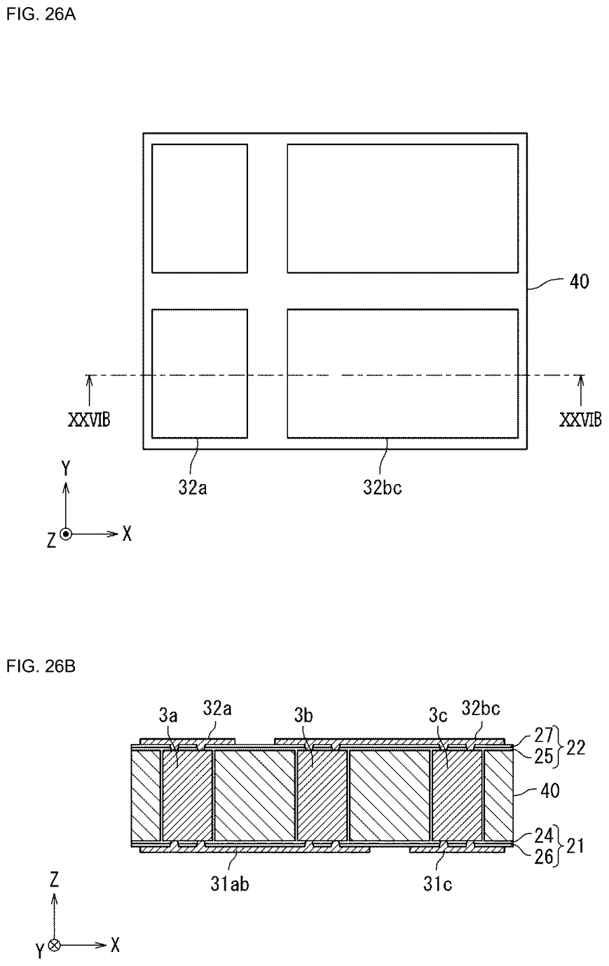

FIGS. 25A and 25B are a schematic top view and a schematic bottom view, respectively, of a component-embedded base body and some wiring layers of the circuit board of the second exemplary embodiment. FIG. 25C is a schematic sectional view taken along line XXVC-XXVC in FIGS. 25A and 25B. In FIG. 25C, wiring layers 110 and 210 are also shown. In FIGS. 25A and 25B, the electrodes on the wiring layers 210 and 110 are indicated by the long dashed double-dotted lines for easy understanding.

A component-embedded base body 300a is different from the component-embedded base body 300 shown in FIGS. 3A through 3C in that an inductor 2, which is a single component, is disposed in a single through-hole 13 formed in a base member 10. The inductor 2 of the second exemplary embodiment is different from the inductor 2 shown in FIGS. 3A through 3C in that magnetic members 4a through 4c are integrally formed (linked), two first electrodes 31a and 31b are integrally formed, and two second electrodes 32b and 32c are integrally formed.

The inductor 2 includes a magnetic layer 4L, conductors 3a through 3c, first electrodes 31ab and 31c, and second electrodes 32a and 32bc.

The magnetic layer 4L is formed in a rectangular-cuboid shape elongated in the X direction. Three magnetic through-holes 41 are formed in the magnetic layer 4L with a distance therebetween in a plan view. Conductors 3a through 3c are disposed in the respective magnetic through-holes 41. Portions 4a through 4c of the magnetic layer 4L that are respectively positioned to surround the peripheral surfaces of the conductors 3a through 3c respectively serve as magnetic elements of the inductor unit cells 20a through 20c. The magnetic members 4a through 4c are continuous (linked) and partition walls of the base member 10 are not provided between adjacent magnetic members.

The first electrode 31ab is equivalent to an integrally formed electrode of the first electrodes 31a and 31b shown in FIGS. 3A through 3C. The first electrode 31ab is disposed on the side of the magnetic layer 4L facing the first surface 11 and is separated from the first electrode 31c with a distance therebetween. The first electrode 31ab is electrically connected to the first end portions of the conductors 3a and 3b. The first electrode 31ab is electrically connected to the first connection electrode 111 by via-conductors within the first insulator 91.

The second electrode 32bc is equivalent to an integrally formed electrode of the second electrodes 32b and 32c shown in FIGS. 3A through 3C. The second electrode 32bc is disposed on the side of the magnetic layer 4L facing the second surface 12 and is separated from the second electrode 32a with a distance therebetween. The second electrode 32bc is electrically connected to the second end portions of the conductors 3b and 3c. The second electrode 32bc is electrically connected to the second connection electrode 212 by via-conductors within the second insulator 92.

In the example in FIGS. 25A through 25C, in a plan view, the first electrode 31ab covers the entirety of the conductors 3a and 3b. In a plan view, the first electrode 31ab is slightly smaller in size than the first connection electrode 111 and may be positioned within the outline of the first connection electrode 111. Likewise, in a plan view, the second electrode 32bc covers the entirety of the conductors 3b and 3c. In a plan view, the second electrode 32bc may be positioned within the outline of the second connection electrode 212.

### [Manufacturing Method for Circuit Board]

A manufacturing method for the circuit board 1 is similar to that of the first exemplary embodiment discussed with reference to FIGS. 7A through 24C. An explanation of the manufacturing method of the second exemplary embodiment will be described below by only referring to the points different from the first exemplary embodiment while omitting the same points as the first exemplary embodiment.

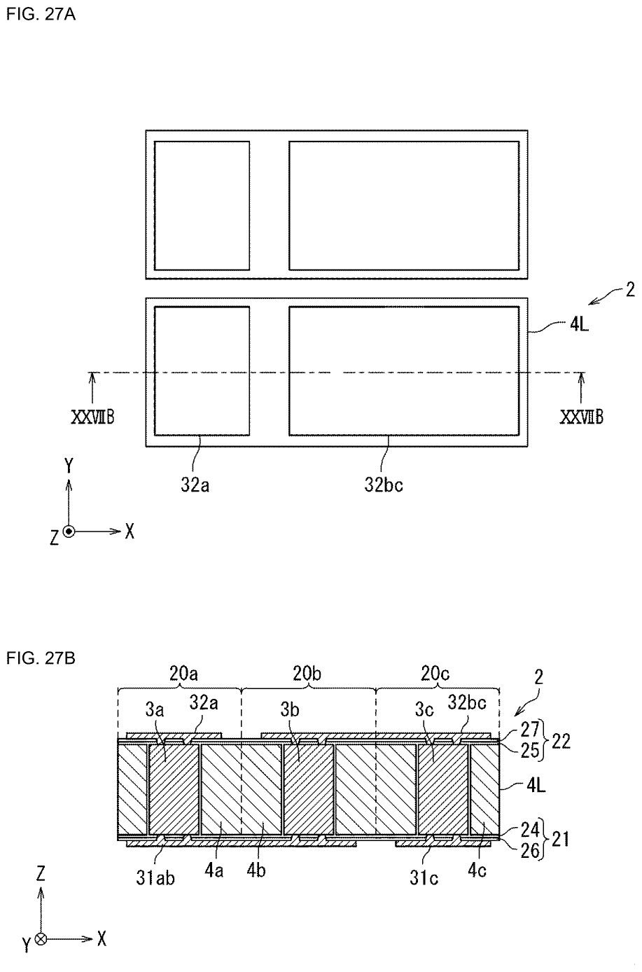

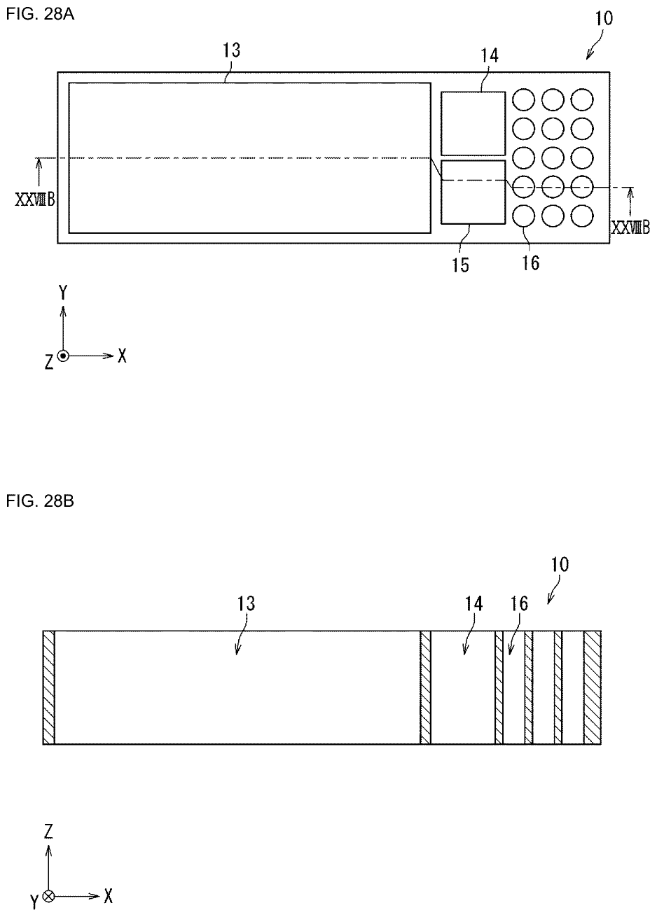

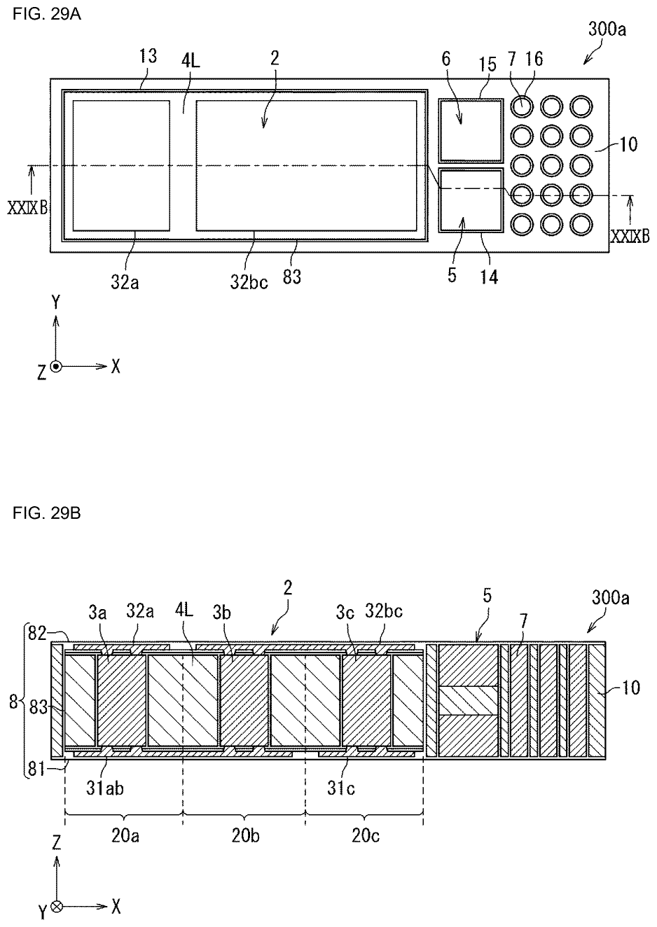

FIGS. 26A and 27A are schematic top views for explaining a method for manufacturing inductor unit cells. FIGS. 28A and 29A are schematic top views for explaining a method for manufacturing a circuit board (embedding step). FIGS. 26B through 29B are schematic sectional views taken along line XXVIB-XXVIB through XXIXB-XXIXB in FIGS. 26A through 29A, respectively.

Conductor layers 312 and 322 are formed and patterned in a manner similar to the method discussed with reference to FIGS. 7A through 12B. In the second exemplary embodiment, the first electrode 31ab connected to the conductors 3a and 3b and the first electrode 31c connected to the conductor 3c are formed from the conductor layer 312, as shown in FIGS. 26A and 26B. Likewise, the second electrode 32a connected to the conductor 3a and the second electrode 32bc connected to the conductors 3b and 3c are formed from the conductor layer 322. Then, as illustrated in FIGS. 27A and 27B, the magnetic block 40 is divided. In this example, the magnetic layer 4L is cut so as to include the conductors 3a through 3c and the surrounding magnetic members 4a through 4c. As a result, the inductor 2 including inductor unit cells 20a through 20c is obtained.

Then, as illustrated in FIGS. 28A and 28B, a base member 10 including one through-hole 13 in an inductor placement region is prepared. Then, as illustrated in FIGS. 29A and 29B, the inductor 2 obtained by the above-described method is placed in the through-hole 13. Predetermined components are placed in through-holes 14 through 16 and are sealed with a sealing member 8. The subsequent steps are similar to those in the first exemplary embodiment.

### [Advantages]

In the circuit board 1 of the second exemplary embodiment, the magnetic members 4a through 4c of the inductor unit cells 20a through 20c are integrally formed, thereby making it possible to reduce the area of the inductor placement region of the base member 10. The circuit board 1 can thus be reduced in size.

Additionally, the first electrodes of the inductor unit cells 20a and 20b are integrally formed, while the second electrodes of the inductor unit cells 20b and 20c are integrally formed. With this configuration, the connection resistance between the inductor unit cells can be lowered, thereby making it possible to reduce the DC resistance of the inductor 2. As a result, the resistance loss of the circuit can be further reduced.

In the example shown in FIGS. 25A through 25C, the three inductor unit cells 20a through 20c are integrally formed. However, two of the inductor unit cells may be integrally formed. Alternatively, three or more inductor unit cells may be integrally formed.

In the second exemplary embodiment, too, each of the inductor unit cells 20a through 20c may include two or more conductors connected in parallel with each other. By connecting the three conductors 3a through 3c in parallel with each other, three inductors may be formed from the conductors 3a through 3c and the magnetic members 4a through 4c.

### Third Exemplary Embodiment

### (Underlying Knowledge Forming Basis of Disclosure)

It is desirable to reduce the area of a circuit board that embeds components, such as a vertical direction inductor, therein. “The area of a circuit board” is the area when the circuit board is seen in the thickness direction. For example, when two or more vertical direction inductors are embedded in a circuit board, the area of the circuit board tends to be large. In particular, as in the first exemplary embodiment, when a single vertical direction inductor is divided into multiple inductor unit cells and embedded, an increased number of inductor unit cells (that is, an increased number of series-connected conductors forming the inductor) is likely to make the area of the circuit board large. In addition to the conductors forming an inductor, when conductors forming another component, such as a transformer component utilizing magnetic coupling between conductors, are embedded, the area of the circuit board may be increased.

Configurations that can further reduce the area of a circuit board having multiple conductors embedded therein are studied. According to an exemplary aspect of the disclosure, a smaller circuit board can be implemented by disposing multiple conductors with a distance therebetween in a single through-hole formed in a base member. The following exemplary embodiment is based on some exemplary aspects.

### [Overall Configuration of Circuit Board]

As in the first exemplary embodiment, the circuit board of the third exemplary embodiment includes a first wiring structure, a second wiring structure, and a component-embedded base body disposed between the first and second wiring structures. The component-embedded base body includes at least one conductor-containing section between the first and second wiring structures. “The conductor-containing section” includes a base member and multiple conductors disposed in a through-hole of the base member.

Each conductor disposed in the through-hole may be a conductor forming a component, such as an inductor. The base member having a through-hole may be a base member (magnetic base member or magnetic layer, for example) disposed within a core base member.

### [Configuration of Conductor-Containing Section]

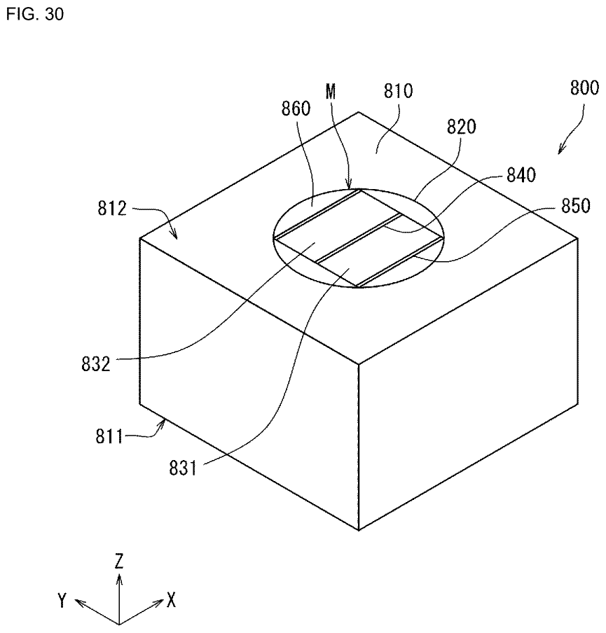

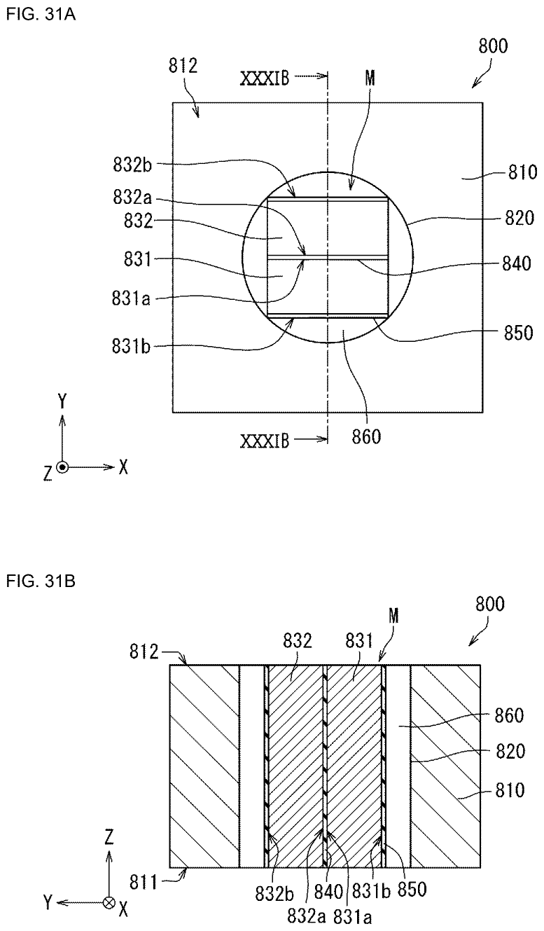

An example of the conductor-containing section of the circuit board according to the third exemplary embodiment will be described below with reference to FIGS. 30 through 31B. The conductor-containing section will be explained below through illustration of a conductor-containing section forming an inductor component.

FIG. 30 is a schematic perspective view of a conductor-containing section of the circuit board according to the third exemplary embodiment. FIG. 31A is a schematic top view of the conductor-containing section shown in FIG. 30. FIG. 31B is a schematic sectional view taken along line XXXIB-XXXIB in FIG. 31A.

A conductor-containing section 800 includes a base member 810, conductors 831 and 832, and a separation insulating layer 840. In this example, the base member 810 is a magnetic member.

The base member 810 has a first surface 811 and a second surface 812. The second surface 812 is located on the side of the base member 810 opposite the first surface 811 in the thickness direction (Z direction). A first wiring layer is disposed on the first surface 811 and a second wiring layer is disposed on the second surface 812, though they are not shown. The base member 810 has a through-hole 820 extending in the thickness direction. In the example in FIGS. 30 through 31B, the base member 810 is formed in a rectangular-prism shape (rectangular cuboid in this example), for instance. The through-hole 820 has a cylindrical shape, for example.

The conductors 831 and 832 are disposed in the through-hole 820 with a distance therebetween, in a plan view as seen in the Z direction (hereinafter may simply be called “in a plan view”). The conductors 831 and 832 each extend in the Z direction. The end portions (first end portions) of the conductors 831 and 832 facing the first surface 811 are electrically connected to a corresponding electrode within the first wiring layer. The end portions (second end portions) of the conductors 831 and 832 facing the second surface 812 are electrically connected to a corresponding electrode within the second wiring layer.

The separation insulating layer 840 is located between the conductors 831 and 832 in a plan view. In the through-hole 820, the separation insulating layer 840 separates the conductors 831 and 832 from each other.

In the specification, a structure M formed by multiple conductors disposed in a single through-hole and a separation insulating layer that separates the conductors from each other will be called a “first structure”. The specific structure of the first structure M will be discussed later.

An insulating portion 860 is provided between the inner wall of the through-hole 820 and the first structure M. The insulating portion 860 is a resin member, for example. The insulating portion 860 may be located to fill gaps between the inner wall of the through-hole 820 and the side surfaces of the first structure M. The insulating portion 860 may contain a magnetic material. This configuration improves the inductance of an inductor component including the conductors 831 and 832 of the conductor-containing section 800.

### (First Structure M)

The conductors 831 and 832 of the first structure M each have a columnar shape extending in the Z direction. The conductors 831 and 832 may be formed in a polygonal-prism shape whose cross section is a polygon having an interior angle of 90° or larger and smaller than 180°. In the specification, a “cross section of a conductor” is a cross section of a conductor perpendicular to the Z direction (thickness direction of a base member). In this example, the conductors 831 and 832 have the same size and the same shape. However, the conductors 831 and 832 may have different sizes and different shapes (cross-sectional shapes).

In the example in FIGS. 30 through 31B, the conductors 831 and 832 are each formed in a rectangular-prism shape having a rectangular cross section. The conductors 831 and 832 are arranged in the Y direction with the separation insulating layer 840 interposed therebetween. In this example, the distance between the conductors 831 and 832 is small and they are disposed close to each other. The distance between the conductors 831 and 832 (the Y-direction dimension of the separation insulating layer 840 in this example) is preferably set to a minimal distance that can secure a sufficient dielectric withstand voltage with respect to the potential difference between the conductors 831 and 832. This configuration enhances the degree of coupling between the conductors and miniaturize the components or the circuit board. The distance between the conductors 831 and 832 is 60 μm or smaller, for example.

The conductor 831 has a first side surface 831a facing the conductor 832 and a second side surface 831b positioned opposite the first side surface 831a in the Y direction. Likewise, the conductor 832 has a first side surface 832a facing the conductor 831 and a second side surface 832b positioned opposite the first side surface 832a in the Y direction. The first side surface 831a of the conductor 831 and the first side surface 832a of the conductor 832 may be bonded to each other by the separation insulating layer 840.

At least some of the side portions of each of the conductors 831 and 832 may be covered with an insulating layer 850. “The side portion of a conductor” is a portion between the end surface of the conductor facing the first surface and the end surface of the conductor facing the second surface. In the example in FIGS. 30 through 31B, the second side surface 831b of the conductor 831 and the second surface 832b of the conductor 832 are covered with the insulating layer 850. The side surfaces of the conductors 831 and 832 extending in the Y direction in a plan view are not covered with the insulating layer 850 and may directly contact the insulating portion 860, for example.

In the example shown in FIGS. 30 through 31B, the first structure M is formed in a rectangular-prism shape. In a plan view, the first structure M has a rectangular shape slightly smaller than the rectangle inscribed in a circular opening of the through-hole 820. With this configuration, in manufacturing the conductor-containing section 800, the first structure M, which is separately formed, can be more easily placed in the through-hole 820 of the base member 810.

### [Advantages]

The circuit board according to the third exemplary embodiment includes a base member 810 having a through-hole 820 extending in the thickness direction (Z direction), conductors 831 and 832 disposed in the through-hole 820 and each extending in the Z direction, and a separation insulating layer 840 that separates the conductors 831 and 832 from each other in the through-hole 820. With this configuration, the area of the circuit board as seen in the Z direction can be made smaller than the configuration in which a through-hole is provided for each conductor. As a result, the circuit board can be miniaturized.

In the circuit board of the third exemplary embodiment, the conductors 831 and 832 are electrically isolated from each other. For example, the first end portions of the conductors 831 and 832 may be electrically connected to different electrodes on the first surface 811, while the second end portions of the conductors 831 and 832 may be electrically connected to different electrodes on the second surface 812. With this configuration, the conductor 831 can form part of a component, while the conductor 832 can form part of another component.

The circuit board of the third exemplary embodiment may include first and second inductors that are operable independently of each other. In this case, the first inductor may include the conductor 831, while the second inductor may include the conductor 832.

The first and second inductors may be formed by a single conductor-containing section 800. Alternatively, the first and second inductors may be formed by multiple conductor-containing sections 800, which will be discussed below. When the first and second inductors are formed by multiple conductor-containing sections 800, the conductors 831 of the conductor-containing sections 800 may be connected in series with each other to form a first inductor, while the conductors 832 of the conductor-containing sections 800 may be connected in series with each other to form a second inductor. With the above-described configuration, the conductor of a vertical direction inductor can be divided and disposed, thereby making the circuit board thin. Additionally, by disposing two or more conductors 831 and 832 in a single through-hole, the area of the circuit board can be made small. It is thus possible to further reduce the size of the circuit board.

The conductors 831 and 832 may be electrically connected to each other. For example, the first end portions of the conductors 831 and 832 may be connected to each other by an electrode disposed on the first surface 811, while the second end portions of the conductors 831 and 832 may be connected to each other by an electrode disposed on the second surface 812.

### First Modified Example

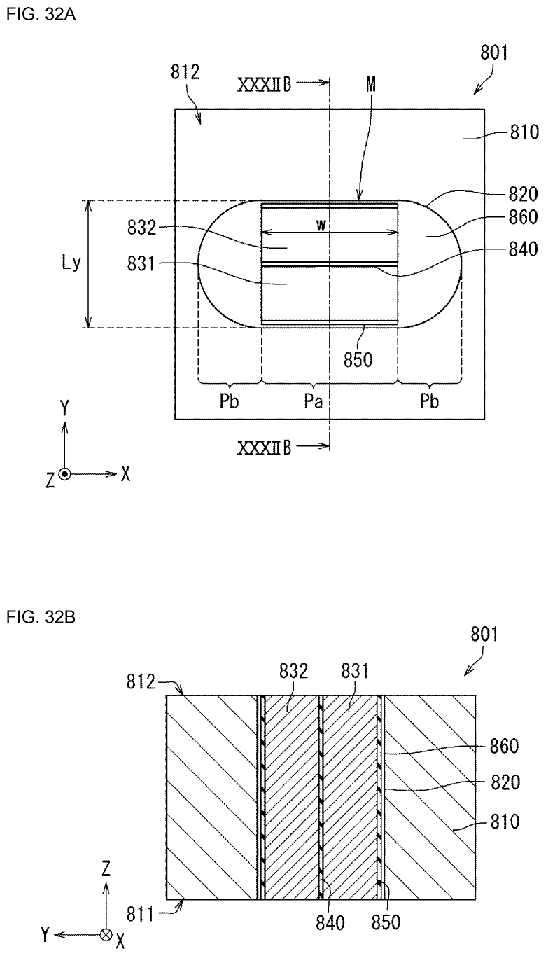

FIG. 32A is a schematic top view of a first modified example of a conductor-containing section. FIG. 32B is a schematic sectional view taken along line XXXIIB-XXXIIB in FIG. 32A.

A conductor-containing section 801 of the first modified example shown in FIGS. 32A and 32B is different from the conductor-containing section 800 shown in FIGS. 31A and 31B in that the shape of a through-hole 820 is not a circle but is elongated in one direction (X direction in this example) in a plan view as seen in the Z direction.

In the first modified example, the opening shape of the through-hole 820 is a track shape (oval) elongated in the X direction. “The opening shape of a through-hole” is the shape of a columnar through-hole when this through-hole is seen in the Z direction and is the shape of the opening on the first surface 811 and the second surface 812 of the base member 810. “The track shape” is a shape, like a racetrack, for example, in which two short sides of a rectangle are replaced by partial circles or semicircles protruding outward, and shapes approximating such a shape. The through-hole 820 having such a shape can be formed by a rectangular prism region Pa having a rectangular-prism shape and two partial cylindrical regions Pb having a partial cylindrical shape and located on both sides of the rectangular prism region Pa in the Y direction. The rectangular prism region Pa corresponds to a rectangular portion positioned at the center of the track shape in a plan view, while the partial cylindrical regions Pb correspond to two partial circular portions positioned on both sides of the rectangular portion in a plan view.

In the example in FIGS. 32A and 32B, in a plan view, both of the first structure M and the through-hole 820 have shapes elongated in one direction (X direction). In a plan view, the longest dimension Ly of the through-hole 820 in the short direction (Y direction) may be smaller than the longest dimension w of the first structure W in the longitudinal direction. With this configuration, in manufacturing the conductor-containing section 801, the first structure M can be placed in the through-hole 820 in a predetermined orientation. More specifically, the first structure M is placed in the through-hole 820 in the orientation in which the longitudinal direction of the through-hole 820 and that of the first structure M match or substantially match each other in a plan view. In this example, the first structure M is disposed in the through-hole 820 such that the conductors 831 and 832 are arranged side by side in the Y direction (that is, the conductor 831 is located on the −Y side or the +Y side of the conductor 832).

The first structure M1 is disposed within the rectangular prism region Pa of the through-hole 820, for example. The first structure M may have a rectangular shape slightly smaller than the rectangular prism region Pa of the through-hole 820 in a plan view. The Y-direction dimension of the through-hole 820 becomes the longest (dimension Ly) in the rectangular prism region Pa and becomes smaller as the through-hole 820 is farther separated from the rectangular prism region Pa in the X direction. Hence, if the shape of the first structure M is slightly smaller than the rectangular prism region Pa in a plan view, the position of the first structure M in the through-hole 820 is unlikely to deviate from the rectangular prism region Pa.

The conductors 831 and 832 may have the same shape and the same size. The first structure M may be arranged to be point-symmetrical with respect to a point at the center of the separation insulating layer 840 in a plan view as seen in the Z direction. With this configuration, even if the conductors 831 and 832 are turned upside down (the conductor 831 is located on the +Y side of the conductor 832) as a result of being rotated 180° from the orientation in FIG. 32A, the conductor-containing section 801 still has substantially the same structure and the same functions as those of the conductor-containing section 801 shown in FIG. 32A.

In the circuit configuration of the first modified example, the opening shape of the through-hole 820 is elongated in one direction. Hence, in a manufacturing process of the conductor-containing section 801, when placing the first structure M in the through-hole 820, the orientation of the first structure M with respect to the through-hole 820 is determined. This facilitates the placement of the conductors 831 and 832 at predetermined positions. As a result, the conductors 831 and 832 can be more reliably connected to predetermined electrodes in a wiring layer, thereby implementing easier manufacturing of a circuit board.

In the first modified example, polygonal-prism shaped conductors 831 and 832 are disposed in the through-hole 820 having a track-shape opening. Accordingly, the cross-sectional area of the conductors 831 and 832 can be made larger than that in a through-hole having a circular opening. It is thus possible to lower the electrical resistance of the conductors 831 and 832 while limiting the increase in the area of the circuit board.

### Second Modified Example

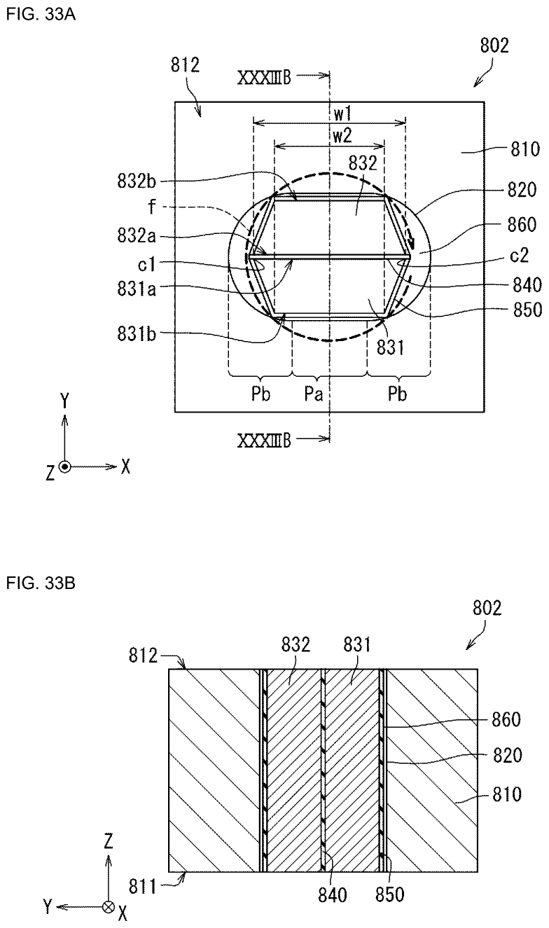

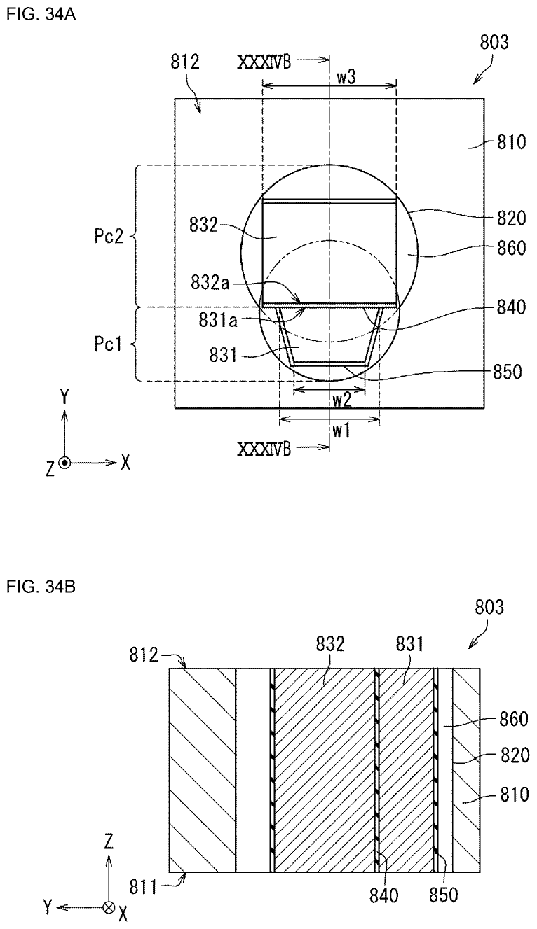

FIG. 33A is a schematic top view of a second modified example of a conductor-containing section. FIG. 33B is a schematic sectional view taken along line XXXIIIB-XXXIIIB in FIG. 33A.

A conductor-containing section 802 of the second modified example shown in FIGS. 33A and 33B is different from the conductor-containing section 801 shown in FIGS. 32A and 32B in the cross-sectional shape of the conductors 831 and 832. The opening shape of the through-hole 820 of the conductor-containing section 802 is a track shape.

In the conductor-containing section 802, the width of the conductor 831 in the X direction becomes smaller as the conductor 831 is farther separated from the conductor 832 in the Y direction. The X-direction dimension w1 of a portion of the conductor 831 closest to the conductor 832 is larger than the X-direction dimension w2 of a portion of the conductor 831 farthest from the conductor 832. The dimension w1 is the X-direction length of the first side surface 831a, for example. The dimension w2 is the X-direction length of the second side surface 831b, for example. As in the conductor 831, the dimension of the conductor 832 in the X direction becomes smaller as the conductor 832 is farther separated from the conductor 831 in the Y direction.

The conductors 831 and 832 may be formed in a polygonal-prism shape (quadrilateral-prism shape in this example). In a plan view, the conductors 831 and 832 each have a polygonal shape having a first side facing the separation insulating layer 840 and second sides adjacent to the first side. The angle c1 between the first side and one second side and the angle c2 between the first side and the other second side may be acute angles. In the example in FIGS. 33A and 33B, the conductors 831 and 832 each have a trapezoidal shape in a plan view. The first side is the base of the trapezoid, while the second sides are the legs of the trapezoid. The conductors 831 and 832 form the first structure M having a substantially hexagonal-prism shape.

The first structure M is disposed in the through-hole 820 in the orientation in which the longitudinal direction of the through-hole 820 and that of the first structure M substantially match each other in a plan view. The longest dimension w1 of the first structure M in the X direction is larger than the X-direction dimension of the rectangular prism region Pa of the through-hole 820. In a plan view, the first structure M thus extends from the rectangular prism region Pa into the partial cylindrical regions Pb on both sides, as shown in FIG. 33A.

At least some of the side portions of each of the conductors 831 and 832 may be covered with an insulating layer 850. In the example in FIGS. 33A and 33B, the side surfaces except for the first side surfaces 831a and 832a of the conductors 831 and 832 are entirely covered with the insulating layer 850.

In the circuit board of the second modified example, at least one of the conductors 831 and 832 (both conductors 831 and 832 in this example) is configured such that its X-direction dimension becomes smaller as one of the conductors 831 and 832 is farther separated from the other one of the conductors 831 and 832 in the Y direction. A magnetic field f generated around the conductors 831 and 832 is thus less likely to be interrupted by the corners of the conductors 831 and 832 and can be circulated more smoothly.

In the circuit board of the second modified example, the first structure M extends to outside the rectangular prism region Pa and enters the partial cylindrical regions Pb. Hence, in a plan view, the ratio of the area of the first structure M to that of the through-hole 820 can be made larger than that in the first modified example, for example. It is thus possible to increase the cross-sectional area of the conductors 831 and 832 so as to further lower the electrical resistance of the conductors 831 and 832 while limiting the increase in the area of the circuit board. Additionally, the gaps between the inner wall of the through-hole 820 and the first structure M can be made smaller, thereby reducing the volume of the insulating portion 860 filling the gaps around the conductors 831 and 832. As a result, the inductance can be further enhanced.

### Third Modified Example

FIG. 34A is a schematic top view of a third modified example of a conductor-containing section. FIG. 34B is a schematic sectional view taken along line XXXIVB-XXXIVB in FIG. 34A.

A conductor-containing section 803 of the third modified example shown in FIGS. 34A and 34B is different from the above-described conductor-containing sections 800 through 802 in that the shapes of the conductors 831 and 832 are different from each other in a plan view. In the third modified example, the first structure M and the through-hole 820 each have an asymmetrical shape in a plan view.

The conductor 831 is a prism shape (quadrilateral-prism shape in this example) similar to the conductor 831 of the second modified example shown in FIGS. 33A and 33B. The dimension of the conductor 831 in the X direction becomes smaller as the conductor 831 is farther separated from the conductor 832. The conductor 832 has a rectangular-prism shape having a rectangular cross section, as in the conductor 831 shown in FIGS. 31A and 31B. The cross-sectional area of the conductor 832 is larger than that of the conductor 831. In the through-hole 820, the first side surface 831a of the conductor 831 faces the first side surface 832a of the conductor 832 in the Y direction with the separation insulating layer 840 interposed therebetween. The dimension w3 of the conductor 832 in the X direction (dimension of the first side surface 832a in this example) is larger than the longest dimension w1 of the conductor 831 in the X direction (X-direction dimension of the first side surface 831a in this example), for instance.

The through-hole 820 has a structure in which two cylindrical holes passing through the base member 810 in the Z direction (hereinafter called a “first hole” and a “second hole”) partially overlap each other. The through-hole 820 includes a first region Pc1 defined by the inner wall of the first hole and a second region Pc2 defined by the inner wall of the second hole.

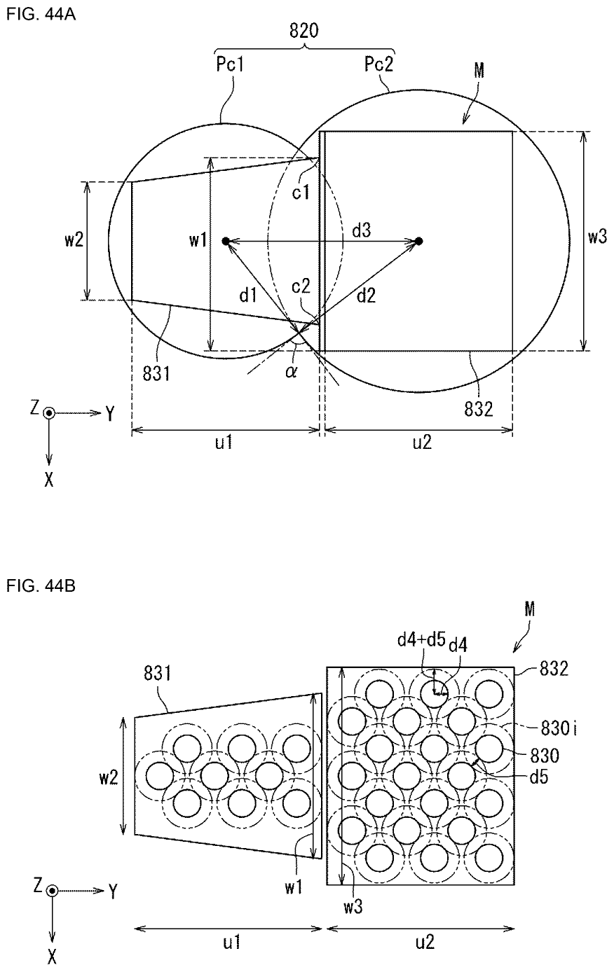

In the example in FIGS. 34A and 34B, the radius of the second hole is larger than that of the first hole. In a plan view, the area of the second region Pc2 is larger than that of the first region Pc1. The conductor 832 is located within the second region Pc2, for example. In a plan view, the conductor 832 may be a quadrilateral slightly smaller than a quadrilateral inscribed in the second region Pc2, which is a partial circle. At least part of the conductor 831 is located within the first region Pc1. The conductor 831 may extend from the first region Pc1 to the second region Pc2. A design method for the through-hole 820 and the conductors 831 and 832 in the third modified example will be discussed later in detail with reference to FIG. 44A.

In the circuit board of the third modified example, in a plan view, the through-hole 820 has an asymmetrical shape and the first structure M also has an asymmetrical shape corresponding to the through-hole 820. With this configuration, the orientation of the first structure M to be disposed in the through-hole 820 is uniquely determined. This facilitates the placement of the conductors 831 and 832 at predetermined positions. As a result, the conductors 831 and 832 can be more reliably connected to predetermined electrodes in a wiring layer, thereby implementing easier manufacturing of a circuit board.

In the circuit board of the third modified example, the cross-sectional area of the conductor 831 and that of the conductor 832 are different, which is advantageous when the current ratio between the conductors 831 and the conductor 832, that is, the current flowing through the conductor 831 and that through the conductor 832 are different. For example, the conductor 832 having a larger cross-sectional area is placed on a line through which a higher current flows, thereby regulating the electrical resistance of this line.

In the circuit board of the third modified example, the X-direction dimension of the conductor 831 becomes smaller as the conductor 831 is farther separated from the conductor 832. A magnetic field generated around the conductors 831 and 832 is thus less likely to be interrupted by the conductor 831, thereby enhancing the inductance.

In the third modified example, the through-hole 820 has a structure in which two cylindrical holes corresponding to the conductors 831 and 832 partially overlap each other. A magnetic field (magnetic flux) generated around each of the conductors 831 and 832 is thus more likely to pass through the magnetic member (base member 810), thereby further enhancing the inductance.

### Fourth Modified Example

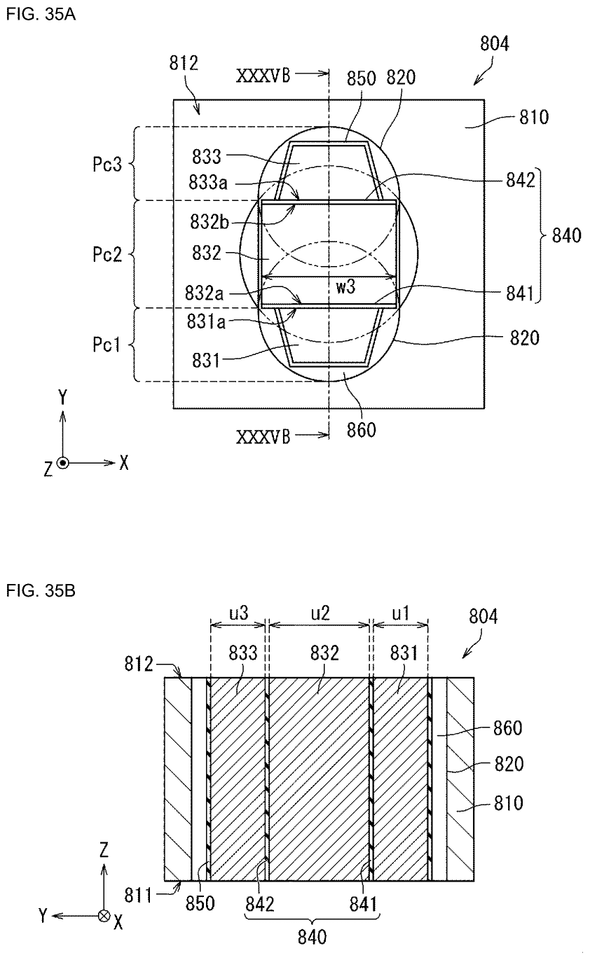

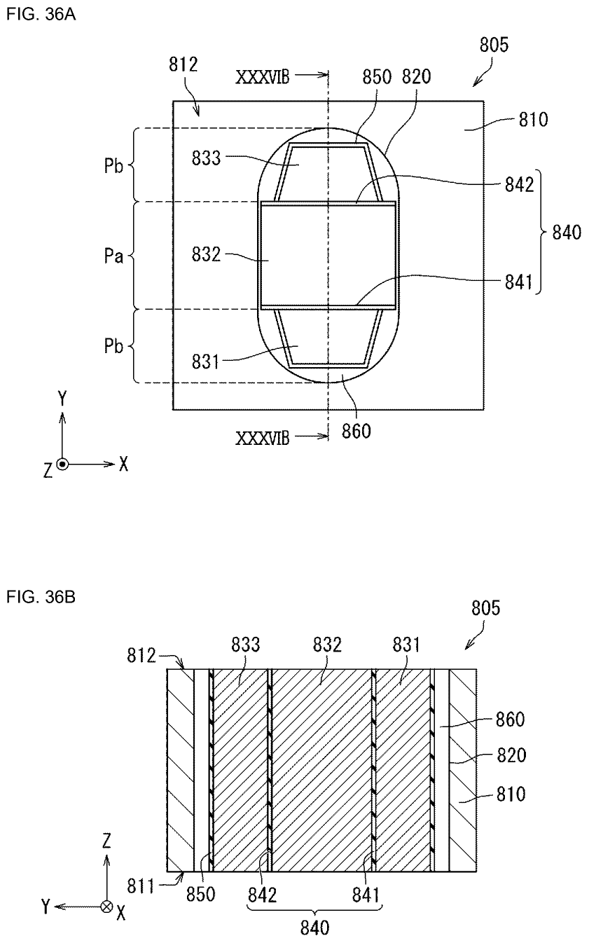

FIG. 35A is a schematic top view of a fourth modified example of a conductor-containing section. FIG. 35B is a schematic sectional view taken along line XXXVB-XXXVB in FIG. 35A.

A conductor-containing section 804 of the fourth modified example shown in FIGS. 35A and 35B is different from the conductor-containing section 803 of the third modified example shown in FIGS. 34A and 34B in that it includes three conductors 831 through 833 disposed in the through-hole 820 of the base member 810.

In the conductor-containing section 804, in the through-hole 820, the conductor 833 is disposed on the opposite side of the conductor 831 with the conductor 832 interposed therebetween. The conductors 831 through 833 are arranged in the Y direction within the through-hole 820 in this order, for example.

The separation insulating layer 840 includes a first separation insulating layer 841 positioned between the conductors 831 and 832 and a second separation insulating layer 842 positioned between the conductors 832 and 833.

In the example in FIGS. 35A and 35B, the conductor 833 has a polygonal-prism shape (quadrilateral-prism shape in this example). A first side surface 833a of the conductor 833 closer to the conductor 832 faces the second side surface 832b of the conductor 832 in the Y direction with the second separation insulating layer 842 interposed therebetween.

The conductor 831 may be formed in a shape similar to the conductor 833. As illustrated in FIGS. 35A and 35B, the dimension of the conductor 833 in the X direction may become smaller as the conductor 833 is farther separated from the conductor 831. The longest dimension of the conductor 833 in the X direction (X-direction dimension of the first side surface 833a in this example) may be smaller than the dimension w3 of the conductor 832 in the X direction and be equal to the X-direction dimension of the conductor 831, for example.

The dimension u2 of the conductor 832 in the Y direction may be larger than the dimension u1 of the conductor 831 and the dimension u3 of the conductor 833 in the Y direction. With this configuration, a higher current can flow through the conductor 832 having a larger cross-sectional area. In one example, the dimension u2 of the conductor 832 in the Y direction may be 0.8 mm, and the dimensions u1 and u3 of the conductors 831 and 833 in the Y direction may be 0.2 mm.

The through-hole 820 has a structure in which three cylindrical holes (hereinafter called a “first hole”, a “second hole”, and a “third hole”) passing through the base member 810 in the Z direction partially overlap each other. In this example, the through-hole 820 has a structure in which the first hole partially overlaps one end portion of the second hole in the Y direction, and the third hole partially overlaps the other end portion of the second hole. The through-hole 820 includes a first region Pc1 defined by the inner wall of the first hole, a third region Pc3 defined by the inner wall of the third hole, and a second region Pc2 located between the first region Pc1 and the third region Pc3 and defined by the inner wall of the second hole.

In the example in FIGS. 35A and 35B, the radius of the second hole is larger than those of the first and third holes. The longest dimension of the second region Pc2 in the X direction is thus larger than those of the first region Pc1 and the third region Pc3 in the X direction. In a plan view, the area of the second region Pc2 may be larger than those of the first region Pc1 and the third region Pc3. The conductor 832 is located within the second region Pc2. At least part of the conductor 831 is located within the first region Pc1, while at least part of the conductor 833 is located within the third region Pc3.

Both of the through-hole 820 and the first structure M may have a shape elongated in one direction (Y direction in this example). In a plan view, the longest dimension of the through-hole 820 in the short direction (X direction) may be smaller than the longest dimension of the first structure W in the longitudinal direction (Y direction). With this configuration, in manufacturing the conductor-containing section 804, the first structure M can be placed in the through-hole 820 in a predetermined orientation. More specifically, the first structure M is disposed in the through-hole 820 in the orientation in which the longitudinal direction of the through-hole 820 and that of the first structure M match or substantially match each other in a plan view.

The conductors 831 and 833 are arranged symmetrically on both sides of the conductor 832, and the first structure M may be arranged to be point-symmetrical in a plan view. With this configuration, even if the first structure M is turned upside down from the orientation shown in the example in FIG. 35A and is disposed in the through-hole 820, the conductor-containing section 804 having substantially the same structure as that in FIG. 35A can be manufactured.

In FIG. 35A, the first structure M and the through-hole 820 are each arranged point-symmetrically in a plan view. However, they may be arranged asymmetrically. For example, the shapes and/or the sizes of the conductors 831 and 833 in a plan view may be different from each other.

In the circuit board of the fourth modified example, the three conductors 831 through 833 can be disposed in the single through-hole 820, thereby further reducing the size of the circuit board. Additionally, the cross-sectional areas, connection methods, and current directions of the conductors 831 through 833 can be designed according to their applications (the magnitude of a current, for example), thereby enhancing the design flexibility.

In the circuit board of the fourth modified example, the X-direction dimensions of the conductors 831 and 833 become smaller as the conductors 831 and 833 are farther separated from the conductor 832 positioned at the center. With this configuration, a magnetic field generated around each of the conductors 831 through 833 is less likely to be interrupted by the conductors 831 and 833. Additionally, in the fourth modified example, the through-hole 820 has a structure in which three cylindrical holes corresponding to the conductors 831 through 833 partially overlap each other. A magnetic field (magnetic flux) generated around each of the conductors 831 through 833 is more likely to pass through the magnetic member (base member 810), thereby further enhancing the inductance.

In the circuit board of the fourth modified example, in a plan view, the conductor 831 is closely disposed at one end of the conductor 832 in the Y direction, while the conductor 833 is closely disposed at the other end of the conductor 832 in the Y direction. This facilitates the formation of magnetic coupling between two or three inductors formed by the conductors 831 through 833.

### Fifth Modified Example

FIG. 36A is a schematic top view of a fifth modified example of a conductor-containing section. FIG. 36B is a schematic sectional view taken along line XXXVIB-XXXVIB in FIG. 36A.

A conductor-containing section 805 of the fifth modified example shown in FIGS. 36A and 36B is different from the conductor-containing section 804 of the fourth modified example shown in FIGS. 35A and 35B in that the through-hole 820 of the base member 810 has a track shape elongated in the Y direction.

In the example in FIGS. 36A and 36B, the conductor 832 is disposed in the rectangular prism region Pa of the through-hole 820. In a plan view, the conductor 832 has a rectangular shape slightly smaller than the rectangular prism region Pa. The conductors 831 and 833 are each disposed in the partial cylindrical region Pb of the through-hole 820. Each of the conductors 831 and 833 may be at least partially disposed in the partial cylindrical region Pb.

As in the fourth modified example, in the fifth modified example, a magnetic field generated around each of the conductors 831 through 833 is less likely to be interrupted by the conductors 831 and 833.

In the fifth modified example, the opening of the through-hole 820 can be made smaller than that in the fourth modified example, thereby further reducing the area of the circuit board. Additionally, the gaps between the first structure M and the inner wall of the through-hole 820 can be made smaller. The conductor 832 and the base member 810, which is a magnetic member, can thus be disposed closer to each other. The conductors 831 through 833 are disposed close to each other in the through-hole 820 having a track-shape opening. As a result, stronger magnetic coupling can be formed between two or three inductors formed by the conductors 831 through 833.

### [Configuration of Circuit Board]

In the circuit board of the third exemplary embodiment, the number of conductors, connection method for conductors, and current direction in the conductor-containing section can be determined by combining those described above in a desired manner. Examples of combinations are indicated in Table 1.

TABLE 1

| | | | | | | | | | | Direction |
|---|---|---|---|---|---|---|---|---|---|---|
| | | | | | | | | | | of |
| | | | Potential of | | | | | | | magnetic |
| | Number | | conductor | | | Direction of current | | | | field |
| Configuration | of | Electrical | First | Second | Third | Parallel/ | First | Second | Third | Same/ |
| example | conductors | isolation | conductor | conductor | conductor | antiparallel | conductor | conductor | conductor | opposite |
| (1) | 2 | 0 | V1 | V1 | | — | | | | — |
| (2) | 2 | 2 | V1 | V2 | | Antiparallel | ↑ | ↓ | | Opposite |
| (3) | 2 | 2 | V1 | V2 | | Parallel | ↑ | ↑ | | Same |
| (4) | 3 | 0 | V1 | V1 | V1 | — | | | | — |
| (5) | 3 | 2 | V1 | V1 | V2 | Antiparallel | ↑ | ↑ | ↓ | Opposite |
| (6) | 3 | 2 | V1 | V1 | V2 | Parallel | ↑ | ↑ | ↑ | Same |
| (7) | 3 | 2 | V1 | V2 | V1 | Antiparallel | ↑ | ↓ | ↑ | Opposite |
| (8) | 3 | 2 | V1 | V2 | V1 | Parallel | ↑ | ↑ | ↑ | Same |
| (9) | 3 | 3 | V1 | V2 | V3 | Parallel | ↑ | ↑ | ↑ | Same |
| (10) | 3 | 3 | V1 | V2 | V3 | Antiparallel | ↑ | ↑ | ↓ | Same |
| | | | | | | | | | | and |
| | | | | | | | | | | opposite |
| (11) | 3 | 3 | V1 | V2 | V3 | Antiparallel | ↑ | ↓ | ↑ | Same |
| | | | | | | | | | | and |
| | | | | | | | | | | opposite |

In Table 1, “Number of conductors” refers to the number of conductors disposed in one through-hole. “Electrical isolation” refers to the number of electrically isolated conductors disposed in one through-hole. “Potential of conductor” refers to the potential of each conductor disposed in one through-hole. The potentials of electrically isolated conductors are different. “Direction of current” refers to the direction of a current flowing through each conductor disposed in one through-hole, and two directions along the Z direction are indicated by the corresponding arrows. The term “Parallel” in Table 1 can indicate that the directions of currents flowing through electrically isolated conductors disposed in one through-hole are the same (parallel). The term “Antiparallel” in Table 1 can indicate that the directions of currents flowing through two electrically isolated conductors disposed in one through-hole are opposite (antiparallel). “Direction of magnetic field” refers to the relationship between the directions of magnetic fields generated around the conductors. “Same” refers to that the directions of magnetic fields around the conductors are the same. “Opposite” refers to that the directions of magnetic fields around the conductors are opposite (opposite circulation directions). In Table 1, in the configuration in which three conductors are arranged in one through-hole, the conductor positioned at the center in the arrangement direction (Y direction, for example) is called a “second conductor”, and conductors at both sides of the second conductor are called a “first conductor” and a “third conductor”.

The conductors in the third exemplary embodiment can be regarded as multiple portions generated by dividing one cylindrical conductor (one conductor within an inductor unit cell) in the Z direction in the first exemplary embodiment. In this case, “Number of conductors” represents the number of portions obtained by physically dividing one cylindrical conductor in the first exemplary embodiment. “Electrical isolation” represents the number of portions obtained by electrically dividing one cylindrical conductor in the first exemplary embodiment.

The conductor-containing sections 800 through 803 illustrated in FIGS. 30 through 34B each include two conductors and are applicable to the circuit boards in configuration examples (1) through (3). The conductor-containing sections 804 and 805 illustrated in FIGS. 35A through 36B each include three conductors and are applicable to the circuit boards in configuration examples (4) through (11).

The circuit board of the third exemplary embodiment can form one or multiple components (inductor, for example) by using the conductor-containing section. An explanation will now be given of examples of the configuration of the inductor using the conductor-containing section and examples of the circuit configuration, based on the circuit boards of the configuration examples (2), (3), and (5) in Table 1.

### Configuration Example (2)

### <Configuration of Inductor>

The circuit board of the configuration example (2) includes multiple conductor-containing sections, multiple first electrodes disposed on the first surfaces of the conductor-containing sections, and multiple second electrodes disposed on the second surfaces of the conductor-containing sections, for example. With this configuration, two inductors are formed. In each conductor-containing section, currents flow through two conductors disposed in one through-hole in the opposite directions (antiparallel) of the Z direction.

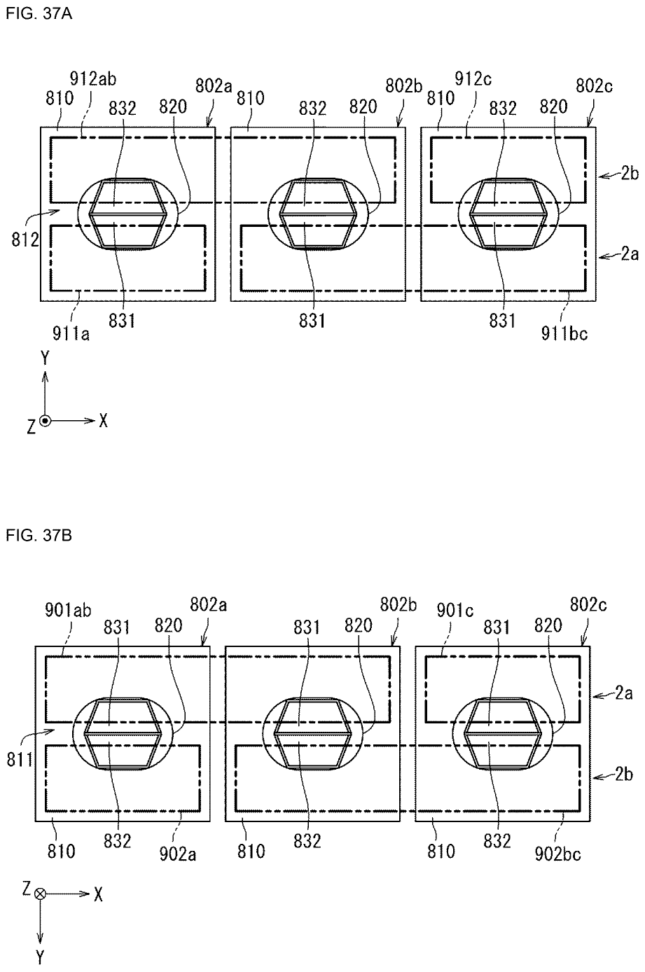

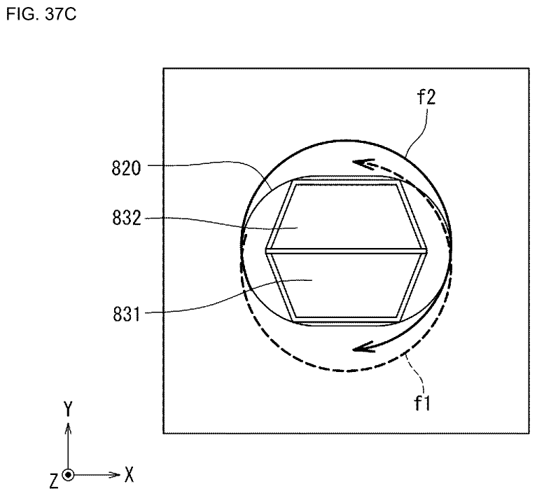

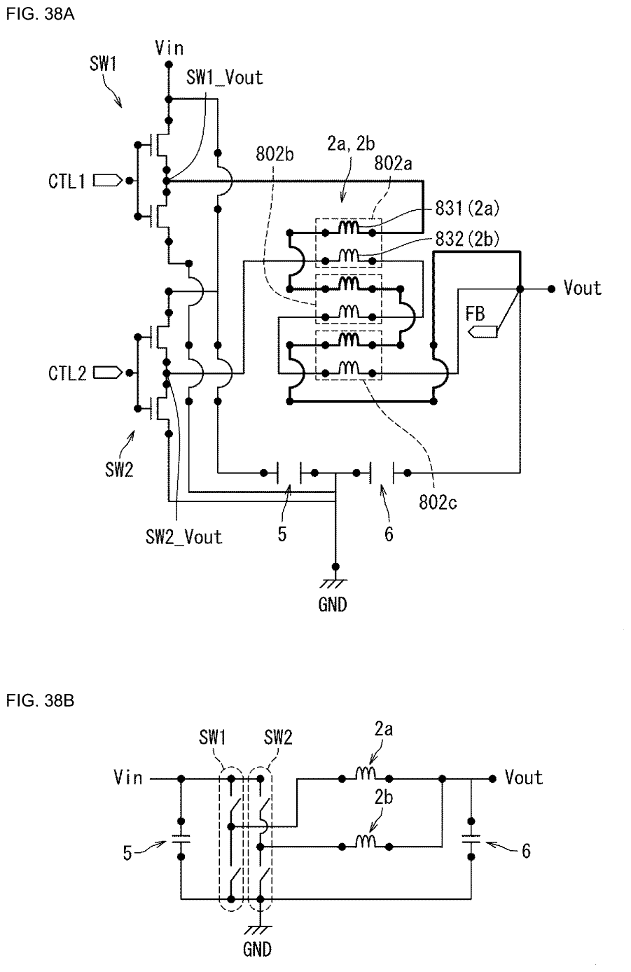

FIG. 37A is a top perspective view schematically illustrating the conductor-containing sections and the second electrodes in the configuration example (2). FIG. 37B is a bottom perspective view schematically illustrating the conductor-containing sections and the first electrodes in the configuration example (2). For easy representation, the first electrodes and the second electrodes are indicated by the long dashed double-dotted lines.

In FIGS. 37A and 37B, in the circuit board, multiple (three in this example) conductor-containing sections 802a through 802c are arranged in the X direction in this order. In each of the conductor-containing sections 802a through 802c, two conductors 831 and 832 are disposed in a through-hole 820. The conductor 832 is positioned on the +Y side of the conductor 831.

In this example, the configuration of each of the conductor-containing sections 802a through 802c is similar to that of the conductor-containing section 802 illustrated in FIGS. 33A and 33B. The configuration of these conductor-containing sections is not limited to the example shown in FIGS. 37A and 37B and may be one of the configuration of the conductor-containing sections 800 through 803 illustrated in FIGS. 30 through 34B.

Multiple (four in this example) first electrodes 901ab, 901c, 902a, and 902bc are provided in the conductor-containing sections 802a through 802c facing the first surface 811. The first electrodes may be disposed in the first wiring layer 110 (FIG. 2), which is positioned closer to the first surface 811 than the other wiring layers of the first wiring structure 100 (FIG. 2). Multiple (four in this example) second electrodes 911a, 911bc, 912ab, and 912c are provided in the conductor-containing sections 802a through 802c facing the second surface 812. The second electrodes may be disposed in the second wiring layer 210 (FIG. 2), which is positioned closer to the second surface 812 than the other wiring layers of the second wiring structure 200 (FIG. 2).

In each of the conductor-containing sections 802a through 802c, the end portions (first end portions) of the conductors 831 and 832 on the first surface 811 are electrically connected to the corresponding first electrodes, while the end portions (second end portions) of the conductors 831 and 832 on the second surface 812 are electrically connected to the corresponding second electrodes. Each end portion of the conductors 831 and 832 may be electrically connected to the corresponding first or second electrode by a via-conductor, for example. Another electrode (electrode corresponding to the electrode 31 or 32 in the first exemplary embodiment) may intervene between the end portion of each conductor and the first or second electrode.

In the configuration example (2), the conductors 831 of the conductor-containing sections 802a through 802c are connected in series with each other so as to form one inductor 2a. The conductors 832 of the conductor-containing sections 802a through 802c are connected in series with each other so as to form one inductor 2b.

The inductor 2a includes the conductors 831 of the conductor-containing sections 802a through 802c, the first electrodes 901ab and 901c, and the second electrodes 911a and 911bc. The second end portion of the conductor 831 of the conductor-containing section 802a is connected to the second electrode 911a and is electrically connected to a predetermined terminal via the second electrode 911a. The first end portions of the conductors 831 of the conductor-containing sections 802a and 802b are electrically connected to each other by the first electrode 901ab. The second end portions of the conductors 831 of the conductor-containing sections 802b and 802c are electrically connected to each other by the second electrode 911bc. The first end portion of the conductor 831 of the conductor-containing section 802c is connected to the first electrode 901c and is electrically connected to a predetermined terminal via the first electrode 901c.

The inductor 2b includes the conductors 832 of the conductor-containing sections 802a through 802c, the first electrodes 902a and 902bc, and the second electrodes 912ab and 912c. The first end portion of the conductor 832 of the conductor-containing section 802a is connected to the first electrode 902a and is electrically connected to a predetermined terminal via the first electrode 902a. The second end portions of the conductors 832 of the conductor-containing sections 802a and 802b are electrically connected to each other by the second electrode 912ab. The first end portions of the conductors 832 of the conductor-containing sections 802b and 802c are electrically connected to each other by the first electrode 902bc. The second end portion of the conductor 832 of the conductor-containing section 802c is connected to the second electrode 912c and is electrically connected to a predetermined terminal via the second electrode 912c.

In the specification, an electrode for electrically connecting two conductors disposed in different through-holes 820 may be called a “connection electrode”. In the example in FIGS. 37A and 37B, the first electrodes 901ab and 902bc and the second electrodes 911bc and 912ab serve as connection electrodes.

In the circuit board of the configuration example (2), the conductors 831 and 832 are electrically isolated from each other. The conductors 831 and 832 can thus form different components (inductors 2a and 2b in this example). Hence, more components can be embedded in the circuit board while limiting the increase in the area of the circuit board. Additionally, as in the first exemplary embodiment, the inductors (vertical direction inductors) 2a and 2b can be formed by connecting conductors of multiple (three in this example) conductor-containing sections 802a through 802c in series with each other. That is, the conductor-containing sections 802a through 802c can serve as inductor unit cells. With this configuration, the circuit board can be made thin.

In the circuit board of the configuration example (2), the conductors 831 and 832 are connected to the corresponding electrodes so that the current directions become antiparallel. Accordingly, the directions of magnetic fields generated by the conductors 831 and 832 become opposite (opposite circulation directions).

FIG. 37C is an enlarged top view schematically illustrating an example of magnetic fields generated by the conductors 831 and 832. In FIG. 37C, magnetic fields f1 and f2 generated when a current flows through the conductor 831 in the +Z direction (from the first end portion toward the second end portion) and when a current flows through the conductor 832 in the −Z direction (from the second end portion toward the first end portion) are shown. As illustrated in FIG. 37C, in each conductor-containing section, the magnetic field f1 generated around the conductor 831 and the magnetic field f2 generated around the conductor 832 are oriented in the opposite directions (opposite circulation directions) and cancel each other out. As a result, magnetic saturation is less likely to occur, thereby suppressing the degradation of the inductance characteristics of each inductor formed by the conductors 831 and 832, which would be caused by magnetic saturation.

When the conductors 831 and 832 are placed close to each other within the through-hole 820, the two magnetic fields f1 and f2 approach even closer and can thus cancel each other out more effectively. The amounts of currents flowing through the conductors 831 and 832 may be substantially the same. With this configuration, magnetic saturation can be reduced more effectively.

### <Circuit Configuration>

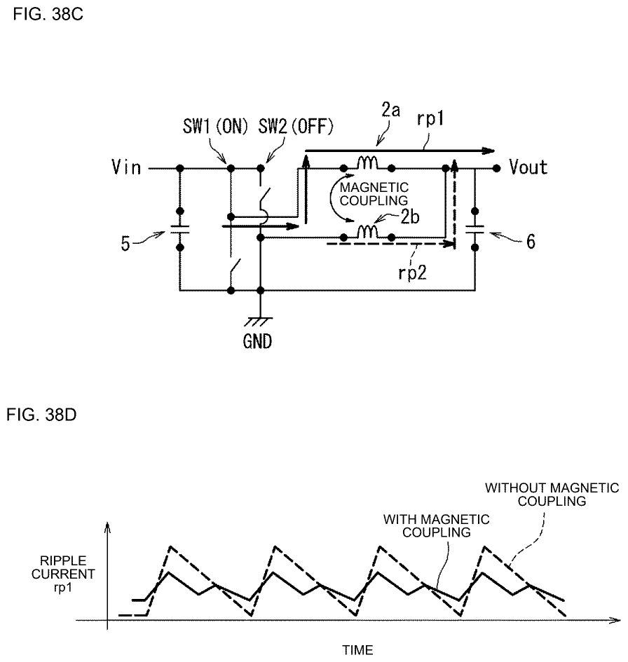

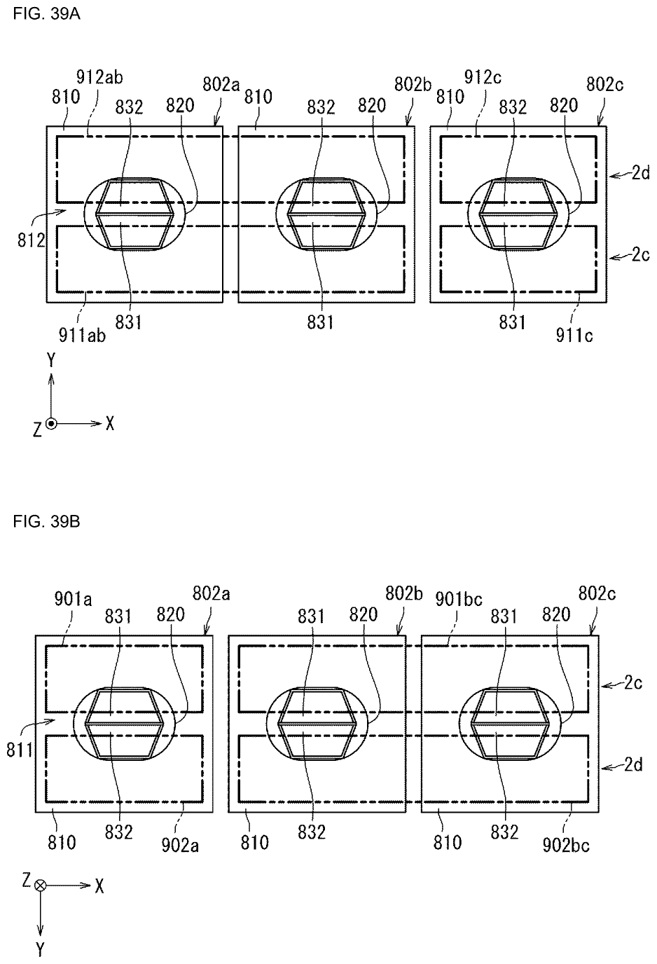

FIG. 38A is a diagram illustrating an example of the circuit configuration of a voltage regulator module (buck DC-DC converter) using the circuit board of the configuration example (2). FIG. 38B illustrates a simplified form of the circuit configuration shown in FIG. 38A. The voltage regulator module shown in FIGS. 38A and 38B is a DC-DC converter having multiple phases (multi-phase).

The DC-DC converter shown in FIGS. 38A and 38B includes the circuit board of the configuration example (2) and two switching devices SW1 and SW2. This module has phase 1 in which the switching device SW1 is ON and the switching device SW2 is OFF and phase 2 in which the switching device SW2 is ON and the switching device SW1 is OFF.

The inductors 2a and 2b, the input capacitor 5, and the output capacitor 6 forming the circuit are embedded in the circuit board (component-embedded base body). The structure of the capacitors 5 and 6 may be similar to that in the first exemplary embodiment. Terminals, such as control terminals CTL, an input terminal Vin, an output terminal Vout, and a ground terminal GND, are formed in the first wiring structure (see FIG. 23A), for example. Terminal lands for the terminals (SW1_CTL, SW2_CTL, SW1_Vout, SW2_Vout, SW_GND) of the switching devices SW1 and SW2 are formed in the second wiring structure (see FIG. 23B), for example.

The inductor 2a is connected between the SW1_Vout terminal of the switching device SW1 and the output terminal Vout. The inductor 2b is connected between the SW2_Vout terminal of the switching device SW2 and the output terminal Vout. The inductors 2a and 2b have the structure shown in FIGS. 37A and 37B, for example. In each of the conductor-containing sections 802a through 802c, the direction of a current flowing through the conductor 831 forming the inductor 2a and that through the conductor 832 forming the inductor 2b are opposite (antiparallel).

Preferably, the two conductors in each conductor-containing section are disposed close to each other to such a degree as to generate magnetic coupling therebetween. The reason for this will be explained below with reference to FIGS. 38C and 38D. FIG. 38C is a diagram illustrating phase 1 of the DC-DC converter shown in FIGS. 38A and 38B. FIG. 38D is a schematic graph illustrating waveforms of a ripple current occurring in phase 1 of the DC-DC converter.

As illustrated in FIG. 38C, in phase 1, a ripple current rp1 is formed in the inductor 2a connected to the switching device SW1 that is ON. Then, a ripple current rp2, which is induced by the ripple current rp1, flows through the switching device SW2 via magnetic coupling. These ripple currents rp1 and rp2 are generated to decrease the each other's current amplitudes. As a result, as illustrated in FIG. 38D, the current amplitudes of the ripple currents rp1 and rp2 generated in each phase can be made smaller through the use of magnetic coupling than those without magnetic coupling.

In a typical DC-DC converter, it is necessary to increase the inductance to limit a ripple current to a predetermined value (about 30% of a load current, for example) or lower. In contrast, in the DC-DC converter shown in FIG. 38A, the ripple current can be suppressed as shown in FIG. 38D, so that a smaller inductance can be set. As a result, the inductors 2a and 2b can be further reduced in size.

### Configuration Example (3)

### <Configuration of Inductor>

The circuit board of the configuration example (3) includes multiple conductor-containing sections, multiple first electrodes, and multiple second electrodes, for example. With this configuration, two inductors are formed. In each conductor-containing section, currents flow through two conductors disposed in one through-hole in the same direction of the Z direction.

FIG. 39A is a top perspective view schematically illustrating the conductor-containing sections and the second electrodes in the configuration example (3). FIG. 39B is a bottom perspective view schematically illustrating the conductor-containing sections and the first electrodes in the configuration example (3). For easy representation, the first electrodes and the second electrodes are indicated by the long dashed double-dotted lines. The configuration example (3) will be explained below by mainly referring to the points different from the configuration example (2) while omitting the same points as the configuration example (2).

In the example in FIGS. 39A and 39B, multiple (four in this example) first electrodes 901a, 901bc, 902a, and 902bc are provided in the conductor-containing sections 802a through 802c facing the first surface 811. Multiple (four in this example) second electrodes 911ab, 911c, 912ab, and 912c are provided in the conductor-containing sections 802a through 802c facing the second surface 812.

In the configuration example (3), the conductors 831 of the conductor-containing sections 802a through 802c are connected in series with each other so as to form one inductor 2c. The conductors 832 of the conductor-containing sections 802a through 802c are connected in series with each other so as to form one inductor 2d.

The inductor 2c includes the conductors 831 of the conductor-containing sections 802a through 802c, the first electrodes 901a and 901bc, and the second electrodes 911ab and 911c. The first end portion of the conductor 831 of the conductor-containing section 802a is electrically connected to a predetermined terminal via the first electrode 901a. The second end portions of the conductors 831 of the conductor-containing sections 802a and 802b are electrically connected to each other by the second electrode 911ab. The first end portions of the conductors 831 of the conductor-containing sections 802b and 802c are electrically connected to each other by the first electrode 901bc. The second end portion of the conductor 831 of the conductor-containing section 802c is electrically connected to a predetermined terminal via the second electrode 911c. The inductor 2d has the same structure as the inductor 2b in the circuit configuration example (2).

In the circuit board of the configuration example (3), too, the conductors 831 and 832 are electrically isolated from each other. The conductors 831 and 832 can thus form different components (inductors 2c and 2d in this example).

In the circuit board of the configuration example (3), the conductors 831 and 832 are connected to the corresponding electrodes so that the current directions become parallel. Accordingly, magnetic fields generated by the conductors 831 and 832 are oriented in the same direction and can be reinforced each other. The characteristics of the inductors formed by the conductors 831 and 832 can thus be enhanced.

### <Circuit Configuration>

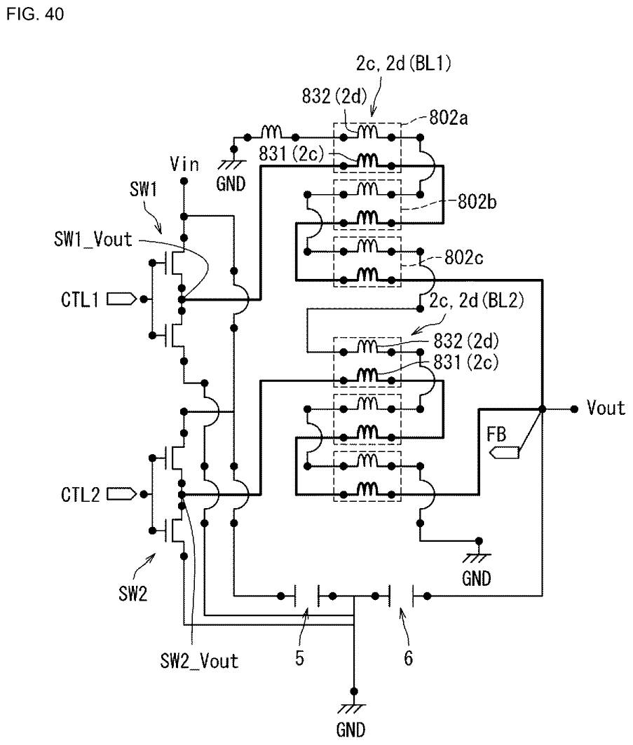

FIG. 40 illustrates an example of the circuit configuration of a voltage regulator module (buck DC-DC converter) using the circuit board of the configuration example (3). The DC-DC converter shown in FIG. 40 is a multi-phase DC-DC converter including two switching devices SW1 and SW2.

In this example, two sets of inductors 2c and 2d (hereinafter one set will be called an “inductor block BL1” and the other set will be called an “inductor block BL2”) are embedded in the circuit board. The inductor 2c of the inductor block BL1 is connected between the SW1_Vout terminal of the switching device SW1 and the output terminal Vout. The inductor 2c of the inductor block BL2 is connected between the SW2_Vout terminal of the switching device SW2 and the output terminal Vout. The inductors 2d of the inductor blocks BL1 and BL2 are connected in series with each other between ground terminals GND.

The inductors 2c and 2d of each of the inductor blocks BL1 and BL2 have the structure illustrated in FIGS. 39A and 39B. In each of the conductor-containing sections 802a through 802c, the direction of a current flowing through the conductor 831 forming the inductor 2c and that through the conductor 832 forming the inductor 2d are the same (parallel).

In the DC-DC converter shown in FIG. 40, the structure, which is known as a trans-inductor voltage regulator (TLVR), is embedded in the circuit board, thereby improving the load transient response characteristics. The two conductors 831 and 832 in each of the conductor-containing sections 802a through 802c are disposed close to each other and are thus magnetically coupled more strongly, thereby further improving the load transient response characteristics.

This advantage will be explained below in greater detail. In a known multi-phase power source, variations in the load current of an inductor are detected from a change in a FB voltage at a FB terminal. A control IC compensates for an excess or a shortage of a current incurred by current variations by controlling the duty ratio (ratio of the ON time to the OFF time) of signals applied to the control terminals CTL1 and CTL2. That is, feedback control is performed using the control IC.

In contrast, in the circuit shown in FIG. 40, in phase 1 in which one of the switching devices (switching device SW1, for example) is ON, variations in the load current of the inductor 2c (inductor 2c of the inductor block BL1) connected to the switching device SW1 are detected by the inductor 2d. Then, a current equivalent to the amount by which the load current is varied is supplied from the inductor 2c of the inductor block BL2 via magnetic coupling. This configuration compensates for an excess or a shortage of the current. In this manner, operating the inductors 2c of the inductor blocks BL1 and BL2 collaboratively can implement a fast load transient response. With this circuit configuration, prior to feedback control using the control IC, an excess or a shortage of a current caused by current variations can be corrected (fed back), thereby implementing a faster operation.

### Configuration Example (5)

### <Configuration of Inductor>

The circuit board of the configuration example (5) includes multiple conductor-containing sections, multiple first electrodes, and multiple second electrodes, for example. With this configuration, two inductors are formed. In each conductor-containing section, three conductors are disposed in one through-hole. The direction of a current flowing through two of the three conductors and that through the remaining conductor are opposite (antiparallel) along the Z direction.

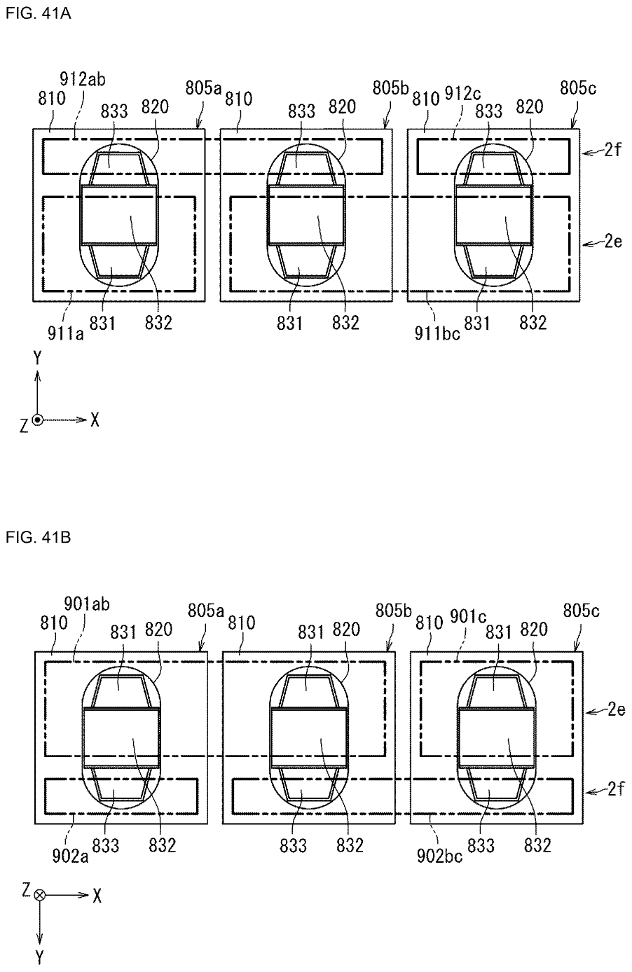

FIG. 41A is a top perspective view schematically illustrating the conductor-containing sections and the second electrodes in the configuration example (5). FIG. 41B is a bottom perspective view schematically illustrating the conductor-containing sections and the first electrodes in the configuration example (5). For easy representation, the first electrodes and the second electrodes are indicated by the long dashed double-dotted lines. The configuration example (5) will be explained below by mainly referring to the points different from the configuration example (2) while omitting the same points as the configuration example (2).

In FIGS. 41A and 41B, in the circuit board, multiple (three in this example) conductor-containing sections 805a through 805c are arranged in the X direction in this order. In each of the conductor-containing sections 805a through 805c, a conductor 832 is positioned between conductors 831 and 833 in the Y direction.

In this example, the configuration of each of the conductor-containing sections 805a through 805c is similar to that of the conductor-containing section 805 illustrated in FIGS. 36A and 36B. The configuration of these conductor-containing sections is not limited to the example shown in FIGS. 41A and 41B and may be the configuration of the conductor-containing section 804 illustrated in FIGS. 35A and 35B, for example.

As in the configuration example (2), in this example, first electrodes 901ab, 901c, 902a, and 902bc and second electrodes 911a, 911bc, 912ab, and 912c are provided in the circuit board. The conductors 831 and 832 in each conductor-containing section are connected to the same electrode to have the same potential. The conductor 833 in each conductor-containing section is connected to another electrode to have a different potential.

In the configuration example (5), the conductors 831 and 832 of the conductor-containing sections 805a through 805c are connected in series with each other so as to form one inductor 2e. The conductors 833 of the conductor-containing sections 805a through 805c are connected in series with each other so as to form one inductor 2f.

In the inductor 2e, the first electrodes 901ab and 901c and the second electrodes 911a and 911bc electrically connect the conductors 831 and 832 of the conductor-containing sections with each other, and, as in the first inductor 2a in the configuration example (2), they are arranged to connect conductor pairs formed by the conductors 831 and 832 of the conductor-containing sections 805a through 805c in series with each other. In the inductor 2f, as in the inductor 2b in the configuration example (2), the first electrodes 902a and 902bc and the second electrodes 912ab and 912c are arranged to connect the conductors 833 of the conductor-containing sections 805a through 805c in series with each other.

In the circuit board in the configuration example (5), the conductors 831 and 832 and the conductor 833 are disposed close to each other in the through-hole 820 and are connected to the corresponding electrodes so that the direction of a current flowing through the conductors 831 and 832 and that of a current flowing through the conductor 833 become antiparallel. Accordingly, the direction of a magnetic field generated by the conductors 831 and 832 and that by the conductor 833 become opposite. As a result, magnetic saturation is less likely to occur, thereby suppressing the degradation of the inductance characteristics, which would be caused by magnetic saturation.

### Other Configuration Examples

### Configuration Example (1)

In the configuration examples (2) and (3), the conductors 831 and 832 are electrically isolated from each other. However, the conductors 831 and 832 may be electrically connected. For example, the first end portions of the conductors 831 and 832 may be electrically connected to each other by the first electrode, while the second end portions of the conductors 831 and 832 may be electrically connected to each other by the second electrode (configuration (1)). In the configuration example (1), the potentials of these conductors become the same and the directions of currents flowing through these conductors become the same.

### Configuration Example (4)

In the configuration example (5), among the conductors 831 through 833 in each conductor-containing section, two conductors and the remaining conductor are electrically isolated from each other. However, it is not essential that two conductors and the remaining conductor are electrically isolated. For example, the first end portions of the three conductors may be electrically connected to each other by the first electrode, while the second end portions of the conductors may be electrically connected to each other by the second electrode (configuration (4)). In the configuration example (4), the potentials of these conductors become the same and the directions of currents flowing through these conductors become the same.

### Configuration Example (6)

In the configuration example (5), among the conductors 831 through 833 in each conductor-containing section, two conductors and the remaining conductor are electrically isolated from each other, and the directions of currents flowing through the two portions (that is, the direction of a current flowing through the conductors 831 and 832 and that through the conductor 833) are antiparallel. However, the directions of these currents may be parallel (configuration example (6)).

### Configuration Examples (7) and (8)

In the configuration example (5), among the conductors 831 through 833 in each conductor-containing section, the conductors 831 and 832 have the same potential V1, while the conductor 833 has the different potential V2. However, the conductors 831 and 833 may have the same potential V1, while the central conductor 832 may have the different potential V2. In this case, the direction of the current flowing through the conductors 831 and 833 and that through the conductor 832 may be antiparallel (configuration example (7)) or may be parallel (configuration example (8)).

### Configuration Examples (9) Through (11)

The conductors 831 through 833 in each conductor-containing section may be electrically isolated from each other (that is, electrically separated into three portions). In this case, the directions of currents flowing through the conductors 831 through 833 may be the same (parallel) (configuration example (9)). Alternatively, the directions of currents flowing through the conductors 831 and 832 may be the same, while the direction of a current flowing through the conductor 833 may be opposite of that in the conductors 831 and 832 (antiparallel) (configuration example (10)). Alternatively, the directions of currents flowing through the conductors 831 and 833 at both ends may be the same, while the direction of a current flowing through the central conductor 832 may be opposite of that in the conductors 831 and 833 (antiparallel) (configuration example (11)). In the configuration examples (10) and (11), the directions of magnetic fields generated in two of the electrically isolated three conductors 831 through 833 are the same, while the direction of a magnetic field generated in the remaining conductor is the opposite of the magnetic fields in the above-described two conductors (combination of the same direction and the opposite direction).

The configuration of the circuit board of the third exemplary embodiment is not limited to the above-described configurations. In Table 1, the number of conductors is two or three, but may be four or more. In FIGS. 37A through 41B, examples of the circuit board including three conductor-containing sections are shown. However, the circuit board of the third exemplary embodiment may include at least one conductor-containing section and the number of conductor-containing sections is not limited to a specific number. Additionally, the circuit board of the third exemplary embodiment may also include a conductor-containing section configured differently from another conductor-containing section (for example, the number and the shape of conductors of one conductor-containing section are different from those of another conductor-containing section).

The position, shape, and cross-sectional area of the conductors 831 through 833, and the position and the shape of electrodes are not limited to the examples in the drawings and may suitably be set in accordance with the design of the circuit board. In FIGS. 30 through 41B, all the conductors 831 through 833 are formed in a quadrilateral prism, but may be formed in another polygonal prism. The conductors may have a shape other than a polygonal prism, such as a cylinder, a semi-cylinder, an elliptical cylinder, and a semi-elliptical cylinder. In the examples in FIGS. 30 through 33B, the cross-sectional areas of the conductors 831 and 832 are equal but may be different. In the examples in FIGS. 35A through 36B, the cross-sectional areas and the shapes of the conductors 831 and 833 are equal but may be different. In a plan view, the conductors 831 and 833 are arranged symmetrically with respect to the conductor 832, but may be arranged asymmetrically.

The configuration of the DC-DC converter using the circuit board of the third exemplary embodiment is not limited to those shown in FIGS. 38A and 40. In FIG. 38A, the circuit board having the configuration example (2) is used, but instead, the circuit board having another configuration in which the directions of currents flowing through two conductors in a through-hole are parallel may be used. In FIG. 40, the circuit board having the configuration example (3) is used, but instead, the circuit board having another configuration in which the directions of currents flowing through two conductors in a through-hole are antiparallel may be used. The circuit configuration and the number of switching devices are not limited to the examples in FIGS. 38A and 40, either. The circuit board in either one of the configuration examples (1) and (4) may be used to form the DC-DC converter shown in FIG. 6.

In the above-described examples, the conductor-containing sections forming inductors have been discussed. However, the conductor-containing section may form a component other than an inductor.

### [Manufacturing Method for Conductor-Containing Section]

A manufacturing method for the conductor-containing section of the third exemplary embodiment will be discussed below. As an example, an explanation will be given of a case in which a first structure M including a conductor 832 having a rectangular cross section and a conductor 831 having a trapezoidal cross section, as in the conductor-containing section 803 shown in FIGS. 34A and 34B, is manufactured.

### (Manufacturing of First Structure M)

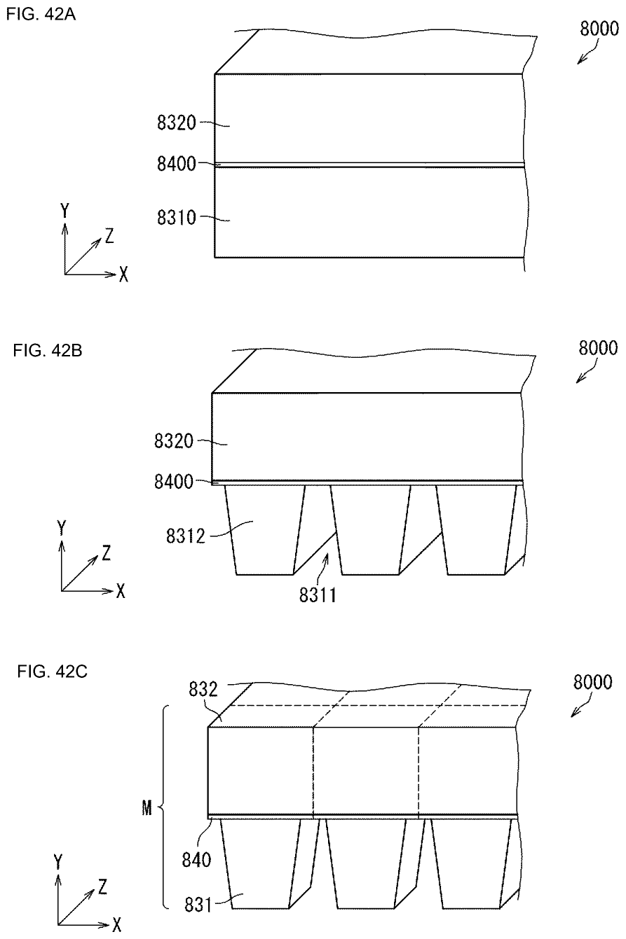

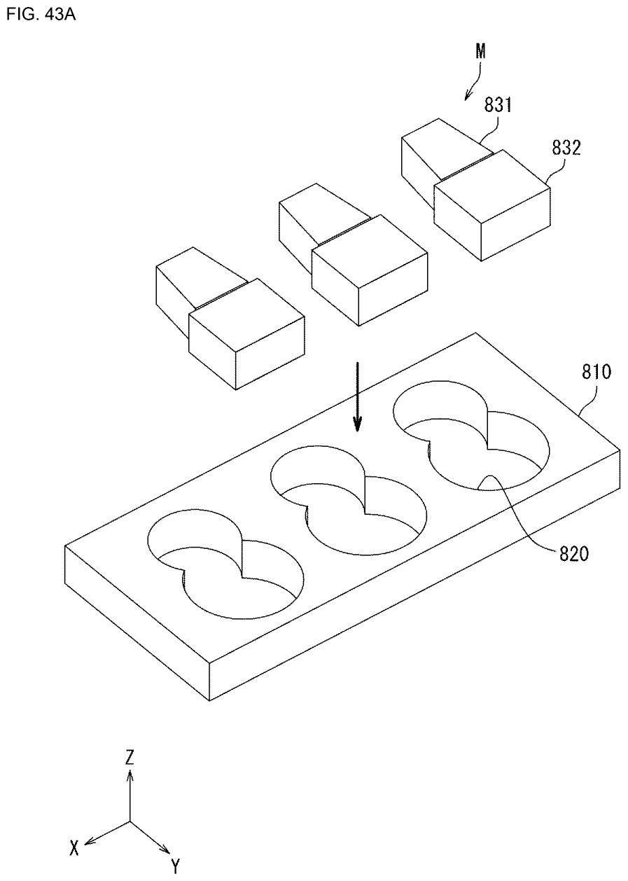

FIGS. 42A through 42C are schematic perspective views for explaining a manufacturing method for the first structure M. First, as illustrated in FIG. 42A, a multilayer body 8000 is formed by stacking a first metal foil (copper foil, for example) 8310, which is to form the conductor 831, a second metal foil (copper foil, for example) 8320, which is to form the conductor 832, with a bonding layer (bonding sheet, for example) 8400, which is to form the separation insulating layer 840, interposed therebetween. Then, as illustrated in FIG. 42B, the first metal foil 8310 and/or the second metal foil 8320 are processed (etched). In this example, multiple grooves 8311 extending in one direction (Z direction in FIG. 42B) are formed in the first metal foil 8310 to separate the first metal foil 8310 into multiple portions 8312. Each portion 8312 has a quadrilateral prism shape having a trapezoidal cross section. An insulating film, which is to form the insulating layer 850, may be formed on the top surface and the bottom surface of the processed multilayer body 8000, though it is not shown. Then, as illustrated in FIG. 42C, the multilayer body 8000 is cut in a direction intersecting with (perpendicular to, in this example) the top surface of the multilayer body 8000. As a result, multiple first structures M are obtained.

### (Manufacturing of Conductor-Containing Section)

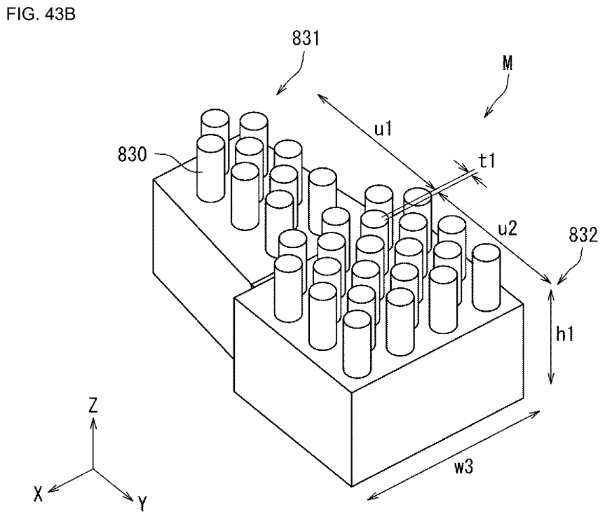

FIG. 43A is a schematic perspective view for explaining a manufacturing method for a conductor-containing section. As illustrated in FIG. 43A, a base member (magnetic member, for example) 810 having through-holes 820 is prepared. The dimension of the base member 810 in the X direction is 4.0 mm, for example, while the dimension of the base member in the Y direction is 3.0 mm, for example. Each through-hole 820 is obtained by forming a cylindrical through-hole (first hole) having a radius d1 and a cylindrical through-hole (second hole) having a radius d2 by drilling, for example, to partially overlap each other. In this example, in the base member 810, multiple (three in this example) through-holes 820 are arranged in the X direction with a distance (0.75 mm, for example) therebetween.

Then, the first structures M manufactured in the above-described method are inserted into the respective through-holes 820 in the base member 810. The first structures M are then sealed. In this example, a resin member, which is to form an insulating portion 860, is formed in gaps between the first structures M and the inner walls of the corresponding through-holes 820, and a sealing insulating layer is formed to cover the top surface and the bottom surface of each conductor. Subsequently, via-holes are formed in the sealing insulating layer and via-conductors are formed in the via-holes.

FIG. 43B is a perspective view illustrating the first structure M on which the via-conductors are formed. In FIG. 43B, the sealing insulating layer is not shown.

As illustrated in FIG. 43B, multiple via-conductors 830 are formed on the first end surface and the second end surface of the conductors 831 and 832 with a distance therebetween. The first end surfaces of the conductors 831 and 832 are surfaces facing the first surface 811 (see FIG. 34B) of the base member 810. The second end surfaces of the conductors 831 and 832 are surfaces facing the second surface 812 (see FIG. 34B) of the base member 810. The thickness h1 of the conductors 831 and 832 in the Z direction is determined by the thickness of the base member 810 and is 0.8 mm, for example. The width t1 of the separation insulating layer 840 can be adjusted by the thickness of the bonding layer 8400 shown in FIG. 42A and is 0.015 mm, for example.

Then, if necessary, electrodes (corresponding to the electrodes 31 and 32 in the first exemplary embodiment) may be formed on the via-conductors. An electrode may be formed for each via-conductor. In this manner, conductor-containing sections are manufactured.

The base member 810 including three conductor-containing sections formed as described above may be disposed in an opening of a core base member 10 (see FIG. 3A). Alternatively, the base member 810 may be divided into portions corresponding to the conductor-containing sections and then disposed in the opening of the core base member. A component-embedded base body is obtained in this manner. Subsequently, as in the first exemplary embodiment, wiring structures are formed on both surfaces of the component-embedded base body. As a result, a circuit board can be manufactured.

### (Design Method)

FIGS. 44A and 44B are schematic top views of the first structure M for explaining an example of the design method for the first structure M.

The X-direction and Y-direction dimensions of the conductors 831 and 832 are determined so that magnetic fields can be easily generated by the conductors 831 and 832 and the cross-sectional areas of the conductors 831 and 832 are enlarged. The relationship between the X-direction and Y-direction dimensions of the conductors 831 and 832 and the opening shape of the through-hole 820 will be explained below with reference to FIG. 44A.

In the example in FIG. 44A, the structure of the through-hole 820 is such that a cylindrical first hole having a radius d1 and a cylindrical second hole having a radius d2 are placed to partially overlap each other. The first region Pc1 defined by the inner wall of the first hole and the second region Pc2 defined by the inner wall of the second hole are in communication with each other. In a plan view, the radii d1 and d2 and the center-to-center distance d3 between the first hole and the second hole are set to satisfy the relationship represented by the following expression:

$${( d 3 )}^{2} \leq {( d 1 )}^{2} + {( d 2 )}^{2}$$

With this relationship, in a plan view, at a point at which the inner wall of the first hole and that of the second hole intersect each other, the angle x between a tangent to the inner wall of the first hole and that to the inner wall of the second hole does not become an acute angle, thereby reducing the magnetic resistance and thus enhancing magnetic coupling between the conductors 831 and 832. In this example, the radius d2 is larger than the radius d1 (d2>d1). The radius d1 is 0.5 mm, for example, while the radius d2 is 0.65 mm, for example.

In a plan view, the conductor 832 has a polygonal shape slightly smaller than a polygon inscribed in the second region Pc2, which is a partial circle. The polygon is an n-gon (n is four or greater), for example. The conductor 832 can thus be disposed within the second region Pc2 of the through-hole 820.

In FIG. 44A, the conductor 832 has a rectangular shape, for example, in a plan view. The dimension u2 of the conductor 832 in the Y direction can be adjusted by the thickness of the second metal foil 8320 (FIG. 42A) and is 0.8 mm, for example. The dimension w3 of the conductor 832 in the X direction can be adjusted by etching and is 1.0 mm, for example.

In a plan view, the conductor 831 is a polygon having two vertices close to the −Y side of the conductor 832 (the side of the conductor 832 closest to the first region Pc1). The polygon is an n-gon (n is four or greater), for example. In a plan view, among the polygonal vertices of the conductor 831, the vertex which is farthest from the conductor 832 may be positioned slightly more inward than a point of an arc in the first region Pc1, which is a partial circle. With this arrangement, the cross-sectional area of the conductor 831 can be made larger while the conductor 832 is placed within the second region Pc2.

In FIG. 44A, in a plan view, the conductor 831 has a trapezoidal shape whose bottom base faces the conductor 832, and two vertices at both sides of the top base of the trapezoid is positioned slightly more inward than a point on an arc in the first region Pc1, which is a partial circle. The dimension u1 of the conductor 831 in the Y direction can be adjusted by the thickness of the first metal foil 8310 (FIG. 42A) and is 0.8 mm, for example. The widths w1 and w2 of the conductor 831 in the X direction can be adjusted by etching. The width w1 (dimension of the bottom base of the trapezoid) is 0.7 mm, for example. The width w2 (dimension of the top base of the trapezoid) is 0.5 mm, for example. The base angle at both ends of the bottom base of the trapezoid can be adjusted to a desired angle (acute angle) by changing the etching method and etching conditions. In this example, the dimensions u1 and u2 are equal but may be different from each other.

An explanation will now be given, with reference to FIG. 44B, of the size of the via-conductors 830 and an example of the arrangement of the via-conductors 830. One end portion of each of the via-conductors 830 is connected to an end surface (first end surface or second end surface) of the conductor 831 or 832. The via-conductors 830 are each formed in a cylindrical shape having a radius d4 and extend in the Z direction to separate from the end surfaces of the conductors 831 and 832. Via-conductors 830 are adjacent to each other with at least a distance d5 therebetween. In one example, in a plan view, concentric circles formed by circles having a radius d4 and virtual circles 830i having a radius (d4+d5) may be arranged on the end surfaces of the conductors 831 and 832 to determine the positions and the number of via-conductors 830. This can dispose multiple via-conductors 830 more densely on the first end surfaces of the conductors 831 and 832 while securing a predetermined space (distance d5). The radius d4 of the cylindrical via-conductor 830 is 0.0575 mm, for example. The distance d5 is 0.05 mm, for example.

In the above-described method, the first structure M including the conductors 831 and 832 separated from each other by the separation insulating layer 840 is disposed in the single through-hole 820 of the base member 810. The first structure M, which is separately manufactured, is disposed in the through-hole of the base member 810, so that the conductors 831 and 832 can be placed more easily in the through-hole 820 with a predetermined distance therebetween. The distance and the positional relationship between the conductors 831 and 832 can also be easily controlled.

In the above-described method, the through-hole 820 and the first structure M may have a planar shape elongated in one direction or an asymmetrical shape. This makes it possible to more easily place the conductors 831 and 832 in a predetermined orientation. No additional structure and step for alignment becomes unnecessary, which is advantageous.

The manufacturing method for the circuit board of the third exemplary embodiment is not limited to the above-described method. For example, multiple columnar conductors (cylindrical Cu pins, for example) whose peripheral surfaces are covered with an insulating layer may be prepared and be placed in a single through-hole of the base member. Then, portions of the through-hole without the conductors may be filled with a resin.

### Fourth Exemplary Embodiment

In a fourth exemplary embodiment, a voltage regulator module including an inductor-embedded circuit board will be described. The voltage regulator module will be explained below through illustration of an example in which the circuit board 1 illustrated in FIGS. 1 and 2 is used as the inductor-embedded circuit board.

FIG. 45 is a schematic sectional view illustrating an example of a voltage regulator module 400 according to the fourth exemplary embodiment. The voltage regulator module 400 is a buck converter having the circuit configuration discussed with reference to FIG. 6, for example.

The voltage regulator module 400 is disposed on a main surface 500s of a system board (motherboard) 500, for example. On the main surface 500s, a power management IC (PMIC) may also be disposed. A processor may be disposed on the main surface of the system board 500 opposite the main surface 500s, though it is not shown.

The voltage regulator module 400 includes the circuit board 1 having an inductor embedded therein and a switching device SW.

The circuit board 1 is the same as the circuit board 1 of the first exemplary embodiment. In the circuit board 1, the inductor 2 and two-terminal capacitors (input capacitor and output capacitor, for example) are embedded. The circuit board 1 has a first main surface s1 on which terminals, such as the input terminal Vin and the output terminal Vout, are disposed. The first main surface s1 faces the main surface 500s of the system board 500.

The switching device SW is disposed on a first main surface s1 of the circuit board 1. The switching device SW includes a MOSFET on the high side, a MOSFET on the low side, and multiple terminals (see FIG. 6). The terminals of the switching device SW are connected to the corresponding lands on the second main surface s2 of the circuit board 1.

In the voltage regulator module 400 of the fourth exemplary embodiment, components, such as the inductor 2 and two-terminal capacitors, are arranged side by side within the circuit board 1. The inductor 2 is divided into multiple portions and embedded in the circuit board 1. The voltage regulator module 400 can thus be made thinner.

In the voltage regulator module 400 of the fourth exemplary embodiment, the output terminal p1 of the inductor 2 is located on the side facing the first main surface s1. It is thus possible to decrease the path between the output terminal p1 of the inductor 2 and the output terminal Vout. The input terminal p2 of the inductor 2 is located on the side facing the second main surface s2. It is thus possible to decrease the path between the input terminal p2 of the inductor 2 and the switch output terminal SW_Vout of the switching device SW. This configuration further reduces the electrical resistance in a range from the switch output terminal SW_Vout of the switching device SW to the output terminal Vout. The voltage regulator module 400 having higher efficiency can thus be provided.

The configuration and the arrangement of the voltage regulator module of the fourth exemplary embodiment are not limited to the example shown in FIG. 45. As the circuit board, any one of the circuit boards discussed in the first through third exemplary embodiments can be used. The voltage regulator module of the fourth exemplary embodiment may be configured in a desired manner if the inductor embedded in the circuit board of the fourth exemplary embodiment is connected between the output terminal of the switching device and the output terminal of the module. In the fourth exemplary embodiment, the inductor-embedded circuit board is applied to a buck converter. However, the inductor-embedded circuit board is applicable to another type of regulator, such as a boost converter or a buck-boost converter.

The present disclosure is not limited to the above-described exemplary embodiments, and any design change may be made without departing from the spirit and scope of the disclosure. Among the above-described various embodiments (including modified examples), the configurations of certain embodiments may suitably be combined, and the corresponding advantages can be achieved.

### REFERENCE SIGNS LIST

1 circuit board (inductor-embedded circuit board)
2, 2a to 2f inductor
3, 3a to 3c conductor
4, 4a to 4c magnetic member
4L magnetic layer
5 input capacitor
6 output capacitor
7, 71 to 73 core through-conductor
8 sealing member
10 base member (core base member)
11 first surface
12 second surface
13a to 13c, 14 to 16 through-hole (core through-hole)
20, 20a to 20c inductor unit cell
21 first cell insulating portion
22 second cell insulating portion
23 insulating portion
24, 25 sealing insulating layer
31, 31a to 31c, 31ab first electrode
32, 32a to 32c, 32bc second electrode
41 magnetic through-hole
51, 61 lower electrode
52, 62 upper electrode
53 dielectric member
81 lower insulating layer
82 upper insulating layer
83 insulating portion
91 first insulator
92 second insulator
100 first wiring structure
101 to 103, 201 to 203 insulating layer
105, 205 solder resist layer
110, 120, 130, 210, 220, 230 wiring layer
111 first connection electrode
112 first inductor connection electrode
113 first input capacitor connection electrode
200 second wiring structure
211 second inductor connection electrode
212 second connection electrode
213 second input capacitor connection electrode
214 output capacitor connection electrode
300, 300a component-embedded base body
400 voltage regulator module
410, 420 MOSFET
500 system board
800 to 805, 802a to 802c, 805a to 805c conductor-containing section
811 first surface
812 second surface
810 base member
820 through-hole
830 via-conductor
831 to 833
conductor
831a, 832a, 833a first side surface
831b, 832b second side surface
840 separation insulating layer
841 first separation insulating layer
842 second separation insulating layer
850 insulating layer
860 insulating portion
901a, 901ab, 901bc, 901c, 902a, 902bc first electrode
911a, 911ab, 911bc, 911c, 912ab, 912c second electrode
M first structure
CTL control terminal
e1 first end surface
e2 second end surface
r1 inductor placement region
r2 capacitor placement region
r3 core through-conductor placement region
SW, SW1, SW2 switching device

1. A conductor-embedded circuit board comprising:
a base member having a first surface and a second surface that is opposite to the first surface in a thickness direction of the base member, a through-hole extending in the base member from the first surface to the second surface in the thickness direction;
a first wiring layer on the first surface of the base member;
a second wiring layer on the second surface of the base member;
a first conductor and a second conductor in the through-hole and each extending in the thickness direction; and
a first separation insulating layer that is between the first conductor and the second conductor within the through-hole in a plan view in the thickness direction, such that the first separation insulating layer separates the first conductor from the second conductor.

2. The conductor-embedded circuit board according to claim 1, wherein the first conductor and the second conductor are electrically isolated from each other.

3. The conductor-embedded circuit board according to claim 2, wherein the first conductor and the second conductor are configured such that a current flowing through the first conductor is in an opposite direction from a current flowing through the second conductor.

4. The conductor-embedded circuit board according to claim 2, wherein the first conductor and the second conductor are configured such that a current flowing through the first conductor is in a same direction as a current flowing through the second conductor.

5. The conductor-embedded circuit board according to claim 1, wherein the first conductor and the second conductor are electrically connected to each other.

6. The conductor-embedded circuit board according to claim 1, wherein, in the plan view in the thickness direction:
the first conductor and the second conductor face each other in a first direction with the first separation insulating layer interposed therebetween, and
a dimension of the first conductor in a second direction perpendicular to the first direction becomes smaller as the first conductor is farther separated from the second conductor in the first direction.

7. The conductor-embedded circuit board according to claim 1, wherein the through-hole has a shape elongated in a first direction in the plan view in the thickness direction.

8. The conductor-embedded circuit board according to claim 7, wherein:
the first conductor, the second conductor, and the first separation insulating layer form a first structure that has a shape elongated in the first direction in the plan view; and
in the plan view, the first structure is disposed in the through-hole so that a longitudinal direction of the first structure matches or substantially matches a longitudinal direction of the through-hole.

9. The conductor-embedded circuit board according to claim 1, further comprising:
a first inductor and a second inductor between the first wiring layer and the second wiring layer, the first inductor and the second inductor being operable independently of each other,
wherein the first inductor includes the first conductor, and the second inductor includes the second conductor.

10. The conductor-embedded circuit board according to claim 1, wherein each conductor of the first conductor and the second conductor includes:
a first end portion that faces the first surface and is electrically connected to an electrode within the first wiring layer, and
a second end portion that faces the second surface and is electrically connected to an electrode within the second wiring layer.

11. The conductor-embedded circuit board according to claim 1, further comprising:
a third conductor disposed in the through-hole and extending in the thickness direction,
wherein, in the plan view, the third conductor is disposed in the through-hole separately from the first conductor and the second conductor with a distance therebetween.

12. The conductor-embedded circuit board according to claim 11, wherein, in the plan view:
the second conductor is between the first conductor and the third conductor in a first direction, and
a second separation insulating layer is disposed between the second conductor and the third conductor.

13. The conductor-embedded circuit board according to claim 12, wherein, in the plan view:
a dimension of the first conductor in a second direction perpendicular to the first direction becomes smaller as the first conductor is farther separated from the second conductor in the first direction, and
a dimension of the third conductor in the second direction becomes smaller as the third conductor is farther separated from the second conductor in the first direction.

14. The conductor-embedded circuit board according to claim 11, wherein the first conductor is electrically connected to the second conductor, while the third conductor is electrically isolated from the first conductor and the second conductor.

15. The conductor-embedded circuit board according to claim 14, wherein the first conductor, the second conductor, and the third conductor are configured such that a current flowing through the first conductor and a current flowing through the second conductor are of a same direction in the thickness direction and such that a direction of a current flowing through the third conductor and the direction of the current flowing through the first conductor are of opposite directions.

16. The conductor-embedded circuit board according to claim 14, wherein the first conductor, the second conductor, and the third conductor are configured such that a current flowing through the first conductor, a current flowing through the second conductor, and a current flowing through the third conductor are of a same direction.

17. The conductor-embedded circuit board according to claim 11, wherein the first conductor, the second conductor, and the third conductor are electrically isolated from each other.

18. The conductor-embedded circuit board according to claim 17, wherein the first conductor, the second conductor, and the third conductor are configured such that a current flowing through the first conductor and a current flowing through the second conductor are of a same direction and such that a current flowing through the third conductor and the current flowing through the first conductor and the second conductor are of opposite directions.

19. The conductor-embedded circuit board according to claim 17, wherein the first conductor, the second conductor, and the third conductor are configured such that a current flowing through the first conductor, a current flowing through the second conductor, and a current flowing through the third conductor are of a same direction in the thickness direction.

20. The conductor-embedded circuit board according to claim 11, wherein the first conductor, the second conductor, and the third conductor are electrically connected to each other.
